(19) United States
(12) Patent Application Publication
(10) Pub. No.: US 2023/0378018 A1
(43) Pub. Date: Nov. 23, 2023

(54) SEMICONDUCTOR DEVICE

(71) Applicant: ROHM CO., LTD., Kyoto (JP)

(72) Inventors: Hajime OKUDA, Kyoto (JP); Yuto NISHIYAMA, Kyoto (JP); Toru TAKUMA, Kyoto (JP); Katsuaki YAMADA, Kyoto (JP)

(73) Assignee: ROHM CO., LTD., Kyoto (JP)

(21) Appl. No.: 18/317,632

(22) Filed: May 15, 2023

(30) Foreign Application Priority Data
May 20, 2022 (JP) 2022-083233

(51) Int. Cl. H01L 23/367; H01L 23/00

(52) U.S. Cl. CPC H01L 23/367; H01L 24/05; H01L 24/48; H01L 24/49; H01L 24/06; H01L 24/32; H01L 24/29; H01L 24/45; H01L 24/73; H01L 2224/05647; H01L 2224/05666; H01L 2224/05655; H01L 2224/05644; H01L 2224/05639; H01L 2224/05624; H01L 2224/05638; H01L 2924/01014; H01L 2224/06181; H01L 2224/05552; H01L 2224/29144; H01L 2224/29139; H01L 2224/29147; H01L 2224/32245; H01L 2224/45147; H01L 2224/45124; H01L 2224/45144; H01L 2224/45139; H01L 2224/45655; H01L 2224/45664; H01L 2224/45644; H01L 2224/48091; H01L 2224/48108; H01L 2224/48245; H01L 2224/48451; H01L 2224/4846; H01L 2224/48465; H01L 2224/49171; H01L 2224/49175; H01L 2224/48101; H01L 2224/4901; H01L 2224/49111; H01L 2224/49112; H01L 2224/48137; H01L 2224/73265; H01L 2224/73215; H01L 2224/32145; H01L 2224/48145; H01L 2224/4945; H01L 23/49513

(57) ABSTRACT

A semiconductor device includes: a substrate; a device region provided in the substrate; a terminal covering the device region in a plan view; a plurality of pseudo-bumps densely arranged on the terminal in a state of being opened from a wire; and at least one genuine bump arranged more sparsely than the plurality of the pseudo-bumps on the terminal in a state of being connected to the wire.

### CROSS-REFERENCE TO RELATED APPLICATION

This application is based upon and claims the benefit of priority from Japanese Patent Application No. 2022-083233, filed on May 20, 2022, the entire contents of which are incorporated herein by reference.

### TECHNICAL FIELD

The present disclosure relates to a semiconductor device.

### BACKGROUND

In the related art, there is provided a semiconductor device including electrodes for wire bonding formed in the vicinity of active elements such as a microcomputer and a power transistor.

### SUMMARY

Some embodiments of the present disclosure provide a semiconductor device capable of improving electrical characteristics.

According to an embodiment of the present disclosure, there is provided a semiconductor device including: a substrate; a device region provided in the substrate; a terminal covering the device region in a plan view; a plurality of pseudo-bumps densely arranged on the terminal in a state of being opened from a wire; and at least one genuine bump arranged more sparsely than the plurality of the pseudo-bumps on the terminal in a state of being connected to the wire.

According to another embodiment of the present disclosure, there is provided a semiconductor device including: a substrate; a device region provided in the substrate; a terminal covering the device region in a plan view; a pseudo-bump arranged on the terminal in a state of being opened from a wire; and a genuine bump that is arranged on the terminal in a state of being connected to the wire and has a size smaller than a size of the pseudo-bump.

The above-described or other objects, features, and advantages will be made clear by embodiments described with reference to the accompanying drawings.

### BRIEF DESCRIPTION OF DRAWINGS

The accompanying drawings, which are incorporated in and constitute a part of the specification, illustrate embodiments of the present disclosure.

FIG. 1 is a plan view showing a semiconductor chip according to a first embodiment of the present disclosure.

FIG. 2 is a cross-sectional view taken along line II-II shown in FIG. 1.

FIG. 3 is a circuit diagram showing an electrical configuration example of the semiconductor chip shown in FIG. 1.

FIG. 4 is a plan view showing a layout of an output region.

FIG. 5 is a cross-sectional view taken along line V-V shown in FIG. 4.

FIG. 6 is a cross-sectional view taken along line VI-VI shown in FIG. 4.

FIG. 7 is a cross-sectional view taken along line VII-VII shown in FIG. 4.

FIG. 8 is a perspective view showing a semiconductor device on which the semiconductor chip shown in FIG. 1 is mounted.

FIG. 9 is a plan view showing an internal structure of the semiconductor device shown in FIG. 8 together with pseudo-bumps according to a first layout example.

FIG. 10 is a cross-sectional view taken along line X-X shown in FIG. 9.

FIG. 11 is a cross-sectional view taken along line XI-XI shown in FIG. 9.

FIG. 12 is a plan view showing the pseudo-bumps according to the first layout example.

FIG. 13 is a cross-sectional view taken along line XIII-XIII shown in FIG. 12.

FIG. 14 is a cross-sectional view taken along line XIV-XIV shown in FIG. 12.

FIG. 15 is a plan view showing pseudo-bumps according to a second layout example.

FIG. 16 is a cross-sectional view taken along line XVI-XVI shown in FIG. 15.

FIG. 17 is a plan view showing an internal structure of the semiconductor device together with pseudo-bumps according to a third layout example.

FIG. 18 is a plan view showing the pseudo-bumps according to the third layout example.

FIG. 19 is a cross-sectional view taken along line XIX-XIX shown in FIG. 18.

FIG. 20 is a cross-sectional view taken along line XX-XX shown in FIG. 18.

FIG. 21 is a plan view showing a semiconductor chip according to a second embodiment of the present disclosure.

FIG. 22 is a plan view showing a semiconductor device on which the semiconductor chip shown in FIG. 21 is mounted, together with the pseudo-bumps according to the first layout example.

FIG. 23 is a cross-sectional view taken along line XXIII-XXIII shown in FIG. 22.

FIG. 24 is a plan view showing an internal structure of a semiconductor device according to a first modification together with the pseudo-bumps according to the first layout example.

FIG. 25 is a cross-sectional view taken along line XXV-XXV shown in FIG. 24.

FIG. 26 is a plan view showing an internal structure of a semiconductor device according to a second modification together with the pseudo-bumps according to the first layout example.

FIG. 27 is a cross-sectional view taken along line XXVII-XXVII shown in FIG. 26.

FIG. 28 is a plan view showing a modification of the pseudo-bumps according to the first layout example.

FIG. 29 is a plan view showing a modification of the pseudo-bumps according to the second layout example.

FIG. 30 is a plan view showing a modification of the pseudo-bumps according to the third layout example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described in detail with reference to the accompanying drawings. The accompanying drawings are schematic views and are not strictly illustrated, and scales and the like thereof may not match. In addition, corresponding structures among the accompanying drawings are denoted by the same reference numerals, and duplicate descriptions are omitted or simplified. For structures whose descriptions are omitted or simplified, the descriptions given before the omissions or simplifications apply.

When a phrase such as “substantially equal” is used in a description with a comparison target, this phrase includes not only a numeric value (form) that is equal to the numeric value (form) of the comparison target, but also a numerical error (form error) within a range of ±10% based on the numerical value (form) of the comparison target. Terms such as “first,” “second,” “third,” and the like are used in the embodiments, but these are symbols attached to the name of each structure to clarify the order of explanation, and are not attached to limit the name of each structure.

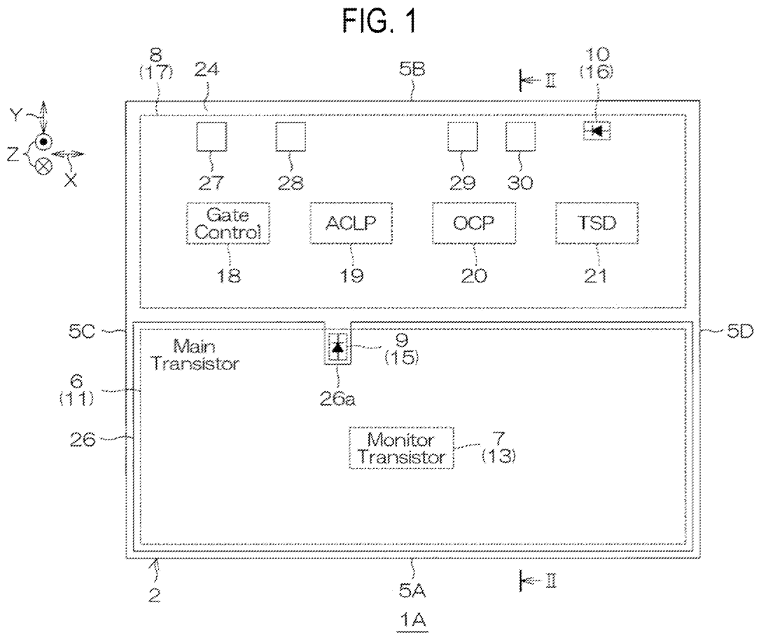

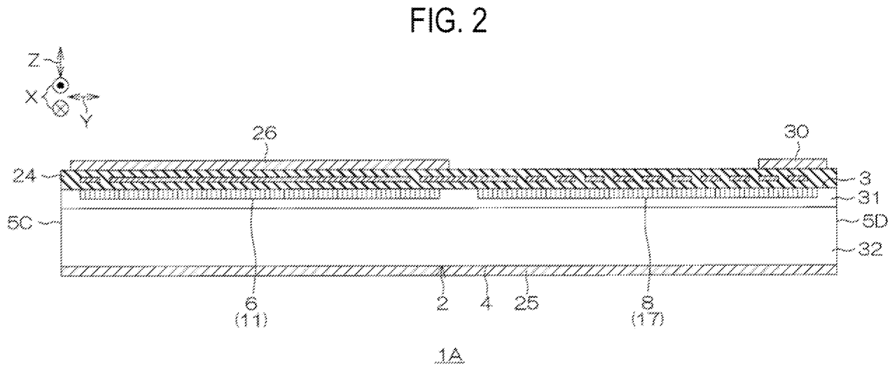

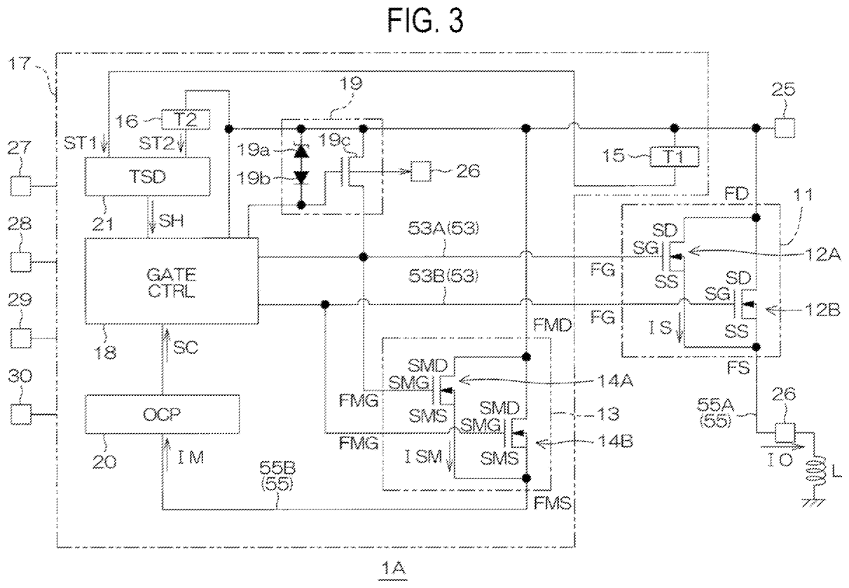

FIG. 1 is a plan view showing a semiconductor chip 1A according to a first embodiment of the present disclosure. FIG. 2 is a cross-sectional view taken along line II-II shown in FIG. 1. FIG. 3 is a circuit diagram showing an electrical configuration example of the semiconductor chip 1A shown in FIG. 1. FIG. 3 shows an example in which an inductive load L is connected to an output terminal (source terminal 26).

Referring to FIGS. 1 and 2, in this embodiment, the semiconductor chip 1A includes a substrate 2 formed in a rectangular parallelepiped shape. The substrate 2 is formed of a Si single crystal substrate. The substrate 2 may be formed of a wide bandgap semiconductor single crystal substrate (for example, a SiC single crystal substrate). The substrate 2 has a first main surface 3 on one side, a second main surface 4 on the other side, and first to fourth side surfaces 5A to 5D connecting the first main surface 3 and the second main surface 4.

The first main surface 3 and the second main surface 4 are formed in a quadrangular shape when viewed from a normal direction Z thereof (hereinafter simply referred to as a “plan view”). The first main surface 3 is a device surface on which functional devices are formed. The second main surface 4 is a non-device surface. The first side surface 5A and the second side surface 5B extend in a first direction X along the first main surface 3 and face each other in a second direction Y intersecting (specifically, perpendicular to) the first direction X. The third side surface 5C and the fourth side surface 5D extend in the second direction Y and face each other in the first direction X.

The first to fourth side surfaces 5A to 5D may each have a length of 0.1 mm or more and 10 mm or less in a plan view. The length of the first to fourth side surfaces 5A to 5D may be 0.1 mm or more and 0.5 mm or less, 0.5 mm or more and 1 mm or less, 1 mm or more and 2.5 mm or less, 2.5 mm or more and 5 mm or less, 5 mm or more and 7.5 mm or less, or 7.5 mm or more and 10 mm or less.

The semiconductor chip 1A includes an output region 6, a current detection region 7, a control region 8, a first temperature detection region 9, and a second temperature detection region 10, which are provided in the first main surface 3. The output region 6, the current detection region 7, the control region 8, the first temperature detection region 9, and the second temperature detection region 10 may be referred to as a “first device region,” a “second device region,” a “third device region,” a “fourth device region,” and a “fifth device region,” respectively.

The output region 6 is a region including a functional device configured to generate an output signal to be output to the outside (outside the semiconductor chip 1A). In this embodiment, the output region 6 is partitioned into regions near the first side surface 5A in the first main surface 3. The output region 6 may be partitioned into a quadrangular shape or may be partitioned into a polygonal shape other than the quadrangular shape in a plan view. The position, size and planar shape of the output region 6 are arbitrary and are not limited to a specific form.

The current detection region 7 is a region including a functional device configured to generate a monitor signal for monitoring the output signal. The current detection region 7 is preferably adjacent to the output region 6. In this embodiment, the current detection region 7 has a plane area smaller than that of the output region 6 and is provided in the inner portion of the output region 6.

That is, the current detection region 7 is provided to be surrounded by the output region 6. The term “surrounded” as used herein includes not only a shape in which the current detection region 7 is surrounded by the output region 6 over the entire circumference, but also a shape in which the current detection region 7 adjoins the output region 6 in at least two directions. In this embodiment, the functional device of the current detection region 7 is formed by using a portion of the functional device of the output region 6.

The control region 8 is a region including a plurality of types of functional devices configured to generate control signals for controlling the functional device of the output region 6. In this embodiment, the control region 8 is partitioned into regions which are near the second side surface 5B with respect to the output region 6 and faces the output region 6 in the second direction Y. The control region 8 may be partitioned into a quadrangular shape or may be partitioned into a polygonal shape other than the quadrangular shape in a plan view. The position, size and planar shape of the control region 8 are arbitrary and are not limited to a specific form.

The control region 8 preferably has a plane area equal to or smaller than the plane area of the output region 6. An area ratio of the plane area of the control region 8 to the plane area of the output region 6 may be 0.1 or more and 2 or less. The area ratio of the plane area of the control region 8 to the plane area of the output region 6 is 0.1 or more and 0.25 or less, 0.25 or more and 0.5 or less, 0.5 or more and 0.75 or less, 0.75 or more and 1 or less, 1 or more and 1.25 or less, 1.25 or more and 1.5 or less, 1.5 or more and 1.75 or less, or 1.75 or more and 2 or less. The area ratio is preferably less than one.

The first temperature detection region 9 is a region including a functional device configured to generate a temperature detection signal for monitoring the temperature of the output region 6. The first temperature detection region 9 is preferably adjacent to the output region 6. In this embodiment, the first temperature detection region 9 has a plane area smaller than the plane area of the output region 6 and is provided in the inner portion of the output region 6.

That is, the first temperature detection region 9 is surrounded by the output region 6. The term “surrounded” as used here includes not only a shape in which the first temperature detection region 9 is surrounded by the output region 6 over the entire circumference, but also a shape in which the first temperature detection region 9 adjoins the output region 6 in at least two directions.

The second temperature detection region 10 is a region including a functional device configured to generate a temperature detection signal for monitoring the temperature of the control region 8. The second temperature detection region 10 is preferably adjacent to the control region 8. In this embodiment, the second temperature detection region 10 has a plane area smaller than the plane area of the control region 8 and is provided in the inner portion of the control region 8.

That is, the second temperature detection region 10 is surrounded by the control region 8. The term “surrounded” as used here includes not only a shape in which the second temperature detection region 10 is surrounded by the control region 8 over the entire circumference, but also a shape in which the second temperature detection region 10 adjoins the control region 8 in at least two directions.

Referring to FIGS. 1 and 3, the semiconductor chip 1A includes an n-system insulated gate type main transistor 11 formed in the output region 6. In this case, “n” is 2 or more (n>2). A 2-system main transistor 11 is illustrated in FIG. 3. The main transistor 11 may be referred to as a “gate split transistor.” The main transistor 11 includes n (n-number) first gates FG, one first drain FD, and one first source FS.

The main transistor 11 is configured such that the same or different n gate signals (gate voltages) are input to the n first gates FG at an arbitrary timing. Each gate signal includes an ON signal for controlling a part of the main transistor 11 to an ON state and an OFF signal for controlling a part of the main transistor 11 to an OFF state.

The main transistor 11 generates a single output current IO (output signal) in response to the n gate signals. That is, the main transistor 11 includes a multi-input single-output type switching device. The output current IO is a drain-source current that flows between the first drain FD and the first source FS. The output current IO is output to the outside of the substrate 2.

The main transistor 11 includes n system transistors 12. A first system transistor 12A and a second system transistor 12B are illustrated in FIG. 3. The n system transistors 12 are collectively formed in the single output region 6 and are configured to be controlled to be turned on and off while being electrically independent from each other.

Specifically, the n system transistors 12 are connected in parallel such that the n gate signals are individually input to the n system transistors 12. That is, the n-system main transistor 11 is configured such that the system transistor 12 in the ON state and the system transistor 12 in the OFF state coexist at an arbitrary timing.

The n system transistors 12 each include a second gate SG, a second drain SD, and a second source SS. The n second gates SG constitute the n first gates FG, respectively. The n second drains SD constitute the one first drain FD. The n second sources SS constitute the one first source FS.

The n system transistors 12 each generate a system current IS in response to the corresponding gate signal. The system current IS is a drain-source current that flows between the second drain SD and the second source SS of the system transistor 12. The n system currents IS may have different values or may have the same values. The n system currents IS are added between the first drain FD and the first source FS. As a result, a single output current IO, which is the sum of n system currents IS, is generated.

Referring to FIGS. 1 and 3, the semiconductor chip 1A includes an m-system insulated gate type monitor transistor 13 formed in the current detection region 7. In this case, “m” is 1 or more (m>1). A 2-system monitor transistor 13 is illustrated in FIG. 3. The monitor transistor 13 is connected in parallel to the main transistor 11 and is configured to monitor a portion or all of the output current IO. That is, the monitor transistor 13 is connected in parallel to at least one system transistor 12 and monitors at least one system current IS.

The monitor transistor 13 is preferably connected in parallel to a plurality of system transistors 12 and configured to monitor the plurality of system currents IS. In this embodiment, the monitor transistor 13 includes an n(m=n)-system monitor transistor 13 connected in parallel to the n system transistors 12 so as to monitor the n system currents IS. In the following description, the “m-system” is replaced with the “n-system,” and “m” is replaced with “n” as necessary.

In this embodiment, the monitor transistor 13 includes n first monitor gates FMG, one first monitor drain FMD, and one first monitor source FMS. The n first monitor gates FMG are configured to individually receive n monitor gate signals (monitor gate voltages).

The first monitor drain FMD is electrically connected to the first drain FD. The first monitor source FMS is electrically isolated from the first source FS. The same or different n monitor gate signals are input to the n first monitor gates FMG at an arbitrary timing. Each monitor gate signal includes an ON signal for controlling a part of the monitor transistor 13 to the ON state and an OFF signal for controlling a part of the monitor transistor 13 to the OFF state.

In this embodiment, the monitor transistor 13 generates a single monitor current IM (monitor signal) for monitoring the n system currents IS (output current IO) in response to the n monitor gate signals. That is, the monitor transistor 13 includes a multi-input single-output type switching device. The monitor current IM is a drain-source current that flows between the first monitor drain FMD and the first monitor source FMS.

In this embodiment, the n first monitor gates FMG are electrically connected to the corresponding n first gates FG in one-to-one correspondence, respectively. Therefore, the n first monitor gates FMG are configured so that the monitor gate signals including gate signals are individually input to the n first monitor gates FMG. That is, the monitor transistor 13 is ON/OFF-controlled at the same timing as the main transistor 11 and generates the monitor current IM that increases and decreases in conjunction with increase and decrease of the output current IO.

The monitor current IM is output to the outside of the output region 6 via a current path electrically independent of a current path of the output current IO. The monitor current IM is equal to or less than the output current IO (IM<IO). The monitor current IM is preferably less than the output current IO (IM<IO). A current ratio IM/JO of the monitor current IM to the output current IO is arbitrary. The current ratio IM/JO may be 1/10,000 or more and 1 or less (preferably less than 1).

The monitor transistor 13 includes m (n in this embodiment) system monitor transistors 14. A first system monitor transistor 14A and a second system monitor transistor 14B are illustrated in FIG. 3. The number of systems of monitor transistors 13 is adjusted by the number of system monitor transistors 14.

That is, when the m-system monitor transistor 13 monitors at least one system current IS, at least one system monitor transistor 14 is electrically connected (specifically, connected in parallel) to at least one system transistor 12. Further, when the m-system monitor transistor 13 monitors a plurality of system currents IS, a plurality of system monitor transistors 14 are electrically connected to a plurality of system transistors 12. In this embodiment, the n system monitor transistors 14 are electrically connected to the n system transistors 12.

The n system monitor transistors 14 are configured to be controlled to be turned on and off electrically independently of each other. Specifically, the n system monitor transistors 14 are connected in parallel so that the n monitor gate signals are individually input to the n system monitor transistors 14. That is, the monitor transistor 13 is configured such that the system monitor transistor 14 in the ON state and the system monitor transistor 14 in the OFF state coexist at an arbitrary timing.

The n system monitor transistors 14 each include a second monitor gate SMG, a second monitor drain SMD, and a second monitor source SMS. The n second monitor gates SMG constitute the n first monitor gates FMG, respectively. The n second monitor drains SMD constitute one first monitor drain FMD. The n second monitor sources SMS constitute one first monitor source FMS.

The same or different n monitor gate signals are input to the n second monitor gates SMG at an arbitrary timing. The n system monitor transistors 14 each generate a system monitor current ISM (system monitor signal) for monitoring the system current IS of the corresponding system transistor 12 in response to the corresponding monitor gate signal.

The system monitor current ISM is a drain-source current that flows between the second monitor drain SMD and the second monitor source SMS of the system monitor transistor 14. The n system monitor currents ISM are added between the first monitor drain FMD and the first monitor source FMS. As a result, the single monitor current IM, which is the sum of n system monitor currents ISM, is generated.

In this embodiment, the n system monitor transistors 14 are electrically connected to the corresponding system transistors 12 in one-to-one correspondence and are controlled in conjunction with the corresponding system transistors 12. Specifically, the n system monitor transistors 14 are connected in parallel to the corresponding system transistors 12, respectively, so that the system monitor current ISM is output to a current path electrically independent of a current path of the system current IS.

The n second monitor gates SMG are electrically connected to the corresponding first gates FG in one-to-one correspondence, respectively. That is, in this embodiment, the monitor gate signals including gate signals are input to the n second monitor gates SMG, respectively. The second monitor drain SMD is electrically connected to the first drain FD. The second monitor source SMS is electrically isolated from the first source FS.

As a result, the n system monitor transistors 14 are ON/OFF-controlled at the same timing as the corresponding system transistors 12 and generate the system monitor currents ISM that increase and decrease in conjunction with increase and decrease in the corresponding system currents IS, respectively. The system monitor current ISM is taken out from the second monitor source SMS electrically independent of the system current IS.

Each system monitor current ISM is equal to or less than the corresponding system current IS (ISM IS). Each system monitor current ISM is preferably less than the corresponding system current IS (ISMC<IS). A current ratio ISM/IS of the system monitor current ISM to the system current IS is arbitrary. The current ratio ISM/IS may be 1/10,000 or more and 1 or less (preferably less than 1).

A control example of the 2-system main transistor 11 and the 2-system monitor transistor 13 will be described below. When a gate signal lower than a gate threshold voltage (that is, an OFF signal) is input to all of the n first gates FG, the first system transistor 12A and the second system transistor 12B are turned off. This control is applied during OFF operation of the main transistor 11. On the other hand, in the monitor transistor 13, the first system monitor transistor 14A and the second system monitor transistor 14B are turned off in conjunction with the main transistor 11.

When a gate signal equal to or higher than the gate threshold voltage (that is, an ON signal) is input to all of the n first gates FG, the first system transistor 12A and the second system transistor 12B are turned on. As a result, the main transistor 11 generates the output current IO including the system current IS of the first system transistor 12A and the system current IS of the second system transistor 12B. In this case, a channel utilization rate of the main transistor 11 increases relatively and on-resistance thereof decreases relatively. This control is applied during normal operation of the main transistor 11.

On the other hand, in the monitor transistor 13, the first system monitor transistor 14A and the second system monitor transistor 14B are turned on in conjunction with the main transistor 11. The monitor transistor 13 generates the monitor current IM including the system monitor current ISM of the first system monitor transistor 14A and the system monitor current ISM of the second system monitor transistor 14B. In this case, a channel utilization rate of the monitor transistor 13 increases relatively and on-resistance thereof decreases relatively.

When a gate signal equal to or higher than the gate threshold voltage (that is, an ON signal) is input to the first gate FG of the first system transistor 12A and a gate signal lower than the gate threshold voltage (that is, an OFF signal) is inputted to the first gate FG of the second system monitor transistor 14B, the first system transistor 12A is turned on and the second system monitor transistor 14B is turned off.

As a result, the main transistor 11 generates the output current IO including the system current IS of the first system transistor 12A. In this case, the channel utilization rate of the main transistor 11 decreases relatively and the on-resistance thereof increases relatively. This control is applied during an active clamp operation of the main transistor 11.

On the other hand, in the monitor transistor 13, in conjunction with the main transistor 11, the first system monitor transistor 14A is turned on and the second system monitor transistor 14B is turned off. The monitor transistor 13 generates the monitor current IM including the system monitor current ISM of the first system monitor transistor 14A. In this case, the channel utilization rate of the monitor transistor 13 decreases relatively and the on-resistance thereof increases relatively.

Referring to FIGS. 1 and 3, the semiconductor chip 1A includes a first temperature-sensitive diode 15 as an example of a first temperature sensor formed in the first temperature detection region 9. The first temperature-sensitive diode 15 has forward voltage temperature characteristics that vary depending on the temperature of the output region 6, and generates a first temperature detection signal ST1 for detecting the temperature of the output region 6. The forward voltage may have negative temperature characteristics such that the forward voltage decreases linearly as the temperature of the output region 6 rises.

Referring to FIGS. 1 and 3, the semiconductor chip 1A includes a second temperature-sensitive diode 16 as an example of a second temperature sensor formed in the second temperature detection region 10. The second temperature-sensitive diode 16 has a forward voltage temperature characteristics that vary depending on the temperature of the control region 8, and generates a second temperature detection signal ST2 for detecting the temperature of the control region 8. The forward voltage may have negative temperature characteristics such that the forward voltage decreases linearly as the temperature of the control region 8 rises.

The second temperature-sensitive diode 16 preferably has substantially the same configuration as the first temperature-sensitive diode 15 and preferably has substantially the same electrical characteristics as the first temperature-sensitive diode 15. The temperature of the control region 8 is lower than the temperature of the output region 6 when the main transistor 11 generates the output current IO. Therefore, the forward voltage of the second temperature-sensitive diode 16 is higher than the forward voltage of the first temperature-sensitive diode 15 when the output current IO is generated.

The semiconductor chip 1A includes a control circuit 17 formed in the control region 8. The control circuit 17 may be called a “control IC (Control Integrated Circuit).” The control circuit 17 constitutes an IPD (Intelligent Power Device) together with the main transistor 11. The IPD may also be called an “IPM (Intelligent Power Module)”. The control circuit 17 includes a plurality of types of functional circuits that implement various functions in response to electrical signals input from the outside.

In this embodiment, the control circuit 17 includes a gate drive circuit 18, an active clamp circuit 19, an overcurrent protection circuit 20, and an overheating protection circuit 21. The overcurrent protection circuit 20 may be called an “OCP (Over Current Protection) circuit,” and the overheating protection circuit 21 may be called a “TSD (Thermal Shutdown) circuit.” The monitor transistor 13, the first temperature-sensitive diode 15, and the second temperature-sensitive diode 16 described above constitute a part of the control circuit 17.

The gate drive circuit 18 is electrically connected to the first gate FG of the main transistor 11 and the first monitor gate FMG of the monitor transistor 13, and generates a gate signal for controlling the main transistor 11 and the monitor transistor 13 in response to electric signals from the outside.

The active clamp circuit 19 is electrically connected to the main transistor 11 and the gate drive circuit 18. Specifically, the active clamp circuit 19 is electrically connected to some (not all) of the first gates FG, the first drains FD, and the gate drive circuit 18.

The active clamp circuit 19 may include a first diode stage 19a, a second diode stage 19b, and an n-channel MISFET 19c. The first diode stage 19a includes one or more Zener diodes forming a forward series circuit. The cathode of the first diode stage 19a is electrically connected to the first drain FD.

The second diode stage 19b includes one or more pn junction diodes forming a forward series circuit. The anode of the second diode stage 19b is in reverse bias connection with the anode of the first diode stage 19a. The cathode of the second diode stage 19b is electrically connected to the gate drive circuit 18.

The gate of the MISFET 19c is electrically connected to the cathode of the second diode stage 19b. The back gate of the MISFET 19c is electrically connected to the first source FS. The drain of the MISFET 19c is connected to the first drain FD. The source of the MISFET 19c is electrically connected to a part (not all) of the first gates FG.

The active clamp circuit 19 limits (clamps) an output voltage in cooperation with the gate drive circuit 18 when a back electromotive force is input to the main transistor 11 due to energy accumulated in the inductive load L, to protect the main transistor 11 from the back electromotive force. That is, the active clamp circuit 19 is configured to limit the output voltage until the back electromotive force is consumed, by active-clamping the main transistor 11 when the back electromotive force is input.

Specifically, during the active clamping operation, the active clamp circuit 19 cooperates with the gate drive circuit 18 to turn on a part (for example, the first system transistor 12A) of the main transistor 11 and turn off a part (for example, the second system transistor 12B) of the main transistor 11.

Further, during the active clamping operation, the active clamp circuit 19 cooperates with the gate drive circuit 18 to turn on a part (for example, the first system monitor transistor 14A) of the monitor transistor 13 and turn off a part (for example, the second system monitor transistor 14B) of the monitor transistor 13.

The active clamp circuit 19 may be configured to ON/OFF-control the n system transistors 12 (the system monitor transistors 14) when the first source FS of the main transistor 11 falls below a predetermined voltage (for example, a predetermined negative voltage).

The overcurrent protection circuit 20 is electrically connected to the monitor transistor 13 and the gate drive circuit 18. The overcurrent protection circuit 20 is electrically connected to the first monitor source FMS of the monitor transistor 13 and is configured to receive a part or all (all in this embodiment) of the monitor current IM. The overcurrent protection circuit 20 cooperates with the gate drive circuit 18 to control the gate signal and protect the main transistor 11 from an overcurrent.

The overcurrent protection circuit 20 may be configured to generate an overcurrent detection signal SC when the monitor current IM exceeds a predetermined threshold value, and to output the overcurrent detection signal SC to the gate drive circuit 18. The overcurrent detection signal SC is a signal for limiting some or all of the n gate signals generated in the gate drive circuit 18 to a predetermined value or less (for example, OFF).

The gate drive circuit 18 limits some or all of the n gate signals in response to the overcurrent detection signal SC to suppress an overcurrent flowing through the main transistor 11. The overcurrent protection circuit 20 shifts the gate drive circuit 18 (the main transistor 11) to normal control when the monitor current IM becomes equal to or less than the predetermined threshold value.

The overheating protection circuit 21 is electrically connected to the first temperature-sensitive diode 15, the second temperature-sensitive diode 16, and the gate drive circuit 18. The overheating protection circuit 21 is configured to cooperate with the gate drive circuit 18 to control the gate signal and protect the main transistor 11 from overheating. The overheating protection circuit 21 receives the first temperature detection signal ST1 from the first temperature-sensitive diode 15 and the second temperature detection signal ST2 from the second temperature-sensitive diode 16.

The overheating protection circuit 21 may be configured to generate an overheating detection signal SH when a difference value between the first temperature detection signal ST1 and the second temperature detection signal ST2 exceeds a predetermined threshold value, and to output the overheating detection signal SH to the gate drive circuit 18. The overheating detection signal SH is a signal for limiting some or all of the n gate signals generated in the gate drive circuit 18 to OFF.

The gate drive circuit 18 turns off a part or all of the main transistor 11 in response to the overheating detection signal SH to suppress the temperature rise of the output region 6. Further, the gate drive circuit 18 turns off a part or all of the monitor transistor 13 in response to the overheating detection signal SH to suppress the temperature rise of the current detection region 7 (the output region 6). The overheating protection circuit 21 shifts the gate drive circuit 18 to normal control when the difference value becomes equal to or smaller than the threshold value.

Referring to FIG. 2, the semiconductor chip 1A includes an interlayer insulating film 24 covering the first main surface 3. The interlayer insulating film 24 collectively covers the output region 6, the current detection region 7, the control region 8, the first temperature detection region 9, and the second temperature detection region 10. In this embodiment, the interlayer insulating film 24 has a multilayer wiring structure including a plurality of insulating films laminated on the first main surface 3 and a plurality of wirings arranged on an arbitrary insulating film.

Each insulating film may include at least one of a silicon oxide film and a silicon nitride film. Each wiring may include at least one of a pure Al layer (an Al layer with a purity of 99% or higher), a Cu layer (a Cu layer with a purity of 99% or higher), an AlCu alloy layer, an AlSiCu alloy layer, and an AlSi alloy layer.

Referring to FIGS. 1 and 2, the semiconductor chip 1A includes a plurality of terminals 25 to 30. The number, layout, and the like of the terminals 25 to 30 are appropriately adjusted according to specifications of the main transistor 11 and specifications of the control circuit 17. In this embodiment, the plurality of terminals 25 to 30 include a drain terminal 25 (power supply terminal), a source terminal 26 (output terminal), a first control terminal 27, a second control terminal 28, a third control terminal 29, and a fourth control terminal 30.

The drain terminal 25 covers the second main surface 4 of the substrate 2 and is electrically connected to the second main surface 4. The drain terminal 25 may include at least one of a Ti layer, a Ni layer, an Au layer, an Ag layer, and an Al layer. The drain terminal 25 may have a laminated structure in which at least two of a Ti layer, a Ni layer, an Au layer, an Ag layer, and an Al layer are laminated in an arbitrary manner. The drain terminal 25 is electrically connected to the first drain FD of the main transistor 11 and transmits a power supply potential.

The source terminal 26 is arranged on the interlayer insulating film 24. The source terminal 26 covers the output region 6 to expose the control region 8 in a plan view. The layout of the source terminal 26 is adjusted by the layout of the output region 6 and is not limited to any particular form. In this embodiment, the source terminal 26 is formed in a quadrangular shape (specifically, a rectangular shape extending in the first direction X) in a plan view. Of course, the source terminal 26 may be formed in a polygonal shape other than the quadrangular shape in a plan view.

In this embodiment, the source terminal 26 includes a notch 26a that is cut in a quadrangular shape so as to expose the first temperature detection region 9 (the first temperature-sensitive diode 15). The source terminal 26 is electrically connected to the first source FS of the main transistor 11 and transmits the output current IO to the outside. The source terminal 26 may include one or both of an Al-based metal layer and a Cu-based metal layer. The source terminal 26 may include at least one of a pure Al layer, a pure Cu layer, an AlCu alloy layer, an AlSiCu alloy layer, and an AlSi alloy layer.

The first to fourth control terminals 27 to 30 are arranged on the interlayer insulating film 24. The first to fourth control terminals 27 to 30 may be, for example, an input terminal configured to apply an input signal to the control circuit 17, an enable terminal configured to apply an enable signal to the control circuit 17, a self-diagnostic output terminal configured to output an electric signal for diagnosing the state of the control circuit 17, and a ground terminal configured to apply a ground potential to the control circuit 17.

The first to fourth control terminals 27 to 30 cover a region (specifically, the control region 8) outside the output region 6 in a plan view. All of the first to fourth control terminals 27 to 30 have a plane area smaller than a plane area of the source terminal 26. The first to fourth control terminals 27 to 30 may include at least one of a pure Al layer, a pure Cu layer, an AlCu alloy layer, an AlSiCu alloy layer, and an AlSi alloy layer.

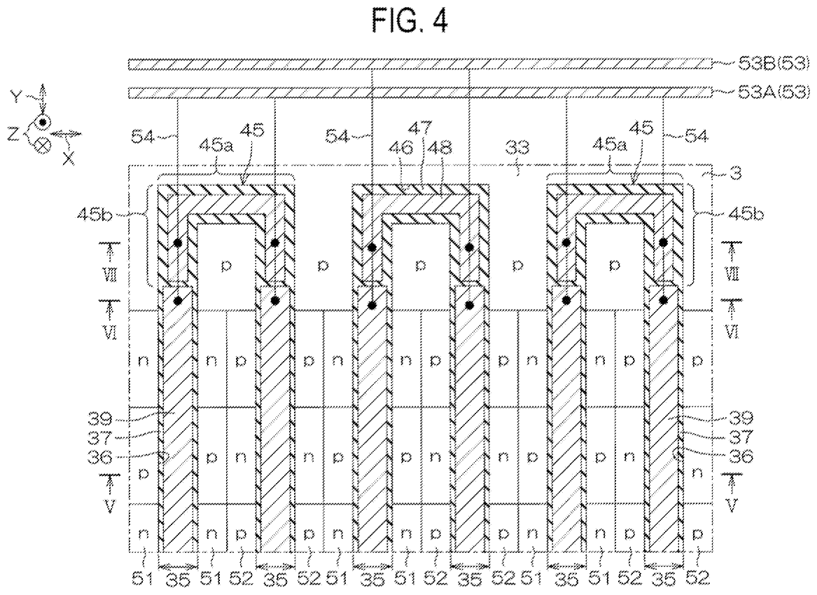

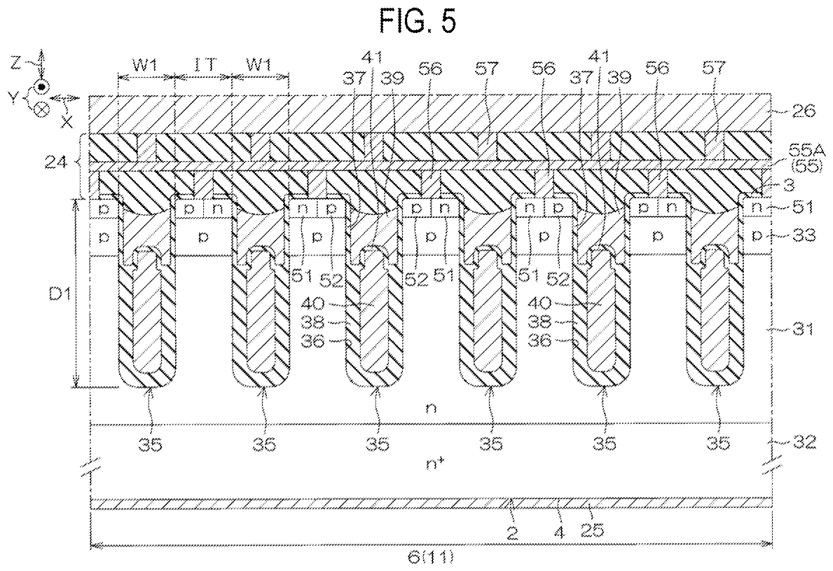

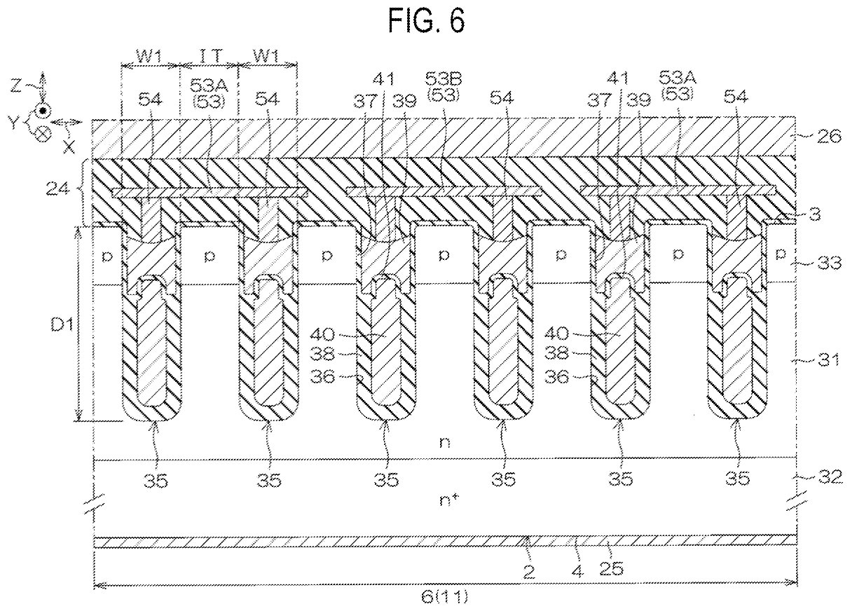

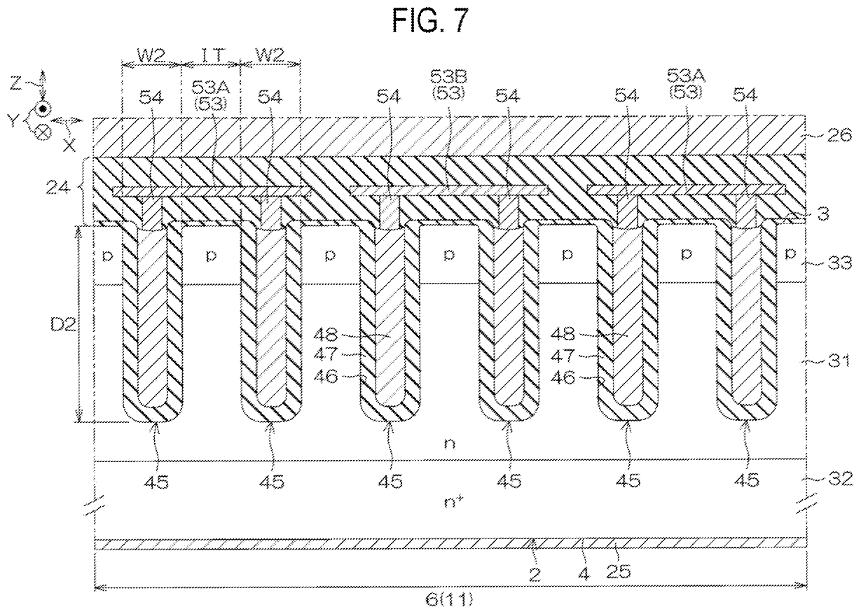

The configuration of the output region 6 will be described below with reference to FIGS. 4 to 7. FIG. 4 is a plan view showing the layout of the output region 6. FIG. 5 is a cross-sectional view taken along line V-V shown in FIG. 4. FIG. 6 is a cross-sectional view taken along line VI-VI shown in FIG. 4. FIG. 7 is a cross-sectional view taken along line VII-VII shown in FIG. 4.

The semiconductor chip 1A includes an n-type (first conductivity type) first semiconductor region 31 formed in the surface layer portion of the first main surface 3 of the substrate 2. The first semiconductor region 31 forms the first drain FD of the main transistor 11 and the first monitor drain FMD of the monitor transistor 13. The first semiconductor region 31 may be called a “drift region.”

The first semiconductor region 31 is formed over the entire surface layer portion of the first main surface 3 and is exposed from the first main surface 3 and the first to fourth side surfaces 5A to 5D. The thickness of the first semiconductor region 31 may be 5 μm or more and 30 μm or less. The thickness of the first semiconductor region 31 is preferably 10 μm or more and 20 μm or less. In this embodiment, the first semiconductor region 31 is formed of an n-type epitaxial layer (Si epitaxial layer).

The semiconductor chip 1A includes an n-type second semiconductor region 32 formed in the surface layer portion of the second main surface 4 of the substrate 2. The second semiconductor region 32 forms the first drain FD of the main transistor 11 and the first monitor drain FMD of the monitor transistor 13 together with the first semiconductor region 31. The second semiconductor region 32 may be called a “drain region.”

The second semiconductor region 32 is formed over the entire surface layer portion of the second main surface 4 to be electrically connected to the first semiconductor region 31, and is exposed from the second main surface 4 and the first to fourth side surfaces 5A to 5D. The second semiconductor region 32 is thicker than the first semiconductor region 31. The thickness of the second semiconductor region 32 may be 10 μm or more and 450 μm or less. The thickness of the second semiconductor region 32 is preferably 50 μm or more and 150 μm or less. In this embodiment, the second semiconductor region 32 is formed of an n-type semiconductor substrate (Si semiconductor substrate).

The semiconductor chip 1A includes p-type (second conductivity type) body regions 33 formed in the surface layer portion of the first semiconductor region 31 of the output region 6 and the current detection region 7. The body regions 33 are formed at intervals from the bottom of the first semiconductor region 31 toward the first main surface 3 and face the second semiconductor region 32 with portions of the first semiconductor region 31 interposed therebetween.

The semiconductor chip 1A includes a plurality of trench structures 35 formed in the first main surface 3 in the output region 6. The trench structure 35 may be called a “trench gate structure.” The plurality of trench structures 35 include a plurality of trench structures 35 for the main transistor 11 formed in the output region 6 and a plurality of trench structures 35 for the monitor transistor 13 formed in the current detection region 7. The number of trench structures 35 for the monitor transistor 13 is less than the number of trench structures 35 for the main transistor 11.

The plurality of trench structures 35 are arranged in the first direction X at intervals in a plan view and are each formed in a strip shape extending in the second direction Y. The plurality of trench structures 35 penetrate through the body region 33 to reach the first semiconductor region 31. The plurality of trench structures 35 are formed at intervals from the bottom of the first semiconductor region 31 toward the first main surface 3 and face the second semiconductor region 32 with portions of the first semiconductor region 31 interposed therebetween.

Each trench structure 35 has a first width W1 and a first depth D1. The first width W1 is a width in a direction perpendicular to the direction in which the trench structure 35 extends. The first width W1 may be 0.5 μm or more and 2 μm or less. The first width W1 is preferably 0.5 μm or more and 1.5 μm or less. The first depth D1 may be 1 μm or more and 10 μm or less. The first depth D1 is preferably 2 μm or more and 6 μm or less. The bottom wall of each trench structure 35 is preferably spaced apart from the bottom of the first semiconductor region 31 by 1 μm or more and 5 μm or less.

The plurality of trench structures 35 are arranged in the first direction X with trench intervals IT. The trench interval IT may be 0.25 to 1.5 times the first width W1. The trench interval IT is preferably equal to or less than the first width W1. The trench interval IT may be 0.5 μm or more and 2 μm or less.

The configuration of one of the trench structures 35 will be described below. The trench structure 35 has a multi-electrode structure including a trench 36, a first insulating film 37, a second insulating film 38, a first electrode 39, a second electrode 40, and a third insulating film 41. That is, the trench structure 35 includes an electrode (gate electrode) buried in the trench 36 with an insulator (gate insulator) interposed therebetween. The insulator includes the first insulating film 37, the second insulating film 38, and the third insulating film 41. The electrode includes the first electrode 39 and the second electrode 40.

The trench 36 is dug down from the first main surface 3 toward the second main surface 4 to partition the wall surface of the trench structure 35. The first insulating film 37 covers an upper wall surface of the trench 36 in the form of a film. Specifically, the first insulating film 37 covers the upper wall surface located on a region near an opening of the trench 36 with respect to the bottom of the body region 33.

The first insulating film 37 includes a portion that crosses a boundary between the first semiconductor region 31 and the body region 33 and covers the first semiconductor region 31. The first insulating film 37 may include a silicon oxide film. The first insulating film 37 preferably includes a silicon oxide film made of oxide of the substrate 2. The first insulating film 37 is formed as a gate insulating film.

The second insulating film 38 covers a lower wall surface of the trench 36 in the form of a film. Specifically, the second insulating film 38 covers the bottom wall surface located on a region near a bottom wall of the trench 36 with respect to the bottom of the body region 33. The second insulating film 38 covers the first semiconductor region 31. The second insulating film 38 may include a silicon oxide film. The second insulating film 38 preferably includes a silicon oxide film made of oxide of the substrate 2. The second insulating film 38 is preferably thicker than the first insulating film 37.

The first electrode 39 is buried in an upper side (near the opening) of the trench 36 with the first insulating film 37 interposed therebetween. The first electrode 39 is buried in a strip shape extending in the second direction Y in a plan view. The first electrode 39 faces the body region 33 and the first semiconductor region 31 with the first insulating film 37 interposed therebetween. The first electrode 39 may contain conductive polysilicon. The first electrode 39 is formed as a gate electrode. A gate signal is input to the first electrode 39.

The second electrode 40 is buried on a lower side (near the bottom wall) of the trench 36 with the second insulating film 38 interposed therebetween. The second electrode 40 is buried in a strip shape extending in the second direction Y in a plan view. The second electrode 40 may have a thickness (length) exceeding a thickness (length) of the first electrode 39 in a depth direction of the trench 36.

The second electrode 40 faces the first semiconductor region 31 with the second insulating film 38 interposed therebetween. The second electrode 40 has an upper end portion protruding from the second insulating film 38 toward the first main surface 3. The upper end portion of the second electrode 40 is engaged with the bottom portion of the first electrode 39 and faces the first insulating film 37 in a lateral direction along the first main surface 3 with the bottom portion of the first electrode 39 interposed therebetween.

The second electrode 40 may contain conductive polysilicon. In this embodiment, the second electrode 40 is formed as a gate electrode and is fixed to the same potential as the first electrode 39. That is, the same gate signal is applied to the second electrode 40 simultaneously with the first electrode 39. As a result, a voltage drop between the first electrode 39 and the second electrode 40 is suppressed, such that an electric field concentration between the first electrode 39 and the second electrode 40 is suppressed. Further, a carrier density in the vicinity of the trench 36 increases, such that the on-resistance of the substrate 2 (particularly, the first semiconductor region 31) decreases.

The third insulating film 41 is interposed between the first electrode 39 and the second electrode 40 to electrically isolate the first electrode 39 and the second electrode 40 from each other. The third insulating film 41 covers a portion of the second electrode 40 exposed from the second insulating film 38 and is connected to the first insulating film 37 and the second insulating film 38. The third insulating film 41 may include a silicon oxide film. The third insulating film 41 preferably includes a silicon oxide film made of oxide of the second electrode 40. The third insulating film 41 is preferably thinner than the second insulating film 38.

The semiconductor chip 1A includes a plurality of trench connection structures 45 formed on the first main surface 3 in the output region 6. The plurality of trench connection structures 45 are formed in a region on one end side of the plurality of trench structures 35 and a region on the other end side of the plurality of trench structures 35, respectively. The region on one end side of the plurality of trench structures 35 is shown in FIG. 4.

The plurality of trench connection structures 45 are each formed in a strip shape extending in the second direction Y to connect one end portions of at least two (two in this embodiment) trench structures 35 adjacent to each other in the first direction X. The plurality of trench connection structures 45 are each formed in a strip shape extending in the second direction Y to connect the other end portions of the at least two (two in this embodiment) trench structures 35 adjacent to each other in the first direction X.

The plurality of trench connection structures 45 each constitute one annular or ladder-shaped unit trench structure together with the plurality of trench structures 35 in a plan view. The plurality of trench connection structures 45 are formed at intervals from the bottom of the first semiconductor region 31 toward the first main surface 3 and face the second semiconductor region 32 with a portion of the first semiconductor region 31 interposed therebetween.

The trench connection structure 45 on the other side has the same structure as the trench connection structure 45 on the one side except that it is connected to the other end portions of the plurality of trench structures 35. Hereinafter, a configuration of one trench connection structure 45 on the one side will be described, and description of the trench connection structure 45 on the other side will be omitted.

The trench connection structure 45 includes a first trench portion 45a extending in the first direction X and a plurality of second trench portions 45b (two second trench portions 45b in this embodiment) extending in the second direction Y. The first trench portion 45a faces the one end portions of the plurality of trench structures 35 in a plan view. The plurality of second trench portions 45b extend from the first trench portion 45a toward the one end portions of the plurality of trench structures 35 and are connected to the plurality of one end portions.

The trench connection structure 45 has a second width W2 and a second depth D2. The second width W2 is a width in a direction perpendicular to the direction in which the trench connection structure 45 extends. The second width W2 is preferably approximately equal to the first width W1 of the trench structure 35. The second depth D2 is preferably approximately equal to the first depth D1 of the trench structure 35. The bottom wall of the trench connection structure 45 is preferably spaced apart from the bottom of the first semiconductor region 31 by 1 μm or more and 5 μm or less.

The trench connection structure 45 has a single electrode structure including a connection trench 46, a connection insulating film 47, and a connection electrode 48. The connection trench 46 is dug down from the first main surface 3 toward the second main surface 4 to partition the wall surface of the trench connection structure 45. The sidewall and bottom wall of the connection trench 46 are connected to the sidewall and bottom wall of the trench 36 of the trench structure 35.

The connection insulating film 47 covers the wall surface of the connection trench 46 in the form of a film. The connection insulating film 47 is connected to the first insulating film 37 and the second insulating film 38 at a communication portion between the trench 36 and the connection trench 46. The connection insulating film 47 may include a silicon oxide film. The connection insulating film 47 preferably includes a silicon oxide film made of oxide of the substrate 2. The connection insulating film 47 is preferably thicker than the first insulating film 37. The thickness of the connection insulating film 47 may be approximately equal to the thickness of the second insulating film 38.

The connection electrode 48 is buried in the connection trench 46 with the connection insulating film 47 interposed therebetween. The connection electrode 48 may contain conductive polysilicon. The connection electrode 48 extends in the first direction X in the first trench portion 45a and extends in the second direction Y in the second trench portion 45b. The connection electrode 48 is connected to the second electrode 40 at the communication portion between the trench 36 and the connection trench 46 and faces the first electrode 39 with the third insulating film 41 interposed therebetween. The same gate signal is applied to the connection electrode 48 at the same time as the first electrode 39 and the second electrode 40.

The semiconductor chip 1A includes a plurality of n-type source regions 51 respectively formed in regions along the plurality of trench structures 35 in the surface layer portion of the body region 33 of the output region 6 and the current detection region 7. An n-type impurity concentration of the plurality of source regions 51 is higher than that of the first semiconductor region 31. The plurality of source regions 51 are respectively disposed on both sides of each trench structure 35 and are arranged at intervals along each trench structure 35. The plurality of source regions 51 are formed at intervals from the bottom of the body region 33 toward the first main surface 3 and face the first electrode 39 with the corresponding first insulating film 37 interposed therebetween.

It is preferable that the plurality of source regions 51 along the trench structure 35 on one side are arranged to be shifted in the second direction Y with respect to the plurality of source regions 51 along the trench structures 35 on the other side. That is, it is preferable that the plurality of source regions 51 along the trench structure 35 on one side are opposed in the first direction X to regions among the plurality of source regions 51 along the trench structures 35 on the other side.

The semiconductor chip 1A includes a plurality of p-type contact regions 52 respectively formed in regions along the plurality of trench structures 35 in the surface layer portion of the body region 33 of the output region 6 and the current detection region 7. A p-type impurity concentration of the plurality of contact regions 52 is higher than that of the body region 33.

The plurality of contact regions 52 are respectively disposed on both sides of each trench structure 35 and arranged at intervals along each trench structure 35. The plurality of contact regions 52 are formed at intervals from the bottom of the body region 33 toward the first main surface 3 and face the first electrodes 39 with the corresponding first insulating films 37 interposed therebetween.

The plurality of contact regions 52 are arranged alternately with the plurality of source regions 51 on both sides of each trench structure 35. It is preferable that the plurality of contact regions 52 along the trench structure 35 on one side are arranged to be shifted in the second direction Y with respect to the plurality of contact regions 52 along the trench structures 35 on the other side. That is, it is preferable that the plurality of contact regions 52 along the trench structure 35 on one side are opposed in the first direction X to regions (that is, the source regions 51) among the plurality of contact regions 52 along the trench structures 35 on the other side.

The semiconductor chip 1A includes n gate wirings 53 arranged electrically independently of each other in the above-described interlayer insulating film 24. The n gate wirings 53 include n gate wirings 53 for the main transistor 11 and n gate wirings 53 for the monitor transistor 13. The n gate wirings 53 are selectively electrically connected to the corresponding at least one trench structure 35 via a plurality of first via electrodes 54 in the output region 6 and the current detection region 7 and are electrically connected to the control circuit 17 (the gate drive circuit 18) in the control region 8. The plurality of first via electrodes 54 may contain tungsten.

Specifically, the n gate wirings 53 for the main transistor 11 are electrically connected to at least one (in this embodiment, a plurality of) trench structure 35 and at least one (in this embodiment, a plurality of) trench connection structure 45 to be systematized (grouped) as the system transistor 12 via the plurality of first via electrodes 54 in the output region 6, respectively.

Here, an example will be described in which the n gate wirings 53 for the main transistor 11 include a first gate wiring 53A for the first system transistor 12A and a second gate wiring 53B for the second system transistor 12B. The first gate wiring 53A is electrically connected to a plurality of unit trench structures (a plurality of trench structures 35 and a plurality of trench connection structures 45) to be systematized (grouped) as the first system transistor 12A via the plurality of first via electrodes 54 in the output region 6.

The second gate wiring 53B is arranged in the interlayer insulating film 24 in a state where the second gate wiring 53B is electrically independent from the first gate wiring 53A. The second gate wiring 53B is electrically connected to the plurality of unit trench structures (the plurality of trench structures 35 and the plurality of trench connection structures 45) to be systematized (grouped) as the second system transistor 12B via the plurality of first via electrodes 54 in the output region 6. In this embodiment, the plurality of unit trench structures for the second system transistor 12B are systemized alternately with the plurality of unit trench structures for the first system transistor 12A.

On the other hand, the n gate wirings 53 for the monitor transistor 13 are electrically connected to at least one (in this embodiment, a plurality of) trench structure 35 and at least one (in this embodiment, a plurality of) trench connection structure 45 to be systematized (grouped) as the system monitor transistor 14 via the plurality of first via electrodes 54 in the current detection region 7, respectively. The number of trench structures 35 (the number of trench connection structures 45) forming the system monitor transistor 14 is less than the number of trench structures 35 (the number of trench connection structures 45) forming the system transistor 12.

Here, an example will be described in which the n gate wirings 53 for the monitor transistor 13 include a first gate wiring 53A for the first system monitor transistor 14A and a second gate wiring 53B for the second system monitor transistor 14B. The first gate wiring 53A is electrically connected to at least one trench structure 35 and at least one trench connection structure 45 to be systematized as the first system monitor transistor 14A via the plurality of first via electrodes 54 in the current detection region 7.

The second gate wiring 53B is arranged in the interlayer insulating film 24 in a state where the second gate wiring 53B is electrically independent from the first gate wiring 53A. The second gate wiring 53B is electrically connected to at least one trench structure 35 and at least one trench connection structure 45 to be systematized as the second system monitor transistor 14B via the plurality of first via electrodes 54 in the current detection region 7. The trench structure 35 for the second system monitor transistor 14B may be adjacent to the trench structure 35 for the first system monitor transistor 14A.

The first gate wiring 53A for the monitor transistor 13 may be formed integrally with the first gate wiring 53A for the main transistor 11. Further, the second gate wiring 53B for the monitor transistor 13 may be formed integrally with the second gate wiring 53B for the main transistor 11.

The semiconductor chip 1A includes a plurality of source wirings 55 arranged in the interlayer insulating film 24. The plurality of source wirings 55 include a first source wiring 55A for the main transistor 11 and a second source wiring 55B for the monitor transistor 13. The first source wiring 55A covers the output region 6 in the interlayer insulating film 24 and is electrically connected to a plurality of source regions 51 and a plurality of contact regions 52 via a plurality of second via electrodes 56. The plurality of second via electrodes 56 may contain tungsten.

The second source wiring 55B is selectively routed through a region between the current detection region 7 and the control region 8 within the interlayer insulating film 24. The second source wiring 55B is electrically connected to the plurality of source regions 51 and the plurality of contact regions 52 via the plurality of second via electrodes 56 in the current detection region 7 and is electrically connected to the control circuit 17 (the overcurrent protection circuit 20) in the control region 8.

The semiconductor chip 1A includes the source terminal 26 arranged on the interlayer insulating film 24. In this embodiment, the source terminal 26 overlaps a plurality of source wirings 55 (the first source wiring 55A and the second source wiring 55B) in a plan view and covers all the trench structures 35 and all the trench connection structures 45.

The source terminal 26 is electrically connected to the first source wiring 55A via a plurality of third via electrodes 57 arranged in the interlayer insulating film 24. The plurality of third via electrodes 57 are arranged in regions among the plurality of second via electrodes 56 in a plan view and a cross-sectional view. That is, in this embodiment, the plurality of third via electrodes 57 do not face the second via electrodes 56 with the first source wiring 55A interposed therebetween. Of course, the plurality of third via electrodes 57 may face the second via electrodes 56 with the first source wiring 55A interposed therebetween.

The source terminal 26 preferably has a thickness greater than that of the source wiring 55. The thickness of the source terminal 26 is preferably greater than the first depth D1 of the plurality of trench structures 35 (the second depth D2 of the trench connection structure 45). The thickness of the source terminal 26 is preferably greater than the thickness of the interlayer insulating film 24. The thickness of the source terminal 26 may be 1 μm or more and 25 μm or less.

The thickness of the source terminal 26 may be 1 μm or more and 5 μm or less, 5 μm or more and 10 μm or less, 10 μm or more and 15 μm or less, 15 μm or more and 20 μm or less, or 20 μm or more and 25 μm or less. In a case where the source terminal 26 contains Al-based metal as a main component, the thickness of the source terminal 26 may be 1 μm or more and 10 μm or less. In a case where the source terminal 26 contains Cu-based metal as a main component, the thickness of the source terminal 26 may be 10 μm or more and 25 μm or less.

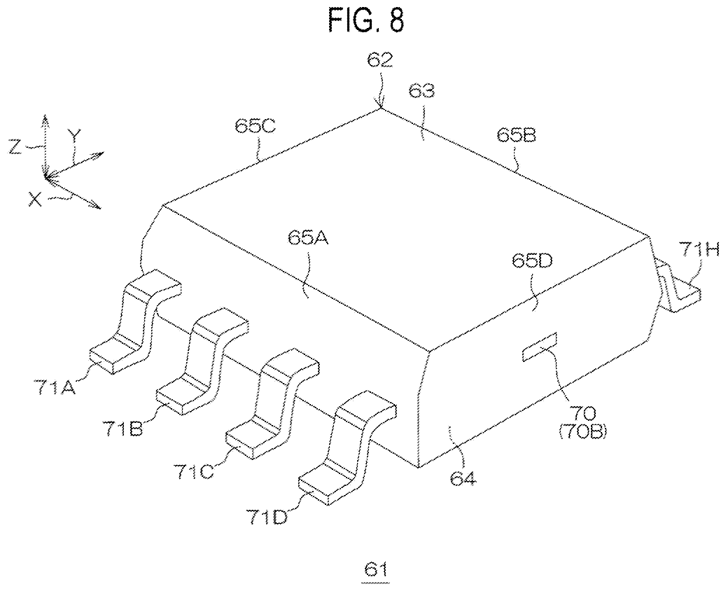

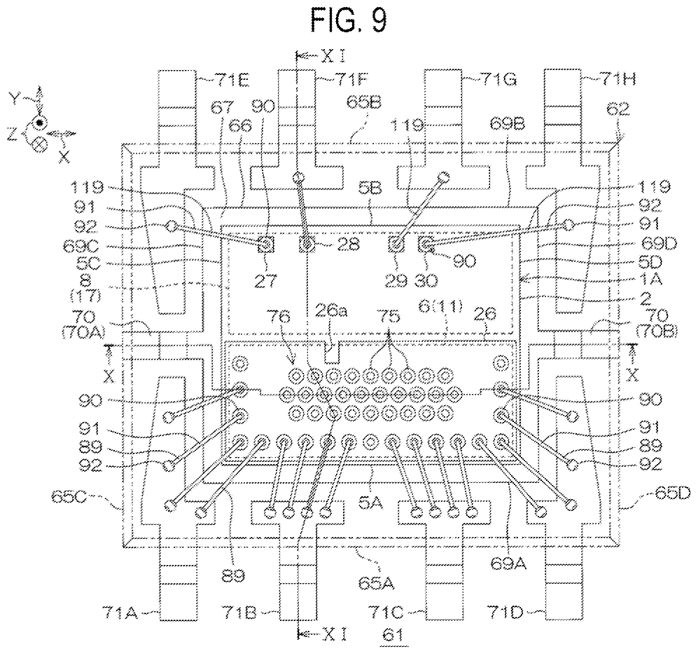

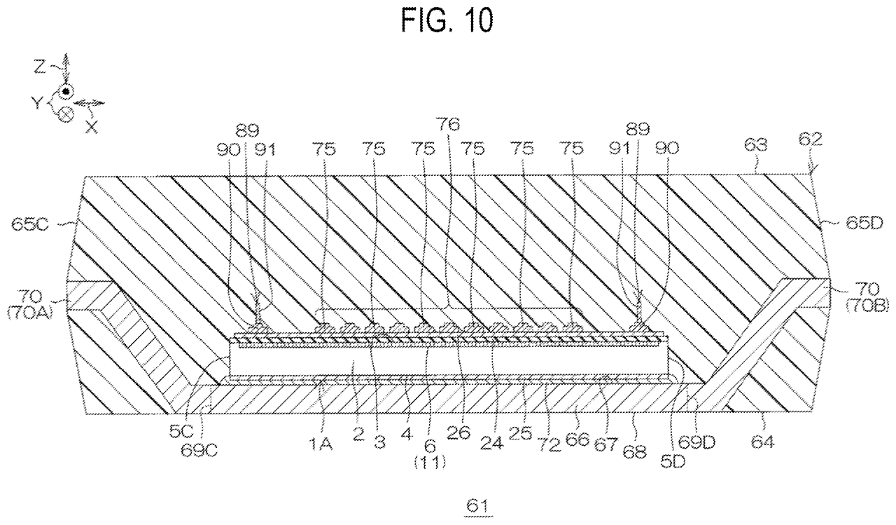

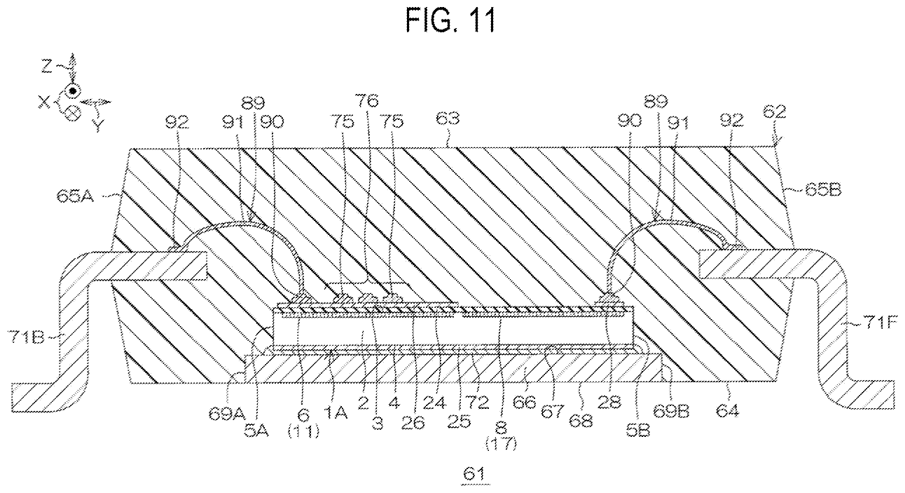

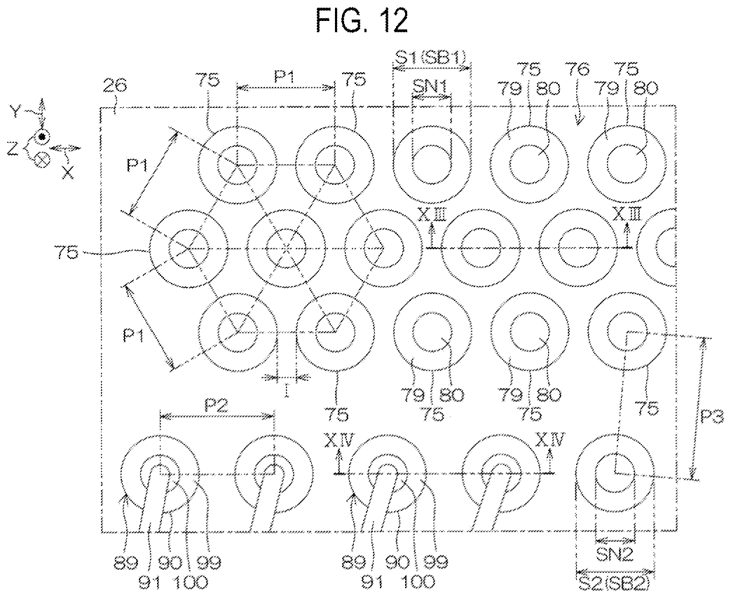

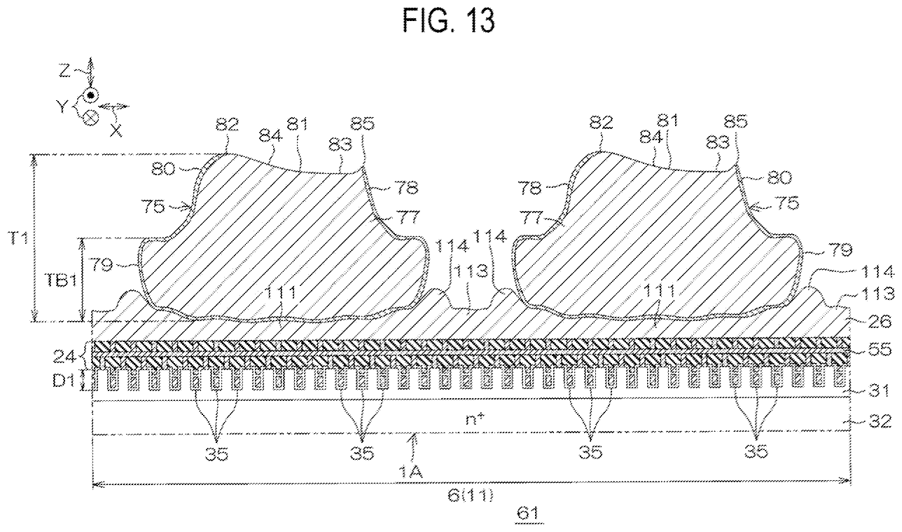

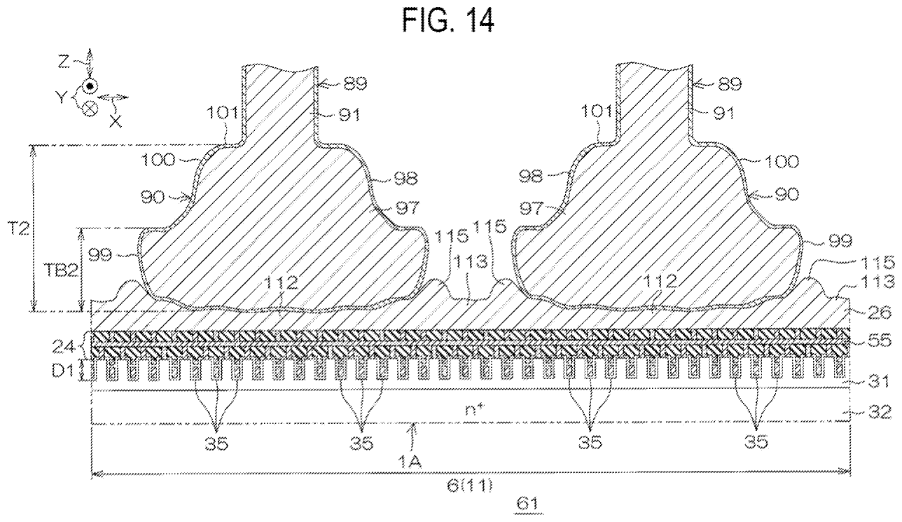

FIG. 8 is a perspective view showing a semiconductor device 61 on which the semiconductor chip 1A shown in FIG. 1 is mounted. FIG. 9 is a plan view showing the internal structure of the semiconductor device 61 shown in FIG. 8 together with pseudo-bumps 75 according to a first layout example. FIG. 10 is a cross-sectional view taken along line X-X shown in FIG. 9. FIG. 11 is a cross-sectional view taken along line XI-XI shown in FIG. 9. FIG. 12 is a plan view showing the pseudo-bumps 75 according to the first layout example. FIG. 13 is a cross-sectional view taken along line XIII-XIII shown in FIG. 12. FIG. 14 is a cross-sectional view taken along line XIV-XIV shown in FIG. 12.

Referring to FIGS. 8 to 14, the semiconductor device 61 may be called a “semiconductor package” or a “semiconductor module.” A package type of the semiconductor device 61 has various forms according to an environment of use, an object to be mounted, a form of the semiconductor chip 1A, and the like. Here, a form in which the semiconductor device 61 is an 8-terminal type SOP (Small Outline Package) is exemplified.

The semiconductor device 61 includes a rectangular parallelepiped package body 62. The package body 62 contains matrix resin and a plurality of fillers. The matrix resin may be a thermosetting resin (for example, epoxy resin). The plurality of fillers may be insulating spherical bodies (for example, silica particles).

The package body 62 has a first surface 63 on one side, a second surface 64 on the other side, and first to fourth side walls 65A to 65D connecting the first surface 63 and the second surface 64. The first surface 63 is a mounting surface and the second surface 64 is a non-mounting surface. The first surface 63 and the second surface 64 are formed in a quadrangular shape (in this embodiment, a rectangular shape extending in the first direction X) in a plan view.

The first side wall 65A and the second side wall 65B extend in the first direction X along the first main surface 3 and face each other in the second direction Y. The first side wall 65A and the second side wall 65B form long sides of the package body 62. The third side wall 65C and the fourth side wall 65D extend in the second direction Y and face each other in the first direction X. The third side wall 65C and the fourth side wall 65D form short sides of the package body 62.

The semiconductor device 61 includes a rectangular parallelepiped metal plate 66 arranged in the package body 62. The metal plate 66 may be called a “die pad” made of metal. The metal plate 66 has a first plate surface 67 on one side, a second plate surface 68 on the other side, and first to fourth plate side walls 69A to 69D connecting the first plate surface 67 and the second plate surface 68.

The first plate surface 67 and the second plate surface 68 are formed in a quadrangular shape (in this embodiment, a rectangular shape extending in the first direction X) in a plan view. The second plate surface 68 is exposed from the second surface 64 of the package body 62. Of course, the metal plate 66 may be arranged inside the package body 62 so that the second plate surface 68 is not exposed from the second surface 64.

The first plate side wall 69A and the second plate side wall 69B extend in the first direction X along the first main surface 3 and face each other in the second direction Y. The first plate side wall 69A and the second plate side wall 69B form long sides of the metal plate 66. The third plate side wall 69C and the fourth plate side wall 69D extend in the second direction Y and face each other in the first direction X. The third plate side wall 69C and the fourth plate side wall 69D form short sides of the metal plate 66.

The semiconductor device 61 includes at least one (in this embodiment, a plurality of) extension portion 70 drawn from the metal plate 66 toward at least one of the first to fourth side walls 65A to 65D within the package body 62. The plurality of extension portions 70 include a first extension portion 70A and a second extension portion 70B.

The first extension portion 70A is drawn in a strip shape from the third plate side wall 69C toward the third side wall 65C. In this embodiment, the first extension portion 70A has a bent portion bent toward the first surface 63 and is exposed from a portion of the third side wall 65C in the middle of a thickness range of the package body 62. The second extension portion 70B is drawn in a strip shape from the fourth plate side wall 69D toward the fourth side wall 65D. In this embodiment, the second extension portion 70B has a bent portion bent toward the first surface 63 and is exposed from a portion of the fourth side wall 65D in the middle of a thickness range of the package body 62.

The semiconductor device 61 includes first to eighth lead terminals 71A to 71H made of metal arranged inside the package body 62 at intervals from the metal plate 66 so as to be drawn from the inside to the outside of the package body 62. The first to fourth lead terminals 71A to 71D are arranged at intervals in the first direction X near the first side wall 65A and are formed in a strip shape extending in the second direction Y, respectively. The fifth to eighth lead terminals 71E to 71H are arranged at intervals in the first direction X near the second side wall 65B and are formed in a strip shape extending in the second direction Y, respectively.

The first to eighth lead terminals 71A to 71H each have an inner end portion, a strip portion, and an outer end portion. The inner end portion is arranged at a portion of the package body 62 in the middle of the thickness range of the package body 62 so as to be positioned near the first surface 63 with respect to a height position of the metal plate 66. The planar shape of the inner end portion is arbitrary. The strip portion is drawn out of the package body 62 from the inner end portion and is bent toward the second surface 64 outside the package body 62. The strip portion extends to a height position crossing the second surface 64 of the package body 62. The outer end portion extends substantially parallel to the second surface 64 of the package body 62 at a height position below the second surface 64.

The semiconductor device 61 includes the semiconductor chip 1A arranged on the metal plate 66 (the first plate surface 67) within the package body 62. The semiconductor chip 1A is arranged on the metal plate 66 with the drain terminal 25 facing the metal plate 66 (the first plate surface 67).

The semiconductor device 61 includes a conductive bonding material 72 interposed between the semiconductor chip 1A and the metal plate 66 within the package body 62. Specifically, the conductive bonding material 72 is interposed between the drain terminal 25 and the metal plate 66 to electrically and mechanically connect the drain terminal 25 and the metal plate 66. The conductive bonding material 72 may contain solder or metal paste. The solder may be lead-free solder. The metal paste may contain at least one of Au, Ag, and Cu. The Ag paste may be Ag sintered paste.

The semiconductor device 61 includes a plurality of pseudo-bumps 75 arranged on the source terminal 26 in a state of being opened from a wire in the package body 62. The plurality of pseudo-bumps 75 are each made of a metal lump formed by using a wire bonding process for the source terminal 26. The wire bonding process is performed by using a capillary (wire feeder) of a bonding apparatus.

In the wire bonding process, a wire is first fed to an inner hole of the capillary, and an initial ball is formed at a tip portion of the capillary by electrical discharge machining for the wire. Next, the initial ball is brought into contact with the source terminal 26, a load directed toward the source terminal 26 is applied to the initial ball, and at the same time, ultrasonic vibration is applied to the initial ball. As a result, the initial ball is crushed and, at the same time, compressed to the source terminal 26. Thereafter, the wire is separated from the crushed initial ball to form the pseudo-bumps 75 made of bump-shaped (for example, substantially columnar) metal lump.

The plurality of pseudo-bumps 75 are densely arranged on the source terminal 26. The term “dense” referred to herein means that an occupation area of the plurality of pseudo-bumps 75 with respect to the source terminal 26 is larger than that of other structures (genuine bumps 90 to be described later) connected to the source terminal 26. The plurality of pseudo-bumps 75 are arranged on the source terminal 26 with a first occupation area per unit plane area.

The plurality of pseudo-bumps 75 each have a first size S1 in a plan view. The first size S1 is defined by a length of the widest portion of the pseudo-bumps 75 in a plan view. The first size S1 may be 50 μm or more and 250 μm or less.

The first size S1 may be 50 μm or more and 75 μm or less, 75 μm or more and 100 μm or less, 100 μm or more and 125 μm or less, 125 μm or more and 150 μm or less, 150 μm or more and 175 μm or less, 175 μm or more and 200 μm or less, 200 μm or more and 225 μm or less, or 225 μm or more and 250 μm or less. The first size S1 is preferably 75 μm or more and 200 m or less. The first size S1 is more preferably 100 μm or more and 180 μm or less.

The plurality of pseudo-bumps 75 are arranged on the source terminal 26 at a first pitch P1 in a plan view. The first pitch P1 is defined by a distance between central portions of the plurality of pseudo-bumps 75. The plurality of pseudo-bumps 75 may be arranged to be in contact with each other at the first pitch P1, or may be arranged at intervals at the first pitch P1. The plurality of pseudo-bumps 75 are preferably arranged at intervals.

The first pitch P1 is preferably 1 to 2.5 times the first size S1. A ratio P1/S1 of the first pitch P1 to the first size S1 may be 1 or more and 1.25 or less, 1.25 or more and 1.5 or less, 1.5 or more and 1.75 or less, 1.75 or more and 2 or less, 2 or more and 2.25 or less, or 2.25 or more and 2.5 or less. The ratio P1/S1 is preferably greater than one. The ratio P1/S1 is more preferably 1.25 or more and 1.75 or less.

The first pitch P1 may be 50 μm or more and 250 μm or less. The first pitch P1 may be 50 μm or more and 75 μm or less, 75 μm or more and 100 μm or less, 100 μm or more and 125 μm or less, 125 μm or more and 150 μm or less, 150 μm or more and 175 μm or less, 175 μm or more and 200 μm or less, 200 μm or more and 225 μm or less, or 225 μm or more and 250 μm or less. The first pitch P1 is preferably 75 μm or more and 200 μm or less. The first pitch P1 is more preferably 100 μm or more and 180 μm or less.

The interval I among the plurality of pseudo-bumps 75 may be 0 μm or more and 100 m or less. The interval I may be 0 μm or more and 10 μm or less, 10 μm or more and 20 μm or less, 20 μm or more and 30 μm or less, 30 μm or more and 40 μm or less, 40 μm or more and 50 μm or less, 50 μm or more and 60 μm or less, 60 μm or more and 70 μm or less, 70 μm or more and 80 μm or less, 80 μm or more and 90 μm or less, or 90 μm or more and 100 μm or less. The interval I is preferably 10 μm or more. The interval I is more preferably 30 μm or more and 60 μm or less.

The plurality of pseudo-bumps 75 each have a first thickness T1. The first thickness T1 is defined by a thickness of the thickest portion of the pseudo-bumps 75 in a cross-sectional view. The first thickness T1 is preferably greater than the first depth D1 of the plurality of trench structures 35. The first thickness T1 is preferably greater than the thickness of the source terminal 26. The first thickness T1 is preferably greater than the thickness of the first semiconductor region 31. The first thickness T1 may be greater than the thickness of the substrate 2. Of course, the first thickness T1 may be smaller than the thickness of the substrate 2.

The first thickness T1 may be 10 μm or more and 150 μm or less. The first thickness T1 may be 10 μm or more and 25 μm or less, 25 μm or more and 50 μm or less, 50 μm or more and 75 μm or less, 75 μm or more and 100 μm or less, 100 μm or more and 125 μm or less, or 125 μm or more and 150 μm or less. The first thickness T1 is preferably 25 μm or more and 100 μm or less. The first thickness T1 is more preferably 50 μm or more.

At least three pseudo-bumps 75 are preferably arranged on the source terminal 26, as a pseudo-bump group 76. In this case, the at least three pseudo-bumps 75 are preferably arranged in a layout in which the at least three pseudo-bumps 75 are located at vertices of an isosceles triangle in a plan view. The isosceles triangle is more preferably an equilateral triangle.

At least seven pseudo-bumps 75 are preferably arranged on the source terminal 26, as a pseudo-bump group 76. In this case, six pseudo-bumps 75 are preferably arranged around one pseudo-bump 75 in a plan view. The six pseudo-bumps 75 are preferably arranged on a concentric circle centered on a central portion of the one pseudo-bump 75 in a plan view.

It is preferable that the six pseudo-bumps 75 are arranged in a layout in which the six pseudo-bumps 75 are located at vertices of a hexagon in a plan view and the one pseudo-bump 75 is arranged in a layout in which the one pseudo-bump 75 is located in the center of the hexagon in a plan view. That is, the plurality of pseudo-bumps 75 are preferably bonded to the source terminal 26 in a layout of hexagonal closest array (that is, a honeycomb array) in a plan view. In this case, the hexagon is most preferably a regular hexagon.

In this embodiment, a pseudo-bump group 76 including 28 pseudo-bumps 75 arranged in a hexagonal closest layout is bonded to the source terminal 26. Although the number of pseudo-bumps 75 bonded to the source terminal 26 is arbitrary, a pseudo-bump group 76 including at least three pseudo-bumps 75 and/or a pseudo-bump group 76 including at least seven pseudo-bumps 75 is preferably bonded to the source terminal 26. Of course, a plurality of pseudo-bump groups 76 may be bonded to the source terminal 26 with a distance greater than the first pitch P1 (the interval I).

Bonding points of the plurality of pseudo-bumps 75 (the pseudo-bump group 76) to the source terminal 26 may be set based on a temperature distribution of the semiconductor chip 1A. For example, a high-temperature region and a low-temperature region of the output region 6 may be analyzed by using thermography, a simulation tool, or the like, and the plurality of pseudo-bumps 75 (the pseudo-bump group 76) may be bonded to a portion of the source terminal 26 that covers the high-temperature region of the output region 6.

For example, the inner portion (for example, the central portion) of the output region 6 is more likely to rise in temperature than a peripheral edge portion of the output region 6. Therefore, the plurality of pseudo-bumps 75 (the pseudo-bump group 76) may be bonded to the source terminal 26 in such a layout that the pseudo-bumps 75 are dense in the inner portion (for example, the central portion) of the source terminal 26 and sparse in the peripheral portion of the source terminal 26. A form in which the plurality of pseudo-bumps 75 are “sparse” includes a form in which no pseudo-bumps 75 are present. In this embodiment, one pseudo-bump 75 is arranged along each of three sides of the peripheral portion of the source terminal 26.

The temperature of the control region 8 is lower than the temperature of the output region 6. In this embodiment, the source terminal 26 covers the output region 6 to expose the control region 8, and the plurality of pseudo-bumps 75 (the pseudo-bump group 76) are arranged in a region overlapping the output region 6 in a plan view. That is, the plurality of pseudo-bumps 75 (the pseudo-bump group 76) are arranged at a position overlapping the main transistor 11 in a plan view, and are not arranged in a region overlapping the control region 8 in a plan view.

Some of the plurality of pseudo-bumps 75 (the pseudo-bump group 76) may face the monitor transistor 13 in a plan view. That is, the plurality of pseudo-bumps 75 (the pseudo-bump group 76) may face the plurality of trench structures 35 for the main transistor 11 and the plurality of trench structures 35 for the monitor transistor 13. Of course, the plurality of pseudo-bumps 75 (the pseudo-bump group 76) may be arranged on the source terminal 26 so as not to face the plurality of trench structures 35 for the monitor transistor 13.

Each pseudo-bump 75 may face ten to two hundred trench structures 35. The number of trench structures 35 associated with and facing each pseudo-bump 75 may be 10 to 25, 25 to 50, 50 to 75, 75 to 100, 100 to 125, 125 to 150, 150 to 175, or 175 to 200. The number of trench structures 35 associated with and facing each pseudo-bump 75 is preferably 25 to 100.

A specific shape of one pseudo-bump 75 will be described below with reference to FIG. 13. In this embodiment, the pseudo-bump 75 includes a first bump body 77 and a first bump metal film 78. The first bump body 77 contains first metal. The first metal includes at least one of Cu-based metal, Al-based metal, Au-based metal, and Ag-based metal.

The Cu-based metal may include pure Cu or a Cu alloy. The Al-based metal may include pure Al or an Al alloy. The Au-based metal may include pure Au or an Au alloy. The Ag-based metal may include pure Ag or an Ag alloy. In this embodiment, the first bump body 77 contains pure Cu.

The first bump body 77 includes a first body portion 79 and a first neck portion 80. The first body portion 79 includes a wide portion connected to the source terminal 26. The first body portion 79 is formed in a substantially columnar shape having an outwardly curved side wall in a cross-sectional view. The first body portion 79 has a first body size SB1 forming the first size S1 of the pseudo-bump 75 in a plan view.

The first body portion 79 may have a first body thickness TB1 that is 0.1 to 0.9 times the first thickness T1 of the pseudo-bump 75. The first body thickness TB1 is preferably larger than the thickness of the first semiconductor region 31. The first body thickness TB1 may be larger than the thickness of the substrate 2. Of course, the first body thickness TB1 may be smaller than the thickness of the substrate 2.

A thickness ratio T1/TB1 of the first body thickness TB1 to the first thickness T1 is 0.1 or more and 0.2 or less, 0.2 or more and 0.3 or less, 0.3 or more and 0.4 or less, 0.4 or more and 0.5 or less, 0.5 or more and 0.6 or less, 0.6 or more and 0.7 or less, 0.7 or more and 0.8 or less, or 0.8 or more and 0.9 or less. The thickness ratio T1/TB1 is preferably 0.4 or more and 0.7 or less. The thickness ratio T1/TB1 is more preferably 0.5 or more.

The first neck portion 80 includes a portion which is narrower than the first body portion 79 and protrudes from the first body portion 79 toward the opposite side of the source terminal 26. The first neck portion 80 is formed in a substantially columnar shape in a cross-sectional view. In this embodiment, the first neck portion 80 has a first upper end portion 81 that slopes downward. Specifically, the first upper end portion 81 may have an upper end apex portion 82, an upper end base portion 83, and an inclined portion 84 in a cross-sectional view.

The upper end apex portion 82 is formed on one side of a peripheral portion of the first upper end portion 81 in a cross-sectional view. The upper end base portion 83 is formed on the other side of the peripheral portion of the first upper end portion 81 in a cross-sectional view and is located near the first body portion 79 with respect to a height position of the upper end apex portion 82. The inclined portion 84 is inclined downward from the upper end apex portion 82 toward the upper end base portion 83 in a cross-sectional view. The first upper end portion 81 may have an upper end protrusion portion 85 that protrudes toward the opposite side of the first body portion 79 in the upper end base portion 83. A tip portion of the upper end protrusion portion 85 may be formed at a height position near the first body portion 79 with respect to a height position of a tip portion of the upper end apex portion 82.

The first neck portion 80 has a first neck size SN1 smaller than the first body size SB1 in a plan view. The first neck size SN1 may be 0.1 to 0.9 times the first body size SB1 (the first size S1).

A size ratio SN1/SB1 of the first neck size SN1 to the first body size SB1 is 0.1 or more and 0.2 or less, 0.2 or more and 0.3 or less, 0.3 or more and 0.4 or less, 0.4 or more and 0.5 or less, 0.5 or more and 0.6 or less, 0.6 or more and 0.7 or less, 0.7 or more and 0.8 or less, or 0.8 or more and 0.9 or less. The size ratio SN1/SB1 is preferably 0.5 or more and 0.7 or less. The size ratio SN1/SB1 is more preferably greater than 0.5.

The first bump metal film 78 contains second metal different from the first metal of the first bump body 77 and covers at least a portion of an outer surface of the first bump body 77. The first bump metal film 78 covers a region outside the upper end apex portion 82 of the outer surface of the first bump body 77 to expose the upper end apex portion 82.

Although FIG. 13 shows a shape in which the first bump metal film 78 covers the entire region outside the upper end apex portion 82, the first bump metal film 78 may not have such a shape. Further, the shape of the first bump metal film 78 among the plurality of pseudo-bumps 75 is not fixed and may not be defined as a fixed shape.

For example, the first bump metal film 78 may cover at least a portion of the outer surface of the first bump body 77 to partially expose the first bump body 77 (the first metal) in the region outside the upper end apex portion 82. A portion of the first bump metal film 78 may be located inside the first bump body 77.

For example, a portion of the first bump metal film 78 may melt into the inside of the first bump body 77. For example, a cover area of the first bump metal film 78 with respect to the first bump body 77 may be smaller than an exposure area of the first bump body 77 with respect to the first bump metal film 78. Of course, the cover area of the first bump metal film 78 with respect to the first bump body 77 may be equal to or larger than the exposure area of the first bump body 77 with respect to the first bump metal film 78.

The first bump metal film 78 is preferably formed of a plating film. The first bump metal film 78 preferably includes at least one of a Ni plating film, a Pd plating film, and an Au plating film. For example, the first bump metal film 78 may have a laminated structure including a Ni plating film, a Pd plating film, and an Au plating film laminated in this order from the first bump body 77.

For example, the first bump metal film 78 may have a laminated structure including a Ni plating film and a Pd plating film laminated in this order from the first bump body 77. For example, the first bump metal film 78 may have a single-layer structure including a Ni plating film, a Pd plating film, or an Au plating film.

The semiconductor device 61 includes at least one (in this embodiment, a plurality of) first bonding wire 89 arranged within the package body 62. The plurality of first bonding wires 89 electrically connect the source terminal 26 to at least one connection object (the first to fourth lead terminals 71A to 71D in this embodiment) selected among the first to eighth lead terminals 71A to 71H. The number of first bonding wires 89 may be one or more and is not limited to a specific number.

In this embodiment, four first bonding wires 89 are connected to the source terminal 26 and the first lead terminal 71A, four first bonding wires 89 are connected to the source terminal 26 and the second lead terminal 71B, four first bonding wires 89 are connected to the source terminal 26 and the third lead terminal 71C, and four first bonding wires 89 are connected to the source terminal 26 and the fourth lead terminal 71D.

The plurality of first bonding wires 89 each include a genuine bump 90, a wire loop 91, and a wire tail 92. The genuine bump 90 is a lump of metal bonded to the source terminal 26 in a state of being connected to a wire (the wire loop 91). The wire loop 91 is a wire portion that extends in an arch shape through a region between the genuine bump 90 and the connection object. The wire tail 92 is a wire end portion that is bonded to the connection object. The plurality of first bonding wires 89 are formed by a wire bonding process in which a capillary (wire feeder) of a bonding apparatus is used.

In the wire bonding process, a wire is first fed to the inner hole of the capillary, and an initial ball is formed at the tip portion of the capillary by electrical discharge machining for the wire. Next, the initial ball is brought into contact with the source terminal 26, a load directed toward the source terminal 26 is applied to the initial ball, and at the same time, ultrasonic vibration is applied to the initial ball. As a result, the initial ball is crushed and, at the same time, compressed to the source terminal 26. Further, the genuine bump 90 made of bump-shaped (for example, substantially columnar) metal lump is formed.

Next, the capillary is moved from a top of the genuine bump 90 to a top of the connection object while the wire is being pulled out. Thus, an arch-shaped wire loop 91 is formed between the genuine bump 90 and the connection object. Next, a portion of the wire loop 91 is brought into contact with the connection object, and a load directed toward the connection object is applied to the wire loop 91, and at the same time, ultrasonic vibration is applied to the wire loop 91. As a result, a portion of the wire loop 91 is crushed and, at the same time, compressed to the connection target. Thereafter, the wire is separated from the compressed portion of the wire loop 91 to form the wire tail 92.

A shape of a plurality of genuine bumps 90 will be described below. The plurality of genuine bumps 90 are arranged on the source terminal 26 at intervals from the plurality of pseudo-bumps 75 (the pseudo-bump group 76). In this embodiment, the plurality of genuine bumps 90 are arranged on a peripheral edge of the source terminal 26 at intervals along the peripheral edge of the source terminal 26. An arrangement location of the plurality of genuine bumps 90 is not limited to a specific arrangement location as long as it is an empty region between the peripheral edge of the source terminal 26 and the plurality of pseudo-bumps 75 (the pseudo-bump group 76).

The plurality of genuine bumps 90 are arranged on the source terminal 26 more sparsely than the plurality of pseudo-bumps 75. The term “sparse” referred to herein means that an occupation area of the plurality of genuine bumps 90 with respect to the source terminal 26 is smaller than an occupation area of the plurality of pseudo-bumps 75 with respect to the source terminal 26.

Even in a case where only a single genuine bump 90 is arranged on the source terminal 26 and an occupation area of the single genuine bump 90 is smaller than the occupation area of the plurality of pseudo-bumps 75, such an arrangement is included in the shape of “sparse” arrangement. That is, one or more genuine bumps 90 may be arranged on the source terminal 26 with a second occupation area smaller than the first occupation area of the plurality of pseudo-bumps 75 per unit plane area.

The plurality of genuine bumps 90 each have a second size S2 in a plan view. The second size S2 is defined by a length of the widest portion of the genuine bump 90 in a plan view. The second size S2 may be 50 μm or more and 250 μm or less.

The second size S2 may be 50 μm or more and 75 μm or less, 75 μm or more and 100 μm or less, 100 μm or more and 125 μm or less, 125 μm or more and 150 μm or less, 150 μm or more and 175 μm or less, 175 μm or more and 200 μm or less, 200 μm or more and 225 μm or less, or 225 μm or more and 250 μm or less. The second size S2 is preferably 75 μm or more and 200 μm or less. The second size S2 is more preferably 100 μm or more and 180 μm or less.

The second size S2 may be equal to or larger than the first size S1 of the pseudo-bump 75, or may be smaller than the first size S1. The second size S2 is preferably approximately equal to the first size S1. According to this configuration, the pseudo-bump 75 and the genuine bump 90 may be formed under the same manufacturing conditions in terms of size.

The plurality of genuine bumps 90 are arranged on the source terminal 26 at a second pitch P2 that is equal to or greater than the first pitch P1 of the pseudo-bump 75 in a plan view. The second pitch P2 is defined by a distance between central portions of two genuine bumps 90 adjacent to each other. The plurality of genuine bumps 90 are preferably arranged to be spaced apart from one another at the second pitch P2 so as not to contact one another.

The second pitch P2 may take any value, as long as the genuine bump 90 is entirely located within a range surrounded by the peripheral edge of the source terminal 26 and the second pitch P2 satisfies a condition that it is equal to or greater than the first pitch P1. As an example, a pitch ratio P2/P1 of the second pitch P2 to the first pitch P1 may be 1 or more and 20 or less. The pitch ratio P2/P1 may be 1 or more and 2 or less, 2 or more and 5 or less, 5 or more and 10 or less, 10 or more and 15 or less, or 15 or more and 20 or less. The pitch ratio P2/P1 is preferably greater than 1.

The plurality of genuine bumps 90 are arranged on the source terminal 26 at a third pitch P3 based on one adjacent pseudo-bump 75. The third pitch P3 is defined by a distance between central portions of a pseudo-bump 75 and a genuine bump 90 that are adjacent to each other. The third pitch P3 is preferably equal to or greater than the first pitch P1 of the pseudo-bump 75. At least one genuine bump 90 is preferably arranged at the third pitch P3 which is larger than the first pitch P1. In this embodiment, all genuine bumps 90 are arranged at the third pitch P3 which is larger than the first pitch P1.

The third pitch P3 takes any value, as long as the genuine bump 90 is entirely located within a range surrounded by the peripheral edge of the source terminal 26 and the third pitch P3 satisfies a condition that it is equal to or greater than the first pitch P1. For example, a pitch ratio P3/P1 of the third pitch P3 to the first pitch P1 may be 1 or more and 20 or less. The pitch ratio P3/P1 may be 1 or more and 2 or less, 2 or more and 5 or less, 5 or more and 10 or less, 10 or more and 15 or less, or 15 or more and 20 or less.

The plurality of genuine bumps 90 each have a second thickness T2. The second thickness T2 is defined by a thickness of the thickest portion of the genuine bump 90 in a cross-sectional view. The second thickness T2 is preferably larger than the first depth D1 of the plurality of trench structures 35. The second thickness T2 is preferably larger than the thickness of the source terminal 26. The second thickness T2 is preferably larger than the thickness of the first semiconductor region 31. The second thickness T2 may be larger than the thickness of the substrate 2. Of course, the second thickness T2 may be smaller than the thickness of the substrate 2.

The second thickness T2 may be 10 μm or more and 150 μm or less. The second thickness T2 may be 10 μm or more and 25 μm or less, 25 μm or more and 50 μm or less, 50 m or more and 75 μm or less, 75 μm or more and 100 μm or less, 100 μm or more and 125 μm or less, or 125 μm or more and 150 μm or less. The second thickness T2 is preferably 25 μm or more and 100 μm or less. The second thickness T2 is more preferably 50 μm or more.

The second thickness T2 may be equal to or greater than the first thickness T1 of the pseudo-bump 75, or may be less than the first thickness T1. The second thickness T2 is preferably approximately equal to the first thickness T1. According to this configuration, the pseudo-bump 75 and the genuine bump 90 may be formed under the same manufacturing conditions in terms of thickness.

The plurality of genuine bumps 90 are arranged in a region overlapping the output region 6 in a plan view. That is, the plurality of genuine bumps 90 are arranged at a position overlapping the main transistor 11 in a plan view and are not arranged in a region overlapping the control region 8 in a plan view. Some of the plurality of genuine bumps 90 may face the monitor transistor 13 in a plan view.

That is, the plurality of genuine bumps 90 may face the plurality of trench structures 35 for the main transistor 11 and the plurality of trench structures 35 for the monitor transistor 13. Of course, the plurality of genuine bumps 90 may be arranged on the source terminal 26 so as not to face the plurality of trench structures 35 for the monitor transistor 13.

Each genuine bump 90 may face ten to two hundred trench structures 35. The number of trench structures 35 associated with and facing each genuine bump 90 may be 10 to 25, 25 to 50, 50 to 75, 75 to 100, 100 to 125, 125 to 150, 150 to 175, or 175 to 200. The number of trench structures 35 associated with and facing each genuine bump 90 is preferably 25 to 100.

A specific shape of one genuine bump 90 will be described below with reference to FIG. 14. In this embodiment, the genuine bump 90 includes a second bump body 97 and a second bump metal film 98. The second bump body 97 contains first metal. The first metal includes at least one of Cu-based metal, Al-based metal, Au-based metal, and Ag-based metal.

The Cu-based metal may contain pure Cu or a Cu alloy. The Al-based metal may contain pure Al or an Al alloy. The Au-based metal may contain pure Au or an Au alloy. The Ag-based metal may include pure Ag or an Ag alloy. In this embodiment, the second bump body 97 contains pure Cu. The second bump body 97 preferably contains the same metal as the first bump body 77 of the pseudo-bump 75. Of course, the second bump body 97 may contain metal different from the first bump body 77.

The second bump body 97 includes a second body portion 99 and a second neck portion 100. The second body portion 99 includes a wide portion connected to the source terminal 26. The second body portion 99 is formed in a substantially columnar shape having an outwardly-curved side wall in a cross-sectional view. The second body portion 99 has a second body size SB2 forming the second size S2 of the genuine bump 90 in a plan view.

The second body portion 99 may have a second body thickness TB2 that is 0.1 to 0.9 times the second thickness T2 of the genuine bump 90. The body thickness TB2 is preferably larger than the thickness of the first semiconductor region 31. The second body thickness TB2 may be larger than the thickness of the substrate 2. Of course, the second body thickness TB2 may be smaller than the thickness of the substrate 2.

A thickness ratio T2/TB2 of the second body thickness TB2 to the second thickness T2 is 0.1 or more and 0.2 or less, 0.2 or more and 0.3 or less, 0.3 or more and 0.4 or less, 0.4 or more and 0.5 or less, 0.5 or more and 0.6 or less, 0.6 or more and 0.7 or less, 0.7 or more and 0.8 or less, or 0.8 or more and 0.9 or less. The thickness ratio T2/TB2 is preferably 0.4 or more and 0.7 or less. The thickness ratio T2/TB2 is more preferably 0.5 or more. The second body thickness TB2 may be approximately equal to the first body thickness TB1 of the pseudo-bump 75.

The second neck portion 100 includes a portion which is narrower than the second body portion 99 and protrudes from the second body portion 99 toward the opposite side of the source terminal 26. The second neck portion 100 is formed in a substantially columnar shape in a cross-sectional view. The second neck portion 100 includes a second upper end portion 101 connected to the wire loop 91. Unlike the first upper end portion 81 of the first neck portion 80, the second upper end portion 101 does not include the upper end apex portion 82, the upper end base portion 83, and the inclined portion 84.

The second neck portion 100 has a second neck size SN2 smaller than the second body size SB2 in a plan view. The second neck size SN2 may be 0.1 to 0.9 times the second body size SB2 (the first size S1).

A size ratio SN2/SB2 of the second neck size SN2 to the second body size SB2 is 0.1 or more and 0.2 or less, 0.2 or more and 0.3 or less, 0.3 or more and 0.4 or less, 0.4 or more and 0.5 or less, 0.5 or more and 0.6 or less, 0.6 or more and 0.7 or less, 0.7 or more and 0.8 or less, or 0.8 or more and 0.9 or less. The size ratio SN2/SB2 is preferably 0.5 or more and 0.7 or less. The size ratio SN2/SB2 is more preferably larger than 0.5. The second neck size SN2 may be approximately equal to the first neck size SN1 of the pseudo-bump 75.

The second bump metal film 98 contains second metal different from the first metal of the second bump body 97 and covers at least a portion of the outer surface of the second bump body 97. The second bump metal film 98 also covers at least a portion of the outer surface of the wire loop 91 and at least a portion of the outer surface of the wire tail 92.

Although FIG. 14 shows a shape in which the second bump metal film 98 covers the entire outer surface of the second bump body 97, the second bump metal film 98 may not have such a shape. Further, the shape of the second bump metal film 98 among the plurality of genuine bumps 90 is not fixed and may not be defined as a fixed shape.

For example, the second bump metal film 98 may cover at least a portion of the outer surface of the second bump body 97 to partially expose the second bump body 97 (the first metal). A portion of the second bump metal film 98 may be located inside the second bump body 97.

For example, a portion of the second bump metal film 98 may melt into the inside of the second bump body 97. For example, the cover area of the second bump metal film 98 with respect to the second bump body 97 may be smaller than the exposure area of the second bump body 97 with respect to the second bump metal film 98. Of course, the cover area of the second bump metal film 98 with respect to the second bump body 97 may be equal to or larger than the exposure area of the second bump body 97 with respect to the second bump metal film 98.

The second bump metal film 98 is preferably formed of a plating film. The second bump metal film 98 preferably includes at least one of a Ni plating film, a Pd plating film, and an Au plating film. For example, the second bump metal film 98 may have a laminated structure including a Ni plating film, a Pd plating film, and an Au plating film laminated in this order from the second bump body 97.

For example, the second bump metal film 98 may have a laminated structure including a Ni plating film and a Pd plating film laminated in this order from the second bump body 97. For example, the second bump metal film 98 may have a single-layer structure including a Ni plating film, a Pd plating film, or an Au plating film. The second bump metal film 98 preferably has the same configuration as the first bump metal film 78 of the pseudo-bump 75.

Referring to FIGS. 13 and 14, the semiconductor device 61 includes a plurality of first thin film portions 111, a plurality of second thin film portions 112, and a thick film portion 113 formed on the source terminal 26. The plurality of first thin film portions 111 are respectively made up of portions of the source terminal 26 subsided along with the bonding of the plurality of pseudo-bumps 75, and are respectively formed at the bonding portions of the plurality of pseudo-bumps 75 in the source terminal 26.

The plurality of second thin film portions 112 are respectively made up of portions of the source terminal 26 subsided along with the bonding of the plurality of genuine bumps 90, and are respectively formed at the bonding portions of the plurality of genuine bumps 90 in the source terminal 26. The thick film portion 113 is made up of a portion which is free from subsidence due to the bonding of the plurality of pseudo-bumps 75 and the plurality of genuine bumps 90, and is formed in a region outside the bonding portion of the plurality of pseudo bumps 75 and the bonding portion of the plurality of genuine bumps 90 in the source terminal 26.

The maximum thickness of the thick film portion 113 may be larger than the minimum thickness of the first thin film portion 111 (the second thin film portion 112) and may be 2.5 times or less the minimum thickness of the first thin film portion 111 (the second thin film portion 112). A thickness ratio of the maximum thickness to the minimum thickness is more than 1 and 1.25 or less, 1.25 or more and 1.5 or less, 1.5 or more and 1.75 or less, 1.75 or more and 2 or less, 2 or more and 2.25 or less, or 2.25 or more and 2.5 or less.

The semiconductor device 61 includes a plurality of first raised portions 114 formed on the source terminal 26. The plurality of first raised portions 114 are formed at the bonding edges of the plurality of pseudo-bumps 75 in the source terminal 26 and are made up of a portion of the source terminal 26 thicker than the thick film portion 113. Each first raised portion 114 extends annularly along the edge (bonding edge) of each pseudo-bump 75 in a plan view. At least a portion of each first raised portion 114 faces the peripheral edge portion of each pseudo-bump 75 in the thickness direction.

A portion of the source terminal 26 along the edge of each pseudo-bump 75 is made thicker than the first thin film portion 111 (the second thin film portion 112) by the thick film portion 113 and the first raised portion 114. Further, portions of the source terminal 26 located among the plurality of pseudo-bumps 75 are made thicker than the plurality of first thin film portions 111 (second thin film portions 112) by the thick film portion 113 and the plurality of first raised portions 114.

The portions of the source terminal 26 located among the plurality of pseudo-bumps 75 preferably face the plurality of trench structures 35. That is, it is preferable that the thick film portion 113 and the plurality of first raised portions 114 face the plurality of trench structures 35 in regions among the plurality of pseudo-bumps 75.

Each of the first raised portions 114 faces at least one trench structure 35 in the thickness direction. In this embodiment, each first raised portion 114 is formed to face the plurality of trench structures 35 in the thickness direction. A raising height of at least one first raised portion 114 based on the thick film portion 113 is preferably larger than the first depth D1 of the trench structure 35. The raising height of the at least one first raised portion 114 may be larger than the thickness of the first semiconductor region 31. Of course, the raising height of the at least one first raised portion 114 may be equal to and less than the first depth D1 of the trench structure 35.

A first total thickness of the thick film portion 113 and the first raised portion 114 is preferably larger than the thickness of the interlayer insulating film 24. The first total thickness may be more than 1 time the minimum thickness of the first thin film portion 111 (the second thin film portion 112) and 10 times or less the minimum thickness of the first thin film portion 111 (the second thin film portion 112). A thickness ratio of the first total thickness to the minimum thickness may be more than 1 and 2 or less, 2 or more and 4 or less, 4 or more and 6 or less, 6 or more and 8 or less, or 8 or more and 10 or less. The thickness ratio is preferably 2 or more and 6 or less.

The first raised portion 114 formed near one pseudo-bump 75 may be integrated with the first raised portion 114 formed near the other pseudo-bump 75. That is, portions of the source terminal 26 located among the plurality of pseudo-bumps 75 may be thicker than the plurality of first thin film portions 111 (second thin film portions 112) due to the first raised portion 114 which may be regarded as one. It is preferable that the first raised portion 114, which may be regarded as one, faces the plurality of trench structures 35.

The semiconductor device 61 includes a plurality of second raised portions 115 formed on the source terminal 26. The plurality of second raised portions 115 are formed at the bonding edges of the plurality of genuine bumps 90 in the source terminal 26 and include a portion of the source terminal 26 thicker than the thick film portion 113. Each second raised portion 115 extends annularly along the edge (bonding edge) of each genuine bump 90 in a plan view. At least a portion of each second raised portion 115 faces the peripheral edge portion of each genuine bump 90 in the thickness direction.

A portion of the source terminal 26 along the edge of each genuine bump 90 is made thicker than the first thin film portion 111 (the second thin film portion 112) by the thick film portion 113 and the second raised portion 115. Further, portions of the source terminal 26 located among the plurality of genuine bumps 90 are made thicker than the first thin film portion 111 (the second thin film portion 112) by the thick film portion 113 and the plurality of second raised portions 115. Further, a portion of the source terminal 26 located between the pseudo-bump 75 and the genuine bump 90 is thickened by the thick film portion 113 and the plurality of second raised portions 115. At least a portion of each second raised portion 115 faces the peripheral edge portion of each genuine bump 90 in the thickness direction.

Each second raised portion 115 faces at least one trench structure 35 in the thickness direction. In this embodiment, each second raised portion 115 is formed to face the plurality of trench structures 35 in the thickness direction. A raising height of at least one second raised portion 115 based on the thick film portion 113 is preferably larger than the first depth D1 of the trench structure 35. The raising height of the at least one second raised portion 115 may be larger than the thickness of the first semiconductor region 31. Of course, the raising height of the at least one second raised portion 115 may be equal to or less than the first depth D1 of the trench structure 35.

The second total thickness of the thick film portion 113 and the second raised portion 115 is preferably larger than the thickness of the interlayer insulating film 24. The second total thickness may be 1 time or more the minimum thickness of the first thin film portion 111 (the second thin film portion 112) and 10 times or less than the minimum thickness of the first thin film portion 111 (the second thin film portion 112). The thickness ratio of the second total thickness to the minimum thickness may be more than 1 and 2 or less, 2 or more and 4 or less, 4 or more and 6 or less, 6 or more and 8 or less, or 8 or more and 10 or less. The thickness ratio is preferably 2 or more and 6 or less.

The semiconductor device 61 includes at least one (in this embodiment, a plurality of) second bonding wire 119 arranged within the package body 62. The plurality of second bonding wires 119 electrically connect the first to fourth control terminals 27 to 30 to at least one connection object (in this embodiment, the fifth to eighth lead terminals 71E to 71H) selected among the first to eighth lead terminals 71A to 71H.

The number of second bonding wires 119 for the first to fourth control terminals 27 to 30 may be one or more, and is not limited to a specific number. In this embodiment, one second bonding wire 119 is connected to the first control terminal 27 and the fifth lead terminal 71E, and one second bonding wire 119 is connected to the second control terminal 28 and the sixth lead terminal 71F. One second bonding wire 119 is connected to the third control terminal 29 and the seventh lead terminal 71G, and one second bonding wire 119 is connected to the fourth control terminal 30 and the eighth lead terminal 71H.

The plurality of second bonding wires 119 each include a genuine bump 90, a wire loop 91, and a wire tail 92, similar to the first bonding wire 89. Further, the plurality of second bonding wires 119 include a second bump body 97 and a second bump metal film 98 in the genuine bump 90, similar to the first bonding wire 89.

It is preferable that the genuine bump 90 is bonded to the first to fourth control terminals 27 to 30 and the wire tail 92 is bonded to the fifth to eighth lead terminals 71E to 71H. Of course, the genuine bump 90 may be bonded to the fifth to eighth lead terminals 71E to 71H and the wire tail 92 may be bonded to the first to fourth control terminals 27 to 30. Other description of the second bonding wire 119 is omitted as the description of the first bonding wire 89 applies.

As described above, the semiconductor device 61 includes the substrate 2, the output region 6 (device region), the source terminal 26 (terminal), the plurality of pseudo-bumps 75, and at least one genuine bump 90. The output region 6 is provided in the substrate 2. The source terminal 26 covers the output region 6 in a plan view. The plurality of pseudo-bumps 75 are densely arranged on the source terminal 26 in a state where they are opened from the wire. The at least one genuine bump 90 is arranged on the source terminal 26 more sparsely than the plurality of pseudo-bumps 75 in a state where the at least one genuine bump 90 is connected to the wire.

That is, the plurality of pseudo-bumps 75 are arranged on the source terminal 26 with the first occupation area per unit plane area, and the at least one genuine bump 90 is arranged on the source terminal 26 with the second occupation area less than the first occupation area per unit plane area. With this configuration, heat generated in the output region 6 may be absorbed by the plurality of pseudo-bumps 75. As a result, temperature rise of the output region 6 may be suppressed, and deterioration of electrical characteristics of the output region 6 due to the temperature rise may be suppressed. Therefore, it is possible to provide the semiconductor device 61 capable of improving the electrical characteristics.

The arrangement locations of the plurality of pseudo-bumps 75 with respect to the source terminal 26 may be set based on a temperature distribution of the semiconductor chip 1A. For example, a high-temperature region and a low-temperature region of the output region 6 may be analyzed by using thermography, a simulation tool, or the like, and the plurality of pseudo-bumps 75 may be densely arranged in a portion of the source terminal 26 covering the high-temperature region of the output region 6 and the plurality of pseudo-bumps 75 may be sparsely arranged in a portion of the source terminal 26 covering the low-temperature region of the output region 6. At least one genuine bump 90 is arranged in a portion where the plurality of pseudo-bumps 75 are sparsely arranged.

For example, the inner portion of the output region 6 is more likely to rise in temperature than the peripheral edge portion of the output region 6. Therefore, the plurality of pseudo-bumps 75 may be bonded to the source terminal 26 in such a layout that the pseudo-bumps 75 are dense in the inner portion of the source terminal 26 and sparse in the peripheral edge portion of the source terminal 26. A form in which the plurality of pseudo-bumps 75 are “sparse” includes a form in which no pseudo-bumps 75 are present.

As another means that absorbs the heat generated in the device region, it is considered that a relatively thick plating terminal film (for example, a Cu plating film of 10 μm or more and 25 μm or less) is formed on the source terminal 26 or as the source terminal 26 in a wafer stage.

In this case, the cost increases due to the equipment (a film-forming apparatus, a plating liquid, etc.) required for forming the plating terminal film, and warpage occurs in the wafer due to the plating terminal film. The wafer warpage degrades electrical characteristics and physical characteristics of the wafer. For example, in a case where cracks or crystal defects occur in the wafer due to the wafer warpage, electrical characteristics of the device region will fluctuate. Further, the wafer warpage may also be an obstacle in a dicing process or the like.

On the other hand, in the semiconductor device 61, a plurality of pseudo-bumps 75 may be bonded to the semiconductor chip 1A in a packaging process of the semiconductor chip 1A segmented from the wafer through the dicing process. Therefore, the equipment necessary for forming the plating terminal film is not required. Further, since the wafer warpage at the wafer stage may be suppressed, the semiconductor chip 1A with suppressed cracks and crystal defects may be obtained. Further, relatively thick pseudo-bumps 75 may be formed by using a relatively inexpensive wire bonding process used in the process of forming the genuine bump 90. Therefore, the electrical characteristics may be improved while suppressing the cost.

Of course, the pseudo-bumps 75 may be bonded to the plating terminal film formed on the terminal (the source terminal 26) or the plating terminal film formed as the terminal (the source terminal 26). In this case, the heat absorption effect by the plurality of pseudo-bumps 75 may be added to the heat absorption effect of the plating terminal film. However, it should be noted that in a case where an amount of heat that may be absorbed by the plating terminal film is already saturated, there is little advantage in bonding the plurality of pseudo-bumps 75 to the plating terminal film.

The plurality of pseudo-bumps 75 are preferably thicker than the source terminal 26. According to this configuration, the source terminal 26 may be thinned by forming the plurality of relatively thick pseudo-bumps 75. Therefore, heat may be transferred to the plurality of pseudo-bumps 75 via the relatively thin source terminal 26, and the cost of forming the source terminal 26 may be suppressed.

For example, by employing the plurality of relatively thick pseudo-bumps 75, the source terminal 26 including a Cu-based metal film or an Al-based metal film and having a thickness of 1 μm or more and 10 μm or less may be employed. Since such a source terminal 26 may be formed by a sputtering method, it may be formed of an electrode film other than the plating film.

A plurality of genuine bumps 90 are preferably sparsely arranged on the source terminal 26. That is, it is preferable not to impose a design rule that the plurality of genuine bumps 90 be densely arranged. According to this configuration, the plurality of genuine bumps 90 may be connected to appropriate positions of the source terminal 26. The plurality of pseudo-bumps 75 may be arranged on the source terminal 26 at the first pitch P1. In this case, the plurality of genuine bumps 90 are preferably arranged on the source terminal 26 at the second pitch P2 equal to or greater than the first pitch P1.

At least three pseudo-bumps 75 are preferably densely arranged on the source terminal 26. The at least three pseudo-bumps 75 are preferably arranged in a layout where the at least three pseudo-bumps 75 are located at vertices of an isosceles triangle in a plan view. In this case, the isosceles triangle is more preferably an equilateral triangle. According to these configurations, the plurality of pseudo-bumps 75 may be appropriately densely arranged. Further, heat generated in the output region 6 may be absorbed by the pseudo-bump group 76 including the plurality of pseudo-bumps 75.

At least seven pseudo-bumps 75 are preferably densely arranged on the source terminal 26. In this case, six pseudo-bumps 75 are preferably arranged around one pseudo-bump 75. The six pseudo-bumps 75 are preferably arranged on the concentric circle around the central portion of the one pseudo-bump 75 in a plan view. It is preferable that the six pseudo-bumps 75 are arranged in a layout in which the six pseudo-bumps 75 are located at vertices of a hexagon in a plan view and the one pseudo-bump 75 is arranged in a layout in which the one pseudo-bump 75 is located in the center of the hexagon in a plan view.

That is, the plurality of pseudo-bumps 75 are preferably bonded to the source terminal 26 in a layout of hexagonal closest array (that is, a honeycomb array) in a plan view. In this case, the hexagon is more preferably a regular hexagon. According to these configurations, the plurality of pseudo-bumps 75 may be appropriately densely arranged. Further, the heat generated in the output region 6 may be absorbed by the pseudo-bump group 76 including the plurality of pseudo-bumps 75.

The semiconductor device 61 preferably includes the first thin film portion 111 formed at the bonding portion of the pseudo-bumps 75 in the source terminal 26. According to this configuration, the heat generated in the output region 6 may be transferred to the pseudo-bumps 75 via the first thin film portion 111. The semiconductor device 61 preferably includes a thick film portion 113 formed in a region outside the bonding portion of the pseudo-bumps 75 in the source terminal 26. According to this configuration, the heat generated in the output region 6 may be absorbed by the thick film portion 113 in the region outside the bonding portion of the pseudo-bumps 75. The heat absorbed by the thick film portion 113 is transferred to the pseudo-bumps 75.

The semiconductor device 61 preferably includes the first raised portion 114 in which a portion of the source terminal 26 is thicker than the thick film portion 113 at the bonding edge of the pseudo-bumps 75 in the source terminal 26. That is, a portion of the source terminal 26 along the edge of the pseudo-bumps 75 is preferably thicker than the first thin film portion 111 by the thick film portion 113 and the first raised portion 114.

Further, portions of the source terminal 26 located among the plurality of pseudo-bumps 75 are made thicker than the plurality of first thin film portions 111 by the thick film portion 113 and the plurality of first raised portions 114. According to these configurations, the heat generated in the output region 6 may be absorbed in a region outside the bonding portion of the pseudo-bumps 75 by the thick film portion 113 and the first raised portion 114.

The pseudo-bump 75 may include the first bump body 77 containing first metal and the first bump metal film 78 containing second metal different from the first metal and covering at least a portion of the outer surface of the first bump body 77. The pseudo-bump 75 may include the wide first body portion 79 connected to the source terminal 26 and the first neck portion 80 which is narrower than the first body portion 79 and protrudes from the first body portion 79 toward the opposite side of the source terminal 26.

The semiconductor device 61 may include the plurality of trench structures 35 formed in the first main surface 3 of the output region 6. In this case, the pseudo-bumps 75 preferably overlap the plurality of trench structures 35 in a plan view. According to this configuration, heat generated in the plurality of trench structures 35 and/or in the vicinity of the plurality of trench structures 35 may be absorbed by the pseudo-bumps 75 directly above.

The pseudo-bumps 75 preferably have a thickness larger than the depth of each trench structure 35. When the first raised portion 114 is formed near the bonding edge of the pseudo-bump 75, the first raised portion 114 preferably faces at least one trench structure 35 in the thickness direction. The raising height of the first raised portion 114 based on the thick film portion 113 is preferably larger than the depth of the trench structure 35.

The semiconductor device 61 preferably includes the insulated gate type main transistor 11 including the plurality of trench structures 35 in the output region 6. According to this configuration, the temperature rise caused by the back electromotive force of the inductive load L during the active clamp operation of the main transistor 11 may be suppressed by the plurality of pseudo-bumps 75. As a result, an active clamp tolerance may be improved.

The main transistor 11 is preferably an n-system gate split transistor including n first gates FG to which n gate signals are individually input. According to this configuration, the main transistor 11 is controlled to switch among a full-on state in which all the first gates FG are in an on state, a part-on state in which some of the first gates FG are in an on state (some gates are in an off state), and a full-off state in which all the first gates FG are in an off state. In the main transistor 11, an on-resistance value in the part-on state is higher than an on-resistance value in the full-on state.

According to the n-system main transistor 11, by controlling some of the first gates FG of the main transistor 11 to be in the on state and some of the first gates FG of the main transistor 11 to be in the off state during the active clamp operation, the output voltage of the main transistor 11 may be clamped. As a result, the main transistor 11 may be protected from the back electromotive force of the inductive load L, thereby improving the active clamp tolerance.

The semiconductor device 61 preferably includes the control region 8 provided in the first main surface 3. The semiconductor device 61 preferably includes the control circuit 17 formed in the control region 8 to generate gate signals to be applied to the plurality of trench structures 35. In this case, the source terminal 26 preferably covers the output region 6 to expose the control region 8 in a plan view.

The semiconductor device 61 preferably includes the first temperature detection region 9 provided in the first main surface 3 to be adjacent to the output region 6 and the second temperature detection region 10 provided in the first main surface 3 to be adjacent to the control region 8. The semiconductor device 61 preferably includes the first temperature-sensitive diode 15 (the first temperature sensor) formed in the first temperature detection region 9 to detect the temperature of the output region 6 and the second temperature-sensitive diode 16 (the second temperature sensor) formed in the second temperature detection region 10 to detect the temperature of the control region 8.

In this case, the control circuit 17 may be configured to generate a gate signal based on the first temperature detection signal ST1 (electrical signal) from the first temperature-sensitive diode 15 and the second temperature detection signal ST2 (electrical signal) from the second temperature-sensitive diode 16. According to this configuration, the temperature rise of the output region 6 may be suppressed by the plurality of pseudo-bumps 75 and at the same time, the temperature rise of the output region 6 may be suppressed by using the control of the control circuit 17.

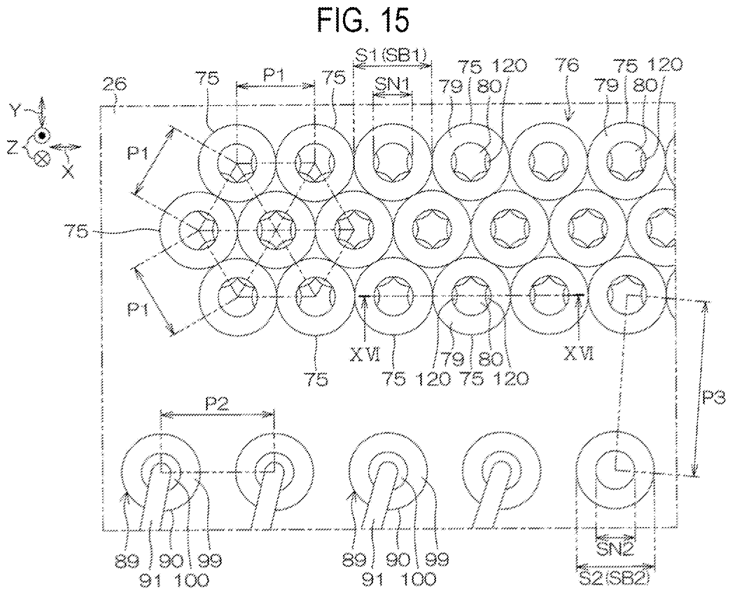

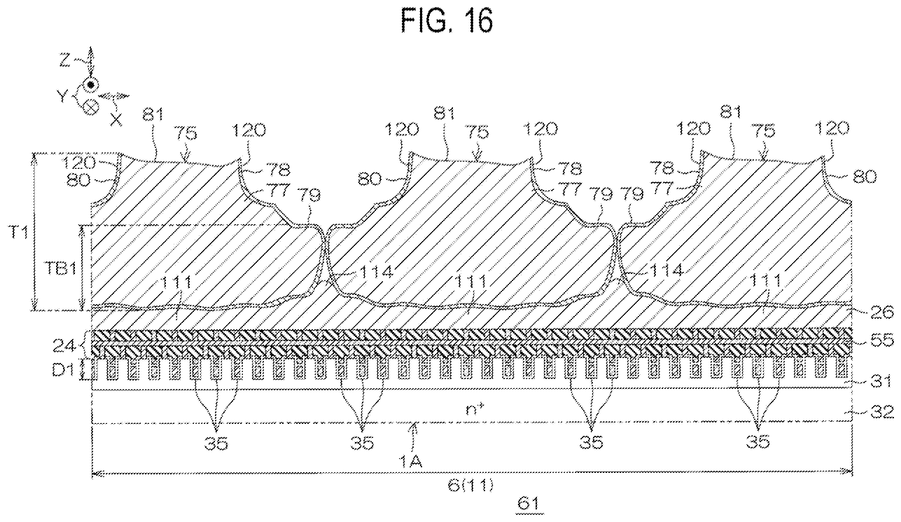

FIG. 15 is a plan view showing the pseudo-bumps 75 according to a second layout example. FIG. 16 is a cross-sectional view taken along line XVI-XVI shown in FIG. 15. FIGS. 15 and 16 show, as the second layout example, a layout in which a plurality of pseudo-bumps 75 are arranged to contact each other.

Each pseudo-bump 75 may include at least one gouged portion 120 recessed toward the central portion of the first neck portion 80 at the peripheral edge portion of the first neck portion 80. In a case where the plurality of pseudo-bumps 75 are arranged at narrow pitches by using the capillary, the gouged portion 120 is formed when the tip of the capillary is in contact with the first neck portion 80 of the pseudo-bump 75 which is already disposed.

The gouged portion 120 is formed in a portion of the first neck portion 80 that faces the adjacent pseudo-bump 75. Therefore, one pseudo-bump 75 adjacent to two pseudo-bumps 75 includes two gouged portions 120 in the first neck portion 80. Further, one pseudo-bump 75 surrounded by six pseudo-bumps 75 includes six gouged portions 120 in the first neck portion 80. A portion of the first upper end portion 81 (the upper end apex portion 82, the upper end base portion 83, and the inclined portion 84) may disappear due to the gouged portion 120.

The above-described first raised portion 114 is formed at the bonding edge of each pseudo-bump 75 in the source terminal 26. The first raised portion 114 formed near one pseudo-bump 75 may be integrated with the first raised portion 114 formed near the other pseudo-bump 75. That is, portions of the source terminal 26 located among the plurality of pseudo-bumps 75 may be thicker than the plurality of first thin film portions 111 (second thin film portions 112) by the first raised portion 114 which may be regarded as one.

The portions of the source terminal 26 located among the plurality of pseudo-bumps 75 preferably face the plurality of trench structures 35. That is, the first raised portion 114, which may be regarded as one, preferably faces the plurality of trench structures 35 in regions among the plurality of pseudo-bumps 75.

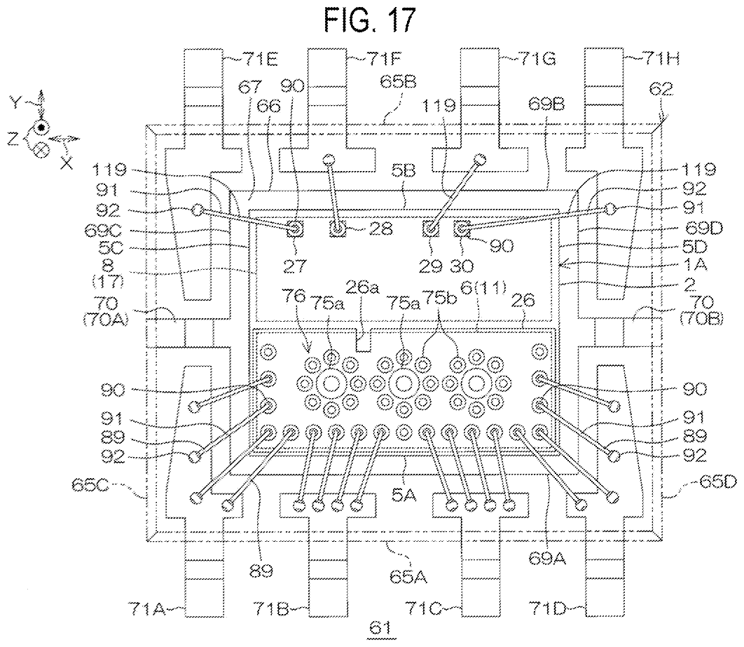

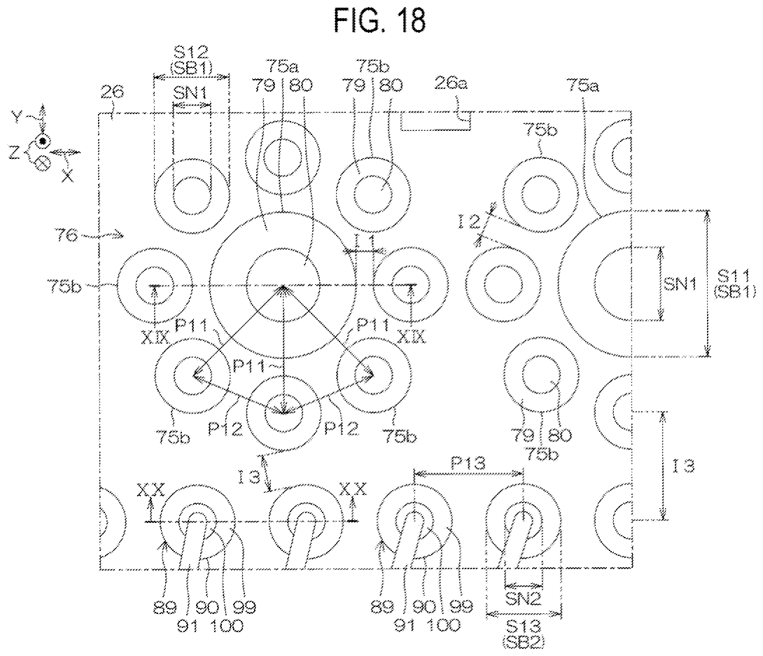

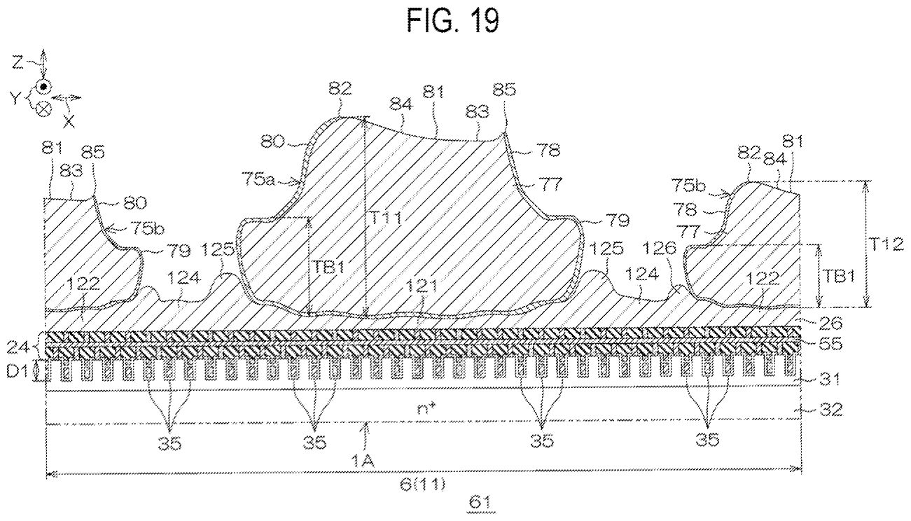

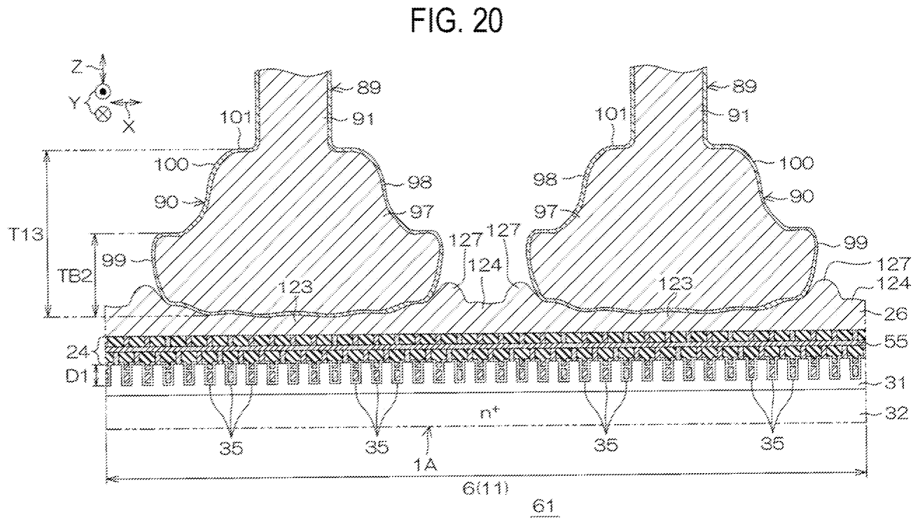

FIG. 17 is a plan view showing the internal structure of the semiconductor device 61 together with the pseudo-bumps 75 according to a third layout example. FIG. 18 is a plan view showing the pseudo-bumps 75 according to the third layout example. FIG. 19 is a cross-sectional view taken along line XIX-XIX shown in FIG. 18. FIG. 20 is a cross-sectional view taken along line XX-XX shown in FIG. 18.

Referring to FIGS. 17 to 20, the pseudo-bumps 75 according to the third layout example have a relatively large first size S11 in a plan view and include at least one (in this embodiment, a plurality of) large pseudo-bump 75a densely arranged on the source terminal 26 in a state of being separated from a wire. The first size S11 is defined by a length of the widest portion of the large pseudo-bump 75a in a plan view.

The term “dense” referred to herein means that an occupation area of one large pseudo-bump 75a with respect to the source terminal 26 is larger than that of another structure (one small pseudo-bump 75b, one genuine bump 90, or the like, which will be described later) with respect to the source terminal 26. The large pseudo-bump 75a is arranged on the source terminal 26 with the first occupation area per unit plane area.

The first size S11 may be 100 μm or more and 1,000 μm or less. The first size S11 may be 100 μm or more and 200 μm or less, 200 μm or more and 300 μm or less, 300 μm or more and 400 μm or less, 400 μm or more and 500 μm or less, 500 μm or more and 600 μm or less, 600 μm or more and 700 μm or less, 700 μm or more and 800 μm or less, 800 μm or more and 900 μm or less, or 900 μm or more and 1,000 μm or less.

Each of the plurality of large pseudo-bumps 75a has a first thickness T11. The first thickness T11 is defined by a thickness of the thickest portion of the large pseudo-bump 75a in a cross-sectional view. The first thickness T11 is preferably larger than the first depth D1 of the plurality of trench structures 35. The first thickness T11 is preferably larger than the thickness of the source terminal 26. The first thickness T11 is preferably larger than the thickness of the first semiconductor region 31. The first thickness T11 may be larger than the thickness of the substrate 2. Of course, the first thickness T11 may be smaller than the thickness of the substrate 2.

The first thickness T11 may be 50 μm or more and 500 μm or less. The first thickness T11 is 50 μm or more and 100 μm or less, 100 μm or more and 150 μm or less, 150 μm or more and 200 μm or less, 200 μm or more and 250 μm or less, 250 μm or more and 300 μm or less, 300 μm or more and 350 μm or less, 350 μm or more and 400 μm or less, 400 μm or more and 450 μm or less, or 450 μm or more and 500 μm or less.

The arrangement location of the plurality of large pseudo-bumps 75a are arbitrary. In this embodiment, the plurality of large pseudo-bumps 75a are arranged at intervals in the first direction X. The plurality of large pseudo-bumps 75a are preferably arranged on a portion of the source terminal 26 that covers the high-temperature region of the output region 6.

The plurality of large pseudo-bumps 75a are preferably arranged on the source terminal 26 in a layout that is dense in the inner portion (for example, the central portion) of the source terminal 26 and sparse in the peripheral edge portion of the source terminal 26. A form in which the large pseudo-bumps 75a are “sparse” includes a form in which no large pseudo-bumps 75a are present.

The plurality of large pseudo-bumps 75a are arranged in a position overlapping the main transistor 11 in a plan view and are not arranged in a region overlapping the control region 8 in a plan view. A portion of at least one large pseudo-bump 75a may face the monitor transistor 13 in a plan view. That is, the plurality of large pseudo-bumps 75a may face the plurality of trench structures 35 for the main transistor 11 and the plurality of trench structures 35 for the monitor transistor 13.

Each large pseudo-bump 75a may face fifty to two hundred trench structures 35. The number of trench structures 35 associated with and facing each large pseudo-bump 75a is 50 to 75, 75 to 100, 100 to 125, 125 to 150, 150 to 175, or 175 to 200.

The pseudo-bumps 75 according to the third layout example have a second size S12 smaller than the first size S11 of the large pseudo-bumps 75a in a plan view and include at least one small pseudo-bump 75b arranged around the large pseudo-bumps 75a in a state of being separated from the wire. The second size S12 is defined by a length of the widest portion of the small pseudo-bump 75b in a plan view. The presence or absence of the small pseudo-bump 75b is optional, and a structure without the small pseudo-bump 75b may be employed.

The second size S12 may be 0.05 to 0.8 times the first size S11. The size ratio of the second size S12 to the first size S11 may be 0.05 or more and 0.075 or less, 0.075 or more and 0.1 or less, 0.1 or more and 0.2 or less, 0.2 or more and 0.3 or less, 0.3 or more and 0.4 or less, 0.4 or more and 0.5 or less, 0.5 or more and 0.6 or less, 0.6 or more and 0.7 or less, or 0.7 or more and 0.8 or less. The size ratio may be less than 0.5. That is, the plane area of the small pseudo-bump 75b may be less than half the plane area of the large pseudo-bump 75a.

The second size S12 may be 50 μm or more and 250 μm or less. The second size S12 may be 50 μm or more and 75 μm or less, 75 μm or more and 100 μm or less, 100 μm or more and 125 μm or less, 125 μm or more and 150 μm or less, 150 μm or more and 175 μm or less, 175 μm or more and 200 μm or less, 200 μm or more and 225 μm or less, or 225 μm or more and 250 μm or less. The second size S12 is preferably 75 μm or more and 200 μm or less. The second size S12 is more preferably 100 μm or more and 180 μm or less.

Each of the plurality of small pseudo-bumps 75b has a second thickness T12. The second thickness T12 is defined by a thickness of the thickest portion of the small pseudo-bump 75b in a cross-sectional view. The second thickness T12 is smaller than the first thickness T11 of the large pseudo-bump 75a. The second thickness T12 is preferably larger than the first depth D1 of the plurality of trench structures 35. The second thickness T12 is preferably larger than the thickness of the source terminal 26. The second thickness T12 is preferably larger than the thickness of the first semiconductor region 31. The second thickness T12 may be larger than the thickness of the substrate 2. Of course, the second thickness T12 may be smaller than the thickness of the substrate 2.

The second thickness T12 may be 10 μm or more and 150 μm or less. The second thickness T12 may be 10 μm or more and 25 μm or less, 25 μm or more and 50 μm or less, 50 μm or more and 75 μm or less, 75 μm or more and 100 μm or less, 100 μm or more and 125 m or less, or 125 μm or more and 150 μm or less.

The small pseudo-bump 75b increases the occupation area of the pseudo-bump 75 with respect to the source terminal 26 by being placed side by side with the large pseudo-bump 75a. It is preferable that at least one small pseudo-bump 75b is arranged around each large pseudo-bump 75a, forming one pseudo-bump group 76 together with one corresponding large pseudo-bump 75a. In this embodiment, a plurality of small pseudo-bumps 75b are respectively arranged around each large pseudo-bump 75a, forming one pseudo-bump group 76 together with one corresponding large pseudo-bump 75a.

The configuration within one pseudo-bump group 76 will be described below. The plurality of small pseudo-bumps 75b may include two small pseudo-bumps 75b arranged around the large pseudo-bump 75a. In this case, the two small pseudo-bumps 75b are preferably arranged on a concentric circle centered on the central portion of the large pseudo-bump 75a.

The two small pseudo-bumps 75b may face each other in the first direction X or the second direction Y with the large pseudo-bump 75a interposed therebetween. One small pseudo-bump 75b may be arranged to deviate from the large pseudo-bump 75a in the first direction X, and the other small pseudo-bumps 75b may be arranged to deviate from the large pseudo-bump 75a in the second direction Y.

One small pseudo-bump 75b may be arranged at a position deviating from the other small pseudo-bumps 75b by a predetermined angle (absolute value) along the circumferential direction of the large pseudo-bump 75a. The predetermined angle is an angle formed between a line connecting the central portion of the large pseudo-bump 75a and the central portion of one small pseudo-bump 75b and a line connecting the central portion of the large pseudo-bump 75a and the central portion of the other small pseudo-bump 75b.

The predetermined angle may be 10 degrees or more and 180 degrees or less. The predetermined angle may be 10 degrees or more and 30 degrees or less, 30 degrees or more and 45 degrees or less, 45 degrees or more and 60 degrees or less, 60 degrees or more and 75 degrees or less, 75 degrees or more and 90 degrees or less, 90 degrees or more and 105 degrees or less, 105 degrees or more and 120 degrees or less, 120 degrees or more and 135 degrees or less, 135 degrees or more and 150 degrees or less, 150 degrees or more and 165 degrees or less, or 165 degrees or more and 180 degrees or less.

The plurality of small pseudo-bumps 75b may include x (x>3) small pseudo-bumps 75b arranged around the large pseudo-bump 75a. The x small pseudo-bumps 75b are preferably arranged at equal intervals around the large pseudo-bump 75a along the circumferential direction of the large pseudo-bump 75a in a plan view. The x small pseudo-bumps 75b are preferably arranged on a concentric circle centered on the central portion of the large pseudo-bump 75a in a plan view.

It is more preferable that the x small pseudo-bumps 75b are respectively arranged at vertices of a regular x-polygon and the large pseudo-bump 75a is arranged at the center of the regular x-polygon. For example, when x=3, three small pseudo-bumps 75b are respectively arranged at vertices of an equilateral triangle, and a large pseudo-bump 75a is arranged at the center of the equilateral triangle. For example, when x=4, four small pseudo-bumps 75b are respectively arranged at vertices of a square, and a large pseudo-bump 75a is arranged at the center of the square.

For example, when x=5, five small pseudo-bumps 75b are respectively arranged at vertices of a regular pentagon, and a large pseudo-bump 75a is arranged at the center of the regular pentagon. For example, when x=6, six small pseudo-bumps 75b are respectively arranged at vertices of a regular hexagon, and a large pseudo-bump 75a is arranged at the center of the regular hexagon.

When the value of x is decreased, a man-hour of a wire bonding process may decrease, but an area of an empty region formed around the large pseudo-bump 75a increases. On the other hand, when the value of x is increased, the man-hour increases and at the same time, a diameter of the small pseudo-bump 75b decreases, such that a heat absorption effect of each small pseudo-bump 75b decreases.

For example, an amount of heat absorption when forty small-diameter small pseudo-bumps 75b are arranged on a concentric circle is almost the same as an amount of heat absorption when twenty large-diameter small pseudo-bumps 75b are arranged on the concentric circle. Therefore, it is preferable that the second size S12 of the small pseudo-bump 75b is adjusted after the value of x is set to 4 or more and 20 or less.

According to this configuration, it is possible to arrange a plurality of small pseudo-bumps 75b surrounding the large pseudo-bump 75a from at least four directions while reducing a man-hour burden. It is more preferable that the value of x is set to 6 or more and 12 or less.

In this embodiment, x=8, eight small pseudo-bumps 75b are respectively arranged at vertices of a regular octagon, and a large pseudo-bump 75a is arranged at the center of the regular octagon.

A plurality of small pseudo-bumps 75b are arranged on the source terminal 26 at a first pitch P11 with one large pseudo-bump 75a as a reference. The first pitch P11 is defined by a distance between the central portions of the large pseudo-bump 75a and the small pseudo-bump 75b. The plurality of small pseudo-bumps 75b may be arranged to be in contact with the large pseudo-bump 75a at the first pitch P11, or may be arranged at intervals from the large pseudo-bump 75a at the first pitch P11.

The plurality of small pseudo-bumps 75b are preferably arranged at intervals from the large pseudo-bump 75a. When the plurality of small pseudo-bumps 75b are in contact with the large pseudo-bump 75a, at least one gouged portion 120 may be formed in one or both of the first body portion 79 and the first neck portion 80 of the large pseudo-bump 75a (see also FIGS. 15 and 16). Of course, a form without the gouged portion 120 may be adopted.

A first interval I1 between the small pseudo-bump 75b and the large pseudo-bump 75a may be 0 μm or more and 100 μm or less. The first interval I1 is 0 μm or more and 10 μm or less, 10 μm or more and 20 μm or less, 20 μm or more and 30 μm or less, 30 μm or more and 40 μm or less, 40 μm or more and 50 μm or less, 50 μm or more and 60 μm or less, 60 μm or more and 70 μm or less, 70 μm or more and 80 μm or less, 80 μm or more and 90 μm or less, or 90 m or more and 100 μm or less. The first interval I1 is preferably 10 μm or more. The first interval I1 is more preferably 30 μm or more and 60 μm or less.

The plurality of small pseudo-bumps 75b are arranged around the large pseudo-bump 75a at a second pitch P12 in a plan view. The second pitch P12 is defined by distances among the central portions of the plurality of small pseudo-bumps 75b. The plurality of small pseudo-bumps 75b may be arranged to be in contact with each other at the second pitch P12, or may be arranged at intervals at the second pitch P12.

The second pitch P12 may be equal to or more than the first pitch P11. The second pitch P12 is preferably less than the first pitch P11. Second intervals 12 among the plurality of small pseudo-bumps 75b may be 0 μm or more and may not be limited to a specific numerical value. The plurality of small pseudo-bumps 75b are preferably arranged at equal intervals at the second pitch P12 (the second interval I2). The second pitch P12 (the second interval 12) is adjusted according to the number of small pseudo-bumps 75b, their arrangement locations, the second size S12, and the like.

The pseudo-bump 75 may include one or more small pseudo-bumps 75b that do not belong to the pseudo-bump group 76. The small pseudo-bumps 75b that do not belong to the pseudo-bump group 76 may be arranged in any empty region of the source terminal 26. The small pseudo-bumps 75b that do not belong to the pseudo-bump group 76 may be arranged, for example, in regions among a plurality of adjacent pseudo-bump groups 76.

The plurality of large pseudo-bumps 75a include a first bump body 77 and a first bump metal film 78, as in the case of the first layout example. The first bump body 77 includes a first body portion 79 and a first neck portion 80. The plurality of small pseudo-bumps 75b include a first bump body 77 and a first bump metal film 78, as in the case of the first layout example. The first bump body 77 includes a first body portion 79 and a first neck portion 80. The description of this configuration is omitted as the above description applies.

Each genuine bump 90 described above is arranged on the source terminal 26 more sparsely than one large pseudo-bump 75a. The term “sparse” referred to herein means that an occupation area of one genuine bump 90 with respect to the source terminal 26 is smaller than an occupation area of one large pseudo-bump 75a with respect to the source terminal 26. That is, each genuine bump 90 is arranged on the source terminal 26 with a second occupation area less than a first occupation area of one large pseudo-bump 75a per unit plane area.

Further, the plurality of genuine bumps 90 are arranged more sparsely than the pseudo-bump group 76. That is, each genuine bump 90 is arranged on the source terminal 26 with the occupation area less than those of the large pseudo-bump 75a and the small pseudo-bump 75b per unit plane area. When comparing the occupation area of one large pseudo-bump 75a and the occupation area of two adjacent genuine bumps 90, the occupation area of the two genuine bumps 90 may be less than the occupation area of one large pseudo-bump 75a.

Each of the plurality of genuine bumps 90 has a third size S13 that is smaller than the first size S11 of the large pseudo-bump 75a in a plan view. The third size S13 is defined by a length of the widest portion of the genuine bump 90 in a plan view. The third size S13 may be 0.05 to 0.8 times the first size S11.

The size ratio of the third size S13 to the first size S11 may be 0.05 or more and 0.075 or less, 0.075 or more and 0.1 or less, 0.1 or more and 0.2 or less, 0.2 or more and 0.3 or less, 0.3 or more and 0.4 or less, 0.4 or more and 0.5 or less, 0.5 or more and 0.6 or less, 0.6 or more and 0.7 or less, or 0.7 or more and 0.8 or less. The size ratio may be less than 0.5. That is, the plane area of the genuine bump 90 may be less than half the plane area of the large pseudo-bump 75a.

The third size S13 may be 50 μm or more and 250 μm or less. The third size S13 may be 50 μm or more and 75 μm or less, 75 μm or more and 100 μm or less, 100 μm or more and 125 μm or less, 125 μm or more and 150 μm or less, 150 μm or more and 175 μm or less, 175 μm or more and 200 μm or less, 200 μm or more and 225 μm or less, or 225 μm or more and 250 μm or less.

The third size S13 is preferably 75 μm or more and 200 μm or less. The third size S13 is more preferably 100 μm or more and 180 μm or less. The third size S13 may be equal to or more than the second size S12 of the small pseudo-bump 75b, or may be less than the second size S12. The third size S13 is preferably approximately equal to the second size S12. According to this configuration, the small pseudo-bump 75b and the genuine bump 90 may be formed under the same manufacturing conditions in terms of size.

Each of the plurality of genuine bumps 90 has a third thickness T13. The third thickness T13 is defined by a thickness of the thickest portion of the genuine bump 90 in a cross-sectional view. The third thickness T13 is smaller than the first thickness T11 of the large pseudo-bump 75a. The third thickness T13 is preferably larger than the first depth D1 of the plurality of trench structures 35. Third thickness T13 is preferably larger than the thickness of the source terminal 26. The third thickness T13 is preferably larger than the thickness of the first semiconductor region 31. The third thickness T13 may be larger than the thickness of the substrate 2. Of course, the third thickness T13 may be smaller than the thickness of the substrate 2.

The third thickness T13 may be 10 μm or more and 150 μm or less. The third thickness T13 may be 10 μm or more and 25 μm or less, 25 μm or more and 50 μm or less, 50 μm or more and 75 μm or less, 75 μm or more and 100 μm or less, 100 μm or more and 125 μm or less, or 125 μm or more and 150 μm or less.

The third thickness T13 may be equal to or more than the second thickness T12 of the small pseudo-bump 75b, or may be less than the second thickness T12. The third thickness T13 is preferably approximately equal to the second thickness T12. According to this configuration, the small pseudo-bump 75b and the genuine bump 90 may be formed under the same manufacturing conditions in terms of thickness.

The plurality of genuine bumps 90 are arranged on the source terminal 26 at an arbitrary third pitch P13 in a plan view. The third pitch P13 is defined by a distance between the central portions of two adjacent genuine bumps 90. The third pitch P13 may take any value as long as the entire genuine bump 90 is located within a range surrounded by the peripheral edge of the source terminal 26. The third pitch P13 may be equal to or more than the first pitch P11, or may be less than the first pitch P11. The third pitch P13 may be equal to or more than the second pitch P12, or may be less than the second pitch P12.

A third interval 13 between one genuine bump 90 and one small pseudo-bump 75b, which are closest to each other, is preferably equal to or more than the first interval I1 between the large pseudo-bump 75a and the small pseudo-bump 75b. The third interval 13 is more preferably larger than the first interval I1. As an example, the ratio of the third interval 13 to the first interval I1 may be 1 or more and 20 or less. The ratio may be 1 or more and 2 or less, 2 or more and 5 or less, 5 or more and 10 or less, 10 or more and 15 or less, or 15 or more and 20 or less.

The plurality of genuine bumps 90 include the above-described second bump body 97 and second bump metal film 98. The second bump body 97 includes the above-described second body portion 99 and second neck portion 100. The description of this configuration is omitted as the above description applies.

In this embodiment, the semiconductor device 61 includes a plurality of first thin film portions 121, a plurality of second thin film portions 122, a plurality of third thin film portions 123, and a thick film portion 124 formed on the source terminal 26. The plurality of first thin film portions 121 are respectively formed at the bonding portions of the plurality of large pseudo-bumps 75a in the source terminal 26. The plurality of second thin film portions 122 are respectively formed at the bonding portions of the plurality of small pseudo-bumps 75b in the source terminal 26. The minimum thickness of the plurality of second thin film portions 122 may be larger than the minimum thickness of the plurality of first thin film portions 121.

The plurality of third thin film portions 123 are respectively formed at the bonding portions of the plurality of genuine bumps 90 in the source terminal 26. The minimum thickness of the plurality of third thin film portions 123 may be larger than the minimum thickness of the plurality of first thin film portions 121. The thick film portion 124 is formed in a region outside the bonding portions of the plurality of large pseudo-bumps 75a, the bonding portions of the plurality of small pseudo-bumps 75b, and the bonding portions of the plurality of genuine bumps 90 in the source terminal 26.

The maximum thickness of the thick film portion 124 may be larger than the minimum thickness of the first thin film portion 121 and may be three times or less the minimum thickness of the first thin film portion 121. The thickness ratio of the maximum thickness to the minimum thickness may be larger than 1 and equal to or less than 1.25, 1.25 or more and 1.5 or less, 1.5 or more and 1.75 or less, 1.75 or more and 2 or less, 2 or more and 2.25 or less, 2.25 or more and 2.5 or less, 2.5 or more and 2.75 or less, or 2.75 or more and 3 or less.

The semiconductor device 61 includes a plurality of first raised portions 125 formed on the source terminal 26. The plurality of first raised portions 125 are formed at the bonding edges of the plurality of large pseudo-bumps 75a in the source terminal 26, and a portion of the source terminal 26 is made up of a portion thicker than the thick film portion 124. Each first raised portion 125 extends annularly along the edge (bonding edge) of each large pseudo-bump 75a in a plan view. At least a portion of each first raised portion 125 faces the peripheral edge portion of each large pseudo-bump 75a in the thickness direction.

A portion of the source terminal 26 along the edge of each large pseudo-bump 75a is made thicker than the first thin film portion 121 by the thick film portion 124 and the first raised portion 125. Each first raised portion 125 faces at least one trench structure 35 in the thickness direction. In this embodiment, each first raised portion 125 is formed to face the plurality of trench structures 35 in the thickness direction.

The raising height of at least one first raised portion 125 based on the thick film portion 124 is preferably larger than the first depth D1 of the trench structure 35. The raising height of the at least one first raised portion 125 may be larger than the thickness of the first semiconductor region 31. Of course, the raising height of the at least one first raised portion 125 may be equal to or less than the first depth D1 of the trench structure 35. The first total thickness of the thick film portion 124 and the first raised portion 125 is preferably larger than the thickness of the interlayer insulating film 24.

The first total thickness is larger than 1 time the minimum thickness of the first thin film portion 121 and may be 10 times or less the minimum thickness of the first thin film portion 121. The thickness ratio of the first total thickness to the minimum thickness may be larger than 1 and equal to less than 2, 2 or more and 4 or less, 4 or more and 6 or less, 6 or more and 8 or less, or 8 or more and 10 or less. The thickness ratio is preferably 2 or more and 6 or less.

The semiconductor device 61 includes a plurality of second raised portions 126 formed on the source terminal 26. The plurality of second raised portions 126 are formed at the bonding edges of the plurality of small pseudo-bumps 75b in the source terminal 26, and a portion of the source terminal 26 is made up of a portion thicker than the thick film portion 124. Each second raised portion 126 extends annularly along the edge (bonding edge) of each small pseudo-bump 75b in a plan view. At least a portion of each second raised portion 126 faces the peripheral edge portion of each small pseudo-bump 75b in the thickness direction.

A portion of the source terminal 26 along the edge of each small pseudo-bump 75b is made thicker than the second thin film portion 122 by the thick film portion 124 and the second raised portion 126. Further, the portion along the edge of each small pseudo-bump 75b is made thicker than the first thin film portion 121. Further, a portion of the source terminal 26 located between the large pseudo-bump 75a and the small pseudo-bump 75b is thicker than the first thin film portion 121 and the second thin film portion 122 by the thick film portion 124, the first raised portion 125, and the second raised portion 126.

Each second raised portion 126 faces at least one trench structure 35 in the thickness direction. In this embodiment, each second raised portion 126 is formed to face the plurality of trench structures 35 in the thickness direction. The raising height of at least one second raised portion 126 based on the thick film portion 124 is preferably smaller than the raising height of the first raised portion 125.

The raising height of the at least one second raised portion 126 is preferably larger than the first depth D1 of the trench structure 35. The raising height of the at least one second raised portion 126 may be larger than the thickness of the first semiconductor region 31. Of course, the raising height of the at least one second raised portion 126 may be equal to or less than the first depth D1 of the trench structure 35. The second total thickness of the thick film portion 124 and the second raised portion 126 is preferably larger than the thickness of the interlayer insulating film 24.

The second total thickness may be larger than 1 time the minimum thickness of the second thin film portion 122 and may be 10 times or less than the minimum thickness of the second thin film portion 122. The thickness ratio of the second total thickness to the minimum thickness may be larger than 1 and equal to or less than 2, 2 or more and 4 or less, 4 or more and 6 or less, 6 or more and 8 or less, or 8 or more and 10 or less. The thickness ratio is preferably 2 or more and 6 or less.

The second raised portion 126 formed near the small pseudo-bump 75b may be integrated with the first raised portion 125 formed near the large pseudo-bump 75a. That is, a portion of the source terminal 26 located between the large pseudo-bump 75a and the small pseudo-bump 75b may be thicker than the plurality of first thin film portions 121 (second thin film portions 122) by the first raised portion 125 (the second raised portion 126) which may be regarded as one. The first raised portion 125 (the second raised portion 126), which may be regarded as one, preferably faces the plurality of trench structures 35.

The semiconductor device 61 includes a plurality of third raised portions 127 formed on the source terminal 26. The plurality of third raised portions 127 are formed at the bonding edges of the plurality of genuine bumps 90 in the source terminal 26, and a portion of the source terminal 26 is made up of a portion thicker than the thick film portion 124. Each third raised portion 127 extends annularly along the edge (bonding edge) of each genuine bump 90 in a plan view. At least a portion of each third raised portion 127 faces the peripheral edge portion of each genuine bump 90 in the thickness direction.

A portion of the source terminal 26 along the edge of each genuine bump 90 is made thicker than the third thin film portion 123 by the thick film portion 124 and the third raised portion 127. Further, a portion of the source terminal 26 located between the small pseudo-bump 75b and the genuine bump 90 is made thicker than the second thin film portion 122 and the third thin film portion 123 by the thick film portion 124, the second raised portion 126, and the third raised portion 127.

Each third raised portion 127 faces at least one trench structure 35 in the thickness direction. In this embodiment, each third raised portion 127 is formed to face the plurality of trench structures 35 in the thickness direction. The raising height of at least one third raised portion 127 based on the thick film portion 124 is preferably smaller than the raising height of the first raised portion 125.

The raising height of the at least one third raised portion 127 is preferably larger than the first depth D1 of the trench structure 35. The raising height of the at least one third raised portion 127 may be larger than the thickness of the first semiconductor region 31. Of course, the raising height of the at least one third raised portion 127 may be equal to or less than the first depth D1 of the trench structure 35. The third total thickness of the thick film portion 124 and the third raised portion 127 is preferably larger than the thickness of the interlayer insulating film 24.

The third total thickness may be larger than 1 time the minimum thickness of the third thin film portion 123 and 10 times or less the minimum thickness of the third thin film portion 123. The thickness ratio of the third total thickness to the minimum thickness may be larger than 1 and equal to or less 2, 2 or more and 4 or less, 4 or more and 6 or less, 6 or more and 8 or less, or 8 or more and 10 or less. The thickness ratio is preferably 2 or more and 6 or less.

As described above, the semiconductor device 61 includes the substrate 2, the output region 6 (device region), the source terminal 26 (terminal), the large pseudo-bumps 75a, and the genuine bumps 90. The output region 6 is provided in the substrate 2. The source terminal 26 covers the output region 6 in a plan view. The large pseudo-bump 75a is arranged on the source terminal 26 in a state of being opened from the wire. The genuine bump 90 is arranged on the source terminal 26 in a state of being connected to the wire and has a size smaller than the size of the large pseudo-bump 75a.

According to this configuration, the heat generated in the output region 6 may be absorbed by the large pseudo-bumps 75a more than by the genuine bumps 90. The amount of heat absorption is adjusted by the size of the large pseudo-bump 75a. As a result, the temperature rise of the output region 6 may be suppressed, and the deterioration of the electrical characteristics of the output region 6 due to the temperature rise may be suppressed. Therefore, it is possible to provide the semiconductor device 61 capable of improving the electrical characteristics.

The large pseudo-bump 75a is preferably thicker than the source terminal 26. According to this configuration, the thickness of the source terminal 26 may be reduced by forming the relatively thick large pseudo-bump 75a. Therefore, heat may be transferred to the large pseudo-bump 75a via the relatively thin source terminal 26, and the cost of forming the source terminal 26 may be reduced.

For example, by employing the relatively thick large pseudo-bump 75a, it is possible to employ the source terminal 26 including a Cu-based metal film or an Al-based metal film and having a thickness of 1 μm or more and 10 μm or less. Since such a source terminal 26 may be formed by a sputtering method, it may include an electrode film other than a plating film.

The semiconductor device 61 may include the small pseudo-bump 75b which is arranged around the large pseudo-bump 75a on the source terminal 26 in a state of being opened from the wire and has a size smaller than the size of the large pseudo-bump 75a. According to this configuration, the heat generated in the output region 6 may be absorbed by the large pseudo-bumps 75a and the small pseudo-bumps 75b.

The small pseudo-bump 75b is preferably thicker than the source terminal 26. According to this configuration, the thickness of the source terminal 26 may be reduced by forming the relatively thick small pseudo-bump 75b. Therefore, heat may be transferred to the small pseudo-bump 75b via the relatively thin source terminal 26, and the cost of forming the source terminal 26 may be reduced.

An x (x>2) number of small pseudo-bumps 75b is preferably arranged around the large pseudo-bump 75a. According to this configuration, the heat generated in the output region 6 may be absorbed by the large pseudo-bump 75a and the x (x>2) small pseudo-bumps 75b. The value of x is preferably 3 or more (x>3). The value of x is preferably 4 or more (x>4). The value of x is preferably 20 or less (x<20).

The value of x is more preferably 6 or more and 12 or less. The x small pseudo-bumps 75b may be arranged at equal intervals along the circumferential direction of the large pseudo-bump 75a. The x small pseudo-bumps 75b may be arranged on a concentric circle centered on the central portion of the large pseudo-bump 75a in a plan view. When the value of x is 3 or more (x>3), the x small pseudo-bumps 75b may be respectively arranged at the vertices of the regular x-polygon. In this case, the large pseudo-bump 75a may be arranged at the center of the regular x-polygon.

The plurality of genuine bumps 90 may be arranged on the source terminal 26. In this case, each genuine bump 90 is preferably arranged on the source terminal 26 with the occupation area less than those of the large pseudo-bump 75a and the small pseudo-bump 75b per unit plane area. The occupation area of two adjacent genuine bumps 90 per unit plane area may be less than the occupation area of one large pseudo-bump 75a per unit plane area. That is, the plane area of one genuine bump 90 may be less than half the plane area of one large pseudo-bump 75a.

The semiconductor device 61 preferably includes the first thin film portion 121 formed at the bonding portion of the large pseudo-bump 75a in the source terminal 26. According to this configuration, the heat generated in the output region 6 may be transferred to the large pseudo-bump 75a via the first thin film portion 121.

The semiconductor device 61 preferably includes the second thin film portion 122 formed at the bonding portion of the small pseudo-bump 75b in the source terminal 26. According to this configuration, the heat generated in the output region 6 may be transferred to the small pseudo-bump 75b via the second thin film portion 122. The second thin film portion 122 may be thicker than the first thin film portion 121.

The semiconductor device 61 preferably includes the thick film portion 124 formed in a region outside the bonding portion of the large pseudo-bump 75a in the source terminal 26. According to this configuration, the heat generated in the output region 6 may be absorbed by the thick film portion 124 in the region outside the bonding portion of the large pseudo-bump 75a. The heat absorbed by the thick film portion 124 is transferred to the large pseudo-bump 75a.

The semiconductor device 61 preferably includes the first raised portion 125 in which a portion of the source terminal 26 is thicker than the thick film portion 124 at the bonding edge of the large pseudo-bump 75a in the source terminal 26. That is, a portion of the source terminal 26 along the edge of the large pseudo-bump 75a is preferably thicker than the first thin film portion 121 by the thick film portion 124 and the first raised portion 125. According to this configuration, the heat generated in the output region 6 may be absorbed by the thick film portion 124 and the first raised portion 125 in a region outside the bonding portion of the large pseudo-bump 75a.

The semiconductor device 61 preferably includes the second raised portion 126 in which a portion of the source terminal 26 is thicker than the thick film portion 124 at the bonding edge of the small pseudo-bump 75b in the source terminal 26. That is, a portion of the source terminal 26 along the edge of the small pseudo-bump 75b is preferably thicker than the second thin film portion 122 by the thick film portion 124 and the second raised portion 126. According to this configuration, the heat generated in the output region 6 may be absorbed by the thick film portion 124 and the second raised portion 126 in a region outside the bonding portion of the small pseudo-bump 75b.

The large pseudo-bump 75a may include the first bump body 77 containing first metal and the first bump metal film 78 containing second metal different from the first metal and covering at least a portion of the outer surface of the first bump body 77. The large pseudo-bump 75a may include the wide first body portion 79 connected to the source terminal 26, and the first neck portion 80 which is narrower than the first body portion 79 and protrudes from the first body portion 79 toward the opposite side of the source terminal 26.

The small pseudo-bump 75b may include the first bump body 77 containing first metal and the first bump metal film 78 containing second metal different from the first metal and covering at least a portion of the outer surface of the first bump body 77. The small pseudo-bump 75b may include the wide first body portion 79 connected to the source terminal 26, and the first neck portion 80 which is narrower than the first body portion 79 and protrudes from the first body portion 79 toward the opposite side of the source terminal 26.

The semiconductor device 61 may include the plurality of trench structures 35 formed in the first main surface 3 of the output region 6. In this case, the large pseudo-bump 75a preferably overlaps the plurality of trench structures 35 in a plan view. According to this configuration, heat generated in the plurality of trench structures 35 and/or in the vicinity of the plurality of trench structures 35 may be absorbed by the large pseudo-bump 75a directly above.

The large pseudo-bump 75a preferably has a thickness larger than the depth of each trench structure 35. When the first raised portion 125 is formed near the bonding edge of the large pseudo-bump 75a, the first raised portion 125 preferably faces at least one trench structure 35 in the thickness direction. The raising height of the first raised portion 125 based on the thick film portion 124 is preferably larger than the depth of the trench structure 35.

The semiconductor device 61 preferably has the insulated gate type main transistor 11 including a plurality of trench structures 35 in the output region 6. According to this configuration, the temperature rise caused by the back electromotive force of the inductive load L during the active clamp operation of the main transistor 11 may be suppressed by the plurality of pseudo-bumps 75. As a result, the active clamp tolerance may be improved.

The main transistor 11 is preferably the n-system gate split transistor including n first gates FG to which n gate signals are individually input. With this configuration, the main transistor 11 is controlled to switch among a full-on state in which all the first gates FG are in an on state, a part-on state in which some of the first gates FG are in an on state (some gates are in an off state), and a full-off state in which all the first gates FG are in an off state. In the main transistor 11, the on-resistance value in the part-on state is higher than the on-resistance value in the full-on state.

According to the n-system main transistor 11, by controlling some of the first gates FG of the main transistor 11 to be on and some of the first gates FG of the main transistor 11 to be off during the active clamp operation, the output voltage of the main transistor 11 may be clamped. As a result, the main transistor 11 may be protected from the back electromotive force of the inductive load L, thereby improving the active clamp tolerance.

The semiconductor device 61 preferably includes the control region 8 provided in the first main surface 3. In this case, the semiconductor device 61 preferably includes the control circuit 17 formed in the control region 8 to generate gate signals to be applied to the plurality of trench structures 35. In this case, the source terminal 26 preferably covers the output region 6 to expose the control region 8 in a plan view.

The semiconductor device 61 preferably includes the first temperature detection region 9 provided in the first main surface 3 to be adjacent to the output region 6 and the second temperature detection region 10 provided in the first main surface 3 to be adjacent to the control region 8. In this case, the semiconductor device 61 preferably includes the first temperature-sensitive diode 15 (the first temperature sensor) formed in the first temperature detection region 9 to detect a temperature of the output region 6 and the second temperature-sensitive diode 16 (the second temperature sensor) formed in the second temperature detection region 10 to detect a temperature of the control region 8.

In this case, the control circuit 17 may be configured to generate a gate signal based on the first temperature detection signal ST1 (electrical signal) from the first temperature-sensitive diode 15 and the second temperature detection signal ST2 (electrical signal) from the second temperature-sensitive diode 16. According to this configuration, the temperature rise of the output region 6 may be suppressed by the plurality of pseudo-bumps 75 and at the same time, the temperature rise of the output region 6 may be suppressed by using the control of the control circuit 17.

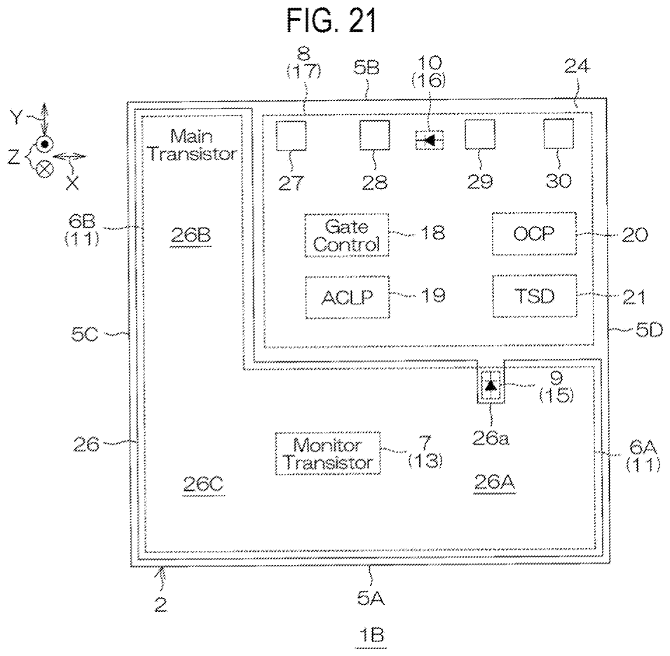

FIG. 21 is a plan view showing a semiconductor chip 1B according to a second embodiment of the present disclosure. Referring to FIG. 21, the semiconductor chip 1B has a form in which the layout of the output region 6 of the semiconductor chip 1A is changed. In this embodiment, the output region 6 is partitioned into an L shape in a plan view. Specifically, the output region 6 has a first region 6A that extends in a strip shape along the first direction X in a region near the first side surface 5A, and a second region 6B that extends in a strip shape along the second direction Y in a region near the third side surface 5C.

In this embodiment, the control region 8 is provided in a region defined by the peripheral edge of the first main surface 3, the first region 6A of the output region 6, and the second region 6B of the output region 6 in a region near the second side surface 5B. The current detection region 7 may be provided in one or both of the first region 6A of the output region 6 and the second region 6B of the output region 6. In this embodiment, the current detection region 7 is provided in the first region 6A.

The first temperature detection region 9 may be provided to be adjacent to one or both of the first region 6A of the output region 6 and the second region 6B of the output region 6. In this embodiment, the first temperature detection region 9 is provided to be adjacent to the first region 6A. The second temperature detection region 10 is provided to be adjacent to the control region 8, as in the case of the first embodiment.

In this embodiment, the source terminal 26 is partitioned into an L shape in a plan view. Specifically, the source terminal 26 has a first terminal portion 26A extending in a strip shape along the first direction X to cover the first region 6A of the output region 6, and a second terminal portion 26B extending in a strip shape along the second direction Y to cover the second region 6B of the output region 6. In this embodiment, the source terminal 26 has a notch 26a that is cut in a quadrangular shape to expose the first temperature detection region 9 in the first terminal portion 26A.

The first to fourth control terminals 27 to 30 are arranged in a region defined by the peripheral edge of the first main surface 3, the first terminal portion 26A of the source terminal 26, and the second terminal portion 26B of the source terminal 26 in a region near the second side surface 5B.

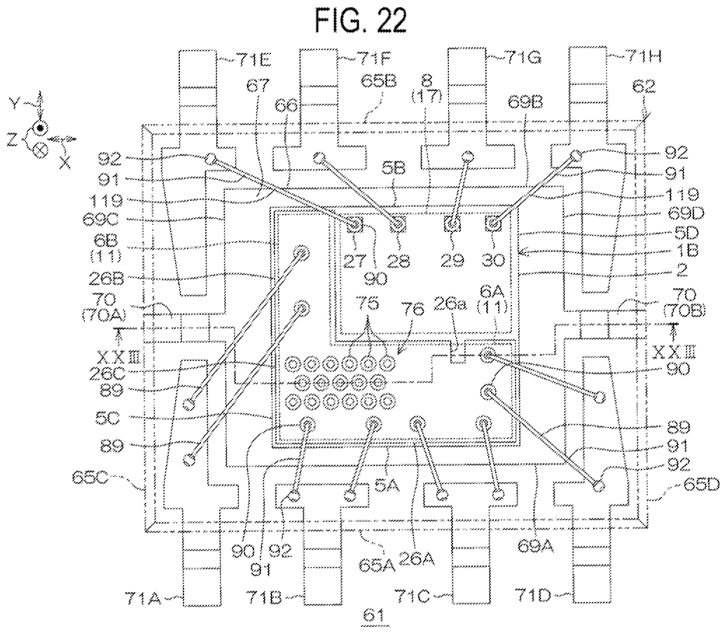

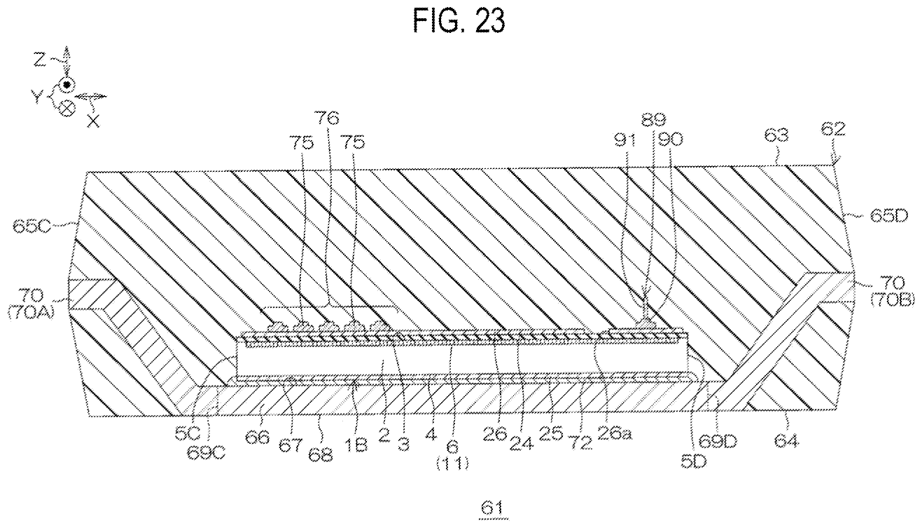

FIG. 22 is a plan view showing the semiconductor device 61 on which the semiconductor chip 1B shown in FIG. 21 is mounted, together with the pseudo-bumps 75 according to the first layout example. FIG. 23 is a cross-sectional view taken along line XXIII-XXIII shown in FIG. 22. Referring to FIGS. 22 and 23, the semiconductor device 61 includes the semiconductor chip 1B instead of the semiconductor chip 1A.

The plurality of pseudo-bumps 75 described above may be arranged on one or both of the first terminal portion 26A and the second terminal portion 26B of the source terminal 26. In this embodiment, the plurality of pseudo-bumps 75 are arranged on an intersecting portion 26C of the first terminal portion 26A and the second terminal portion 26B. In this embodiment, the intersecting portion 26C is also a portion of the source terminal 26 that covers the high-temperature region of the output region 6.

A description of the layout of the plurality of pseudo-bumps 75 and the relationship between the layout of the genuine bumps 90 and the layout of the plurality of pseudo-bumps 75 is omitted because it is as described above. Of course, the pseudo-bumps 75 according to the second layout example may be arranged on the source terminal 26. Further, the pseudo-bumps 75 (the large pseudo-bump 75a and the small pseudo-bump 75b) according to the third layout example may be arranged on the source terminal 26.

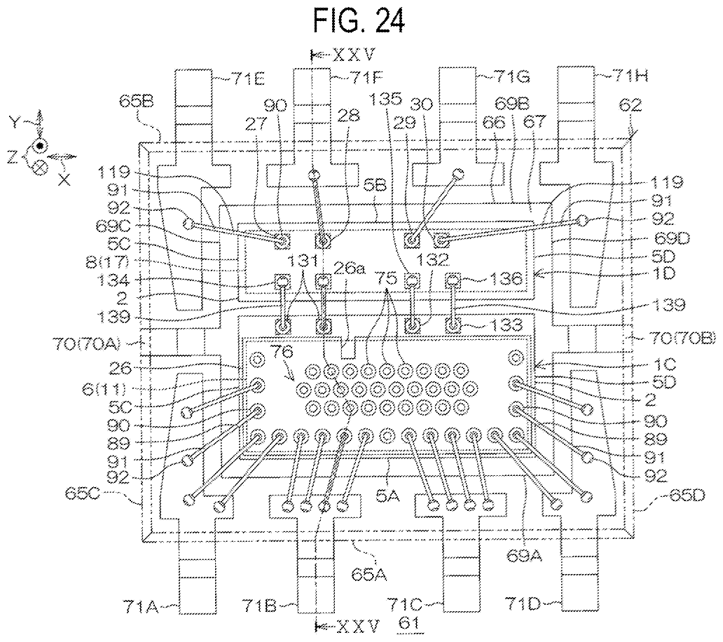

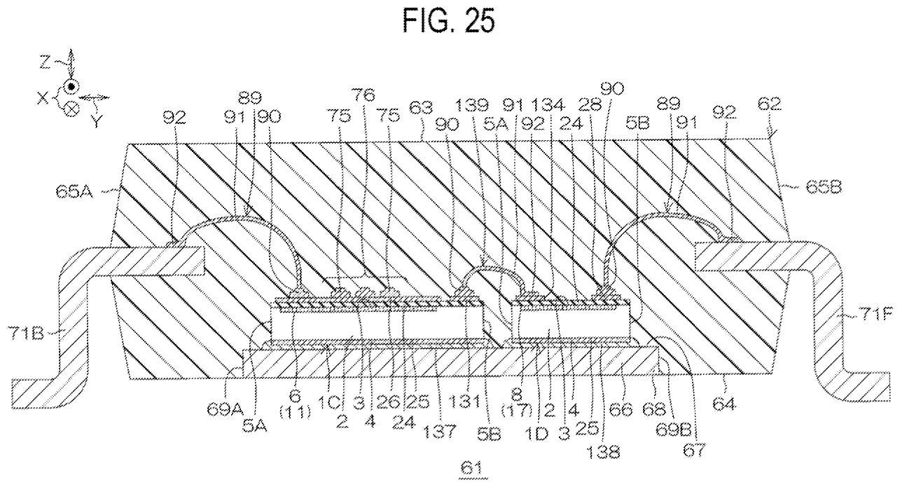

FIG. 24 is a plan view showing the internal structure of a semiconductor device 61 according to a first modification together with the pseudo-bumps 75 according to the first layout example. FIG. 25 is a cross-sectional view taken along line XXV-XXV shown in FIG. 24. Referring to FIGS. 24 and 25, the semiconductor device 61 according to the first modification includes a first semiconductor chip 1C and a second semiconductor chip 1D instead of the semiconductor chip 1A. The first semiconductor chip 1C and the second semiconductor chip 1D, as two chips, are configured to perform the same functions as the semiconductor chip 1A.

Specifically, the first semiconductor chip 1C includes the substrate 2, the output region 6, the current detection region 7, the first temperature detection region 9, the main transistor 11 (the plurality of trench structures 35), the monitor transistor 13 (the plurality of trench structures 35), the first temperature-sensitive diode 15, the interlayer insulating film 24, the drain terminal 25, the source terminal 26, the gate wiring 53, the source wiring 55, and a plurality of first functional terminals 131 to 133, and does not include the control region 8, the second temperature detection region 10, the second temperature-sensitive diode 16, and the control circuit 17.

The plurality of first functional terminals 131 to 133 includes n (here, two) first gate terminals 131, at least one (here, one) first monitor terminal 132, and at least one (here, 1) first temperature detection terminal 133. The n first gate terminals 131 are electrically connected to the first gates FG (the plurality of trench structures 35) of the n-system (here, two-system) main transistor 11 via n gate wirings 53 and transmit n (here, two) gate signals, which are input from the outside, to the first gates FG.

The first monitor terminal 132 is electrically connected to the first monitor source FMS of the monitor transistor 13 via the source wiring 55 and outputs the monitor current IM from the monitor transistor 13 to the outside. The first temperature detection terminal 133 is electrically connected to the first temperature-sensitive diode 15 and outputs the first temperature detection signal ST1 from the first temperature-sensitive diode 15 to the outside.

On the other hand, the second semiconductor chip 1D includes the substrate 2, the control region 8, the second temperature detection region 10, the second temperature-sensitive diode 16, the control circuit 17 (the gate drive circuit 18, the active clamp circuit 19, the overcurrent protection circuit 20, and the overheating protection circuit 21), the interlayer insulating film 24, the drain terminal 25, the first to fourth control terminals 27 to 30, the gate wiring 53, the source wiring 55, and a plurality of second functional terminals 134 to 136, and does not include the output region 6, the current detection region 7, the first temperature detection region 9, the main transistor 11 (the plurality of trench structures 35), the monitor transistor 13 (the plurality of trench structures 35), and the first temperature-sensitive diode 15.

The plurality of second functional terminals 134 to 136 includes n (here, two) second gate terminals 134, at least one (here, one) second monitor terminal 135, and at least one (here, one) second temperature detection terminal 136. The n second gate terminals 134 are electrically connected to the control circuit 17 (the gate drive circuit 18) via n gate wirings 53 and output n gate signals generated by the control circuit 17 to the outside.

The second monitor terminal 135 is electrically connected to the control circuit 17 (the overcurrent protection circuit 20) via the source wiring 55 and receives the monitor current IM from the monitor transistor 13. The second temperature detection terminal 136 is electrically connected to the control circuit 17 (the overheating protection circuit 21) and receives the first temperature detection signal ST1 from the first temperature-sensitive diode 15.

The semiconductor device 61 includes a first conductive bonding material 137 interposed between the first semiconductor chip 1C and the metal plate 66 within the package body 62. Specifically, the first conductive bonding material 137 is interposed between the drain terminal 25 of the first semiconductor chip 1C and the metal plate 66 and electrically and mechanically connects the drain terminal 25 of the first semiconductor chip 1C and the metal plate 66. The first conductive bonding material 137 may contain solder or metal paste. The solder may be lead-free solder. The metal paste may contain at least one of Au, Ag, and Cu. The Ag paste may be made of Ag sintered paste.

The semiconductor device 61 includes a second conductive bonding material 138 interposed between the second semiconductor chip 1D and the metal plate 66 within the package body 62. Specifically, the second conductive bonding material 138 is interposed between the drain terminal 25 of the second semiconductor chip 1D and the metal plate 66 and electrically and mechanically connects the drain terminal 25 of the second semiconductor chip 1D and the metal plate 66. The second conductive bonding material 138 may include solder or metal paste. The solder may be lead-free solder. The metal paste may contain at least one of Au, Ag, and Cu. The Ag paste may be made of Ag sintered paste.

The semiconductor device 61 according to the first modification includes at least one (in this embodiment, a plurality of) third bonding wires 139 arranged inside the package body 62. The plurality of third bonding wires 139 electrically connect the plurality of first functional terminals 131 to 133 to the plurality of second functional terminals 134 to 136, respectively.

The plurality of third bonding wires 139 each include the genuine bump 90, the wire loop 91, and the wire tail 92, similar to the first bonding wires 89. Further, the plurality of third bonding wires 139 includes the second bump body 97 and the second bump metal film 98 in the genuine bump 90, similar to the first bonding wires 89.

It is preferable that the genuine bump 90 is bonded to the first functional terminals 131 to 133 and the wire tail 92 is bonded to the second functional terminals 134 to 136. Of course, the genuine bump 90 may be bonded to the second functional terminals 134 to 136 and the wire tail 92 may be bonded to the first functional terminals 131 to 133. Other descriptions of the third bonding wires 139 are omitted as the description of the first bonding wires 89 applies.

In the semiconductor device 61 according to the first modification, the electrical configuration of the semiconductor chip 1A is implemented by the first semiconductor chip 1C and the second semiconductor chip 1D. Since a process on the second semiconductor chip 1D is omitted in a manufacturing process of the first semiconductor chip 1C, manufacturing difficulty of the first semiconductor chip 1C may be reduced, thereby shortening the manufacturing time of the first semiconductor chip 1C. Similarly, since a process on the first semiconductor chip 1C is omitted in a manufacturing process of the second semiconductor chip 1D, the manufacturing difficulty of the second semiconductor chip 1D may be reduced, thereby shortening the manufacturing time of the second semiconductor chip 1D.

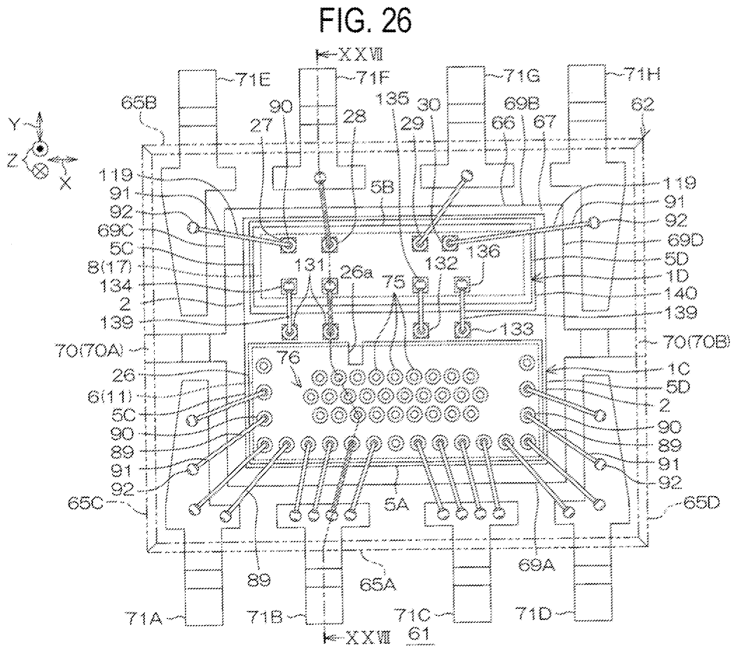

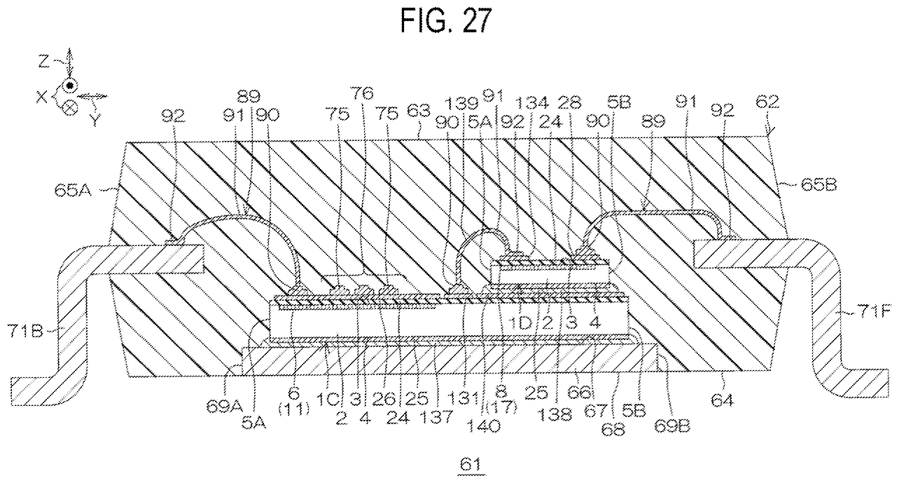

FIG. 26 is a plan view showing the internal structure of a semiconductor device 61 according to a second modification of the present disclosure together with the pseudo-bumps 75 according to the first layout example. FIG. 27 is a cross-sectional view taken along line XXVII-XXVII shown in FIG. 26. The semiconductor device 61 according to the second modification has a form obtained by changing the form of the first semiconductor chip 1C and the form of the second semiconductor chip 1D according to the first modification.

Specifically, the first semiconductor chip 1C includes a pad terminal 140 arranged on the interlayer insulating film 24 at an interval from the source terminal 26. The arrangement location of the pad terminal 140 is arbitrary. In this embodiment, the pad terminal 140 is arranged to face the source terminal 26 with the plurality of first functional terminals 131 to 133 interposed therebetween. The pad terminal 140 preferably covers a region outside the output region 6 in a plan view.

The second semiconductor chip 1D has a smaller size than the first semiconductor chip 1C and is arranged on the first semiconductor chip 1C. The second semiconductor chip 1D is arranged on the pad terminal 140 with the drain terminal 25 facing the pad terminal 140. Further, the second semiconductor chip 1D is arranged in such a posture that the plurality of second functional terminals 134 to 136 face the plurality of first functional terminals 131 to 133 in a plan view.

In this embodiment, the aforementioned second conductive bonding material 138 is interposed between the second semiconductor chip 1D and the pad terminal 140 within the package body 62. Specifically, the second conductive bonding material 138 is interposed between the drain terminal 25 of the second semiconductor chip 1D and the pad terminal 140 and electrically and mechanically connects the drain terminal 25 of the second semiconductor chip 1D and the pad terminal 140. The plurality of third bonding wires 139 described above electrically connect the plurality of first functional terminals 131 to 133 to the plurality of second functional terminals 134 to 136, respectively, on the first semiconductor chip 1C.

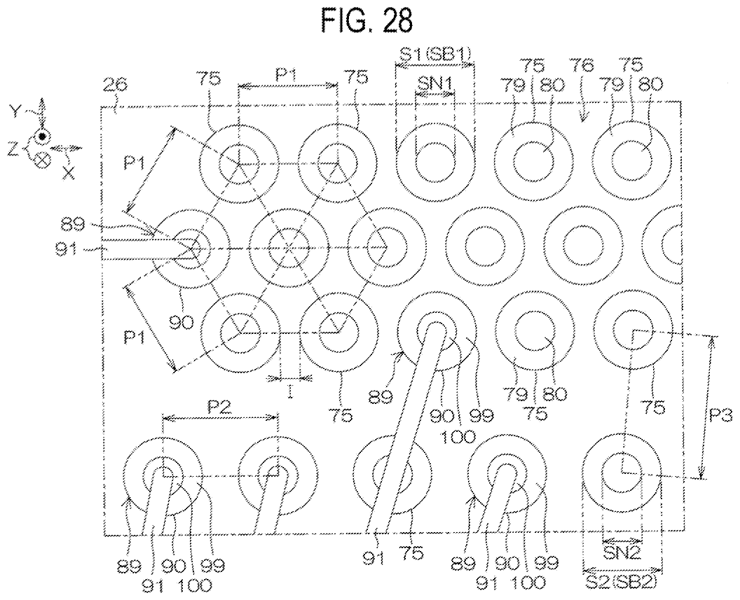

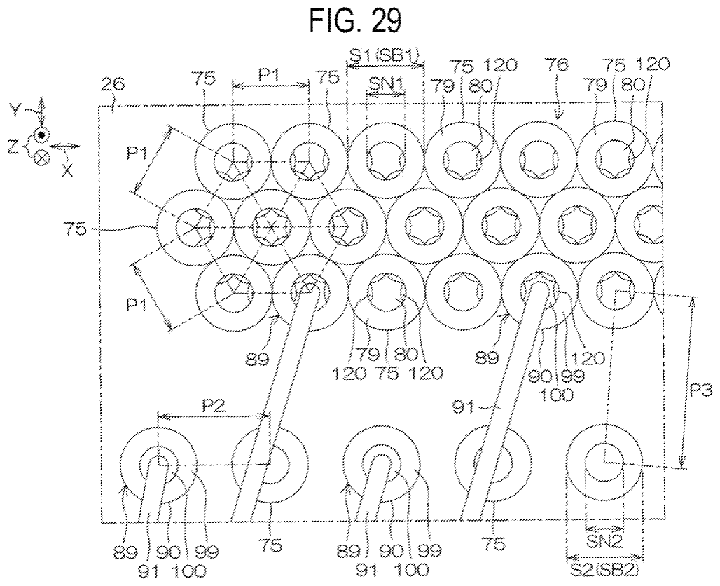

A modification of the pseudo-bumps 75 according to the first to third layout examples is shown below with reference to plan views of FIGS. 28 to 30. Referring to FIG. 28, at least one pseudo-bump 75 may be replaced with a genuine bump 90 in the plurality of pseudo-bumps 75 according to the first layout example. Referring to FIG. 29, at least one pseudo-bump 75 may be replaced with a genuine bump 90 in the plurality of pseudo-bumps 75 according to the second layout example.

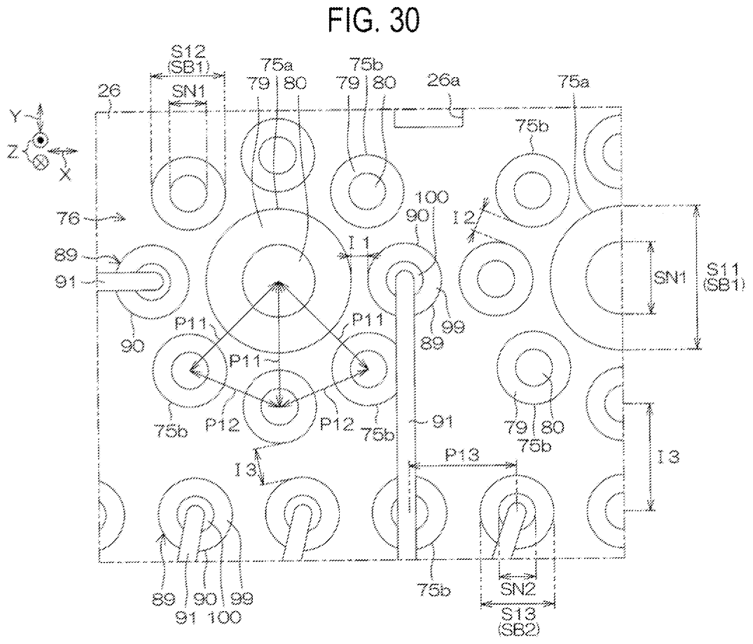

Referring to FIG. 30, at least one small pseudo-bump 75b may be replaced with a genuine bump 90 in the plurality of small pseudo-bumps 75b according to the third layout example. In the first to third layout examples, the arrangement location and the number of pseudo-bumps 75 to be replaced with the genuine bump 90 are arbitrary. A specific description of the layouts according to FIGS. 28 to 30 is obtained by reading the “pseudo-bump 75” replaced with the “genuine bump 90” as the “genuine bumps 90” in the aforementioned description of the “pseudo-bump 75.”

The above-described embodiments may be implemented in other forms. For example, in the above-described embodiments, a one-system main transistor 11 may be employed. In this case, all the trench structures 35 for the main transistor 11 are on/off-controlled at the same time. For example, in the above-described embodiments, a one-system monitor transistor 13 may be employed. In this case, all the trench structures 35 for the monitor transistor 13 are on/off-controlled at the same time.

For example, in the above-described embodiments, the current detection region 7 may be provided in a region (for example, within the control region 8) outside the output region 6. For example, in the above-described embodiments, a structure in which a first active clamp circuit 19 is connected to the main transistor 11 and a second active clamp circuit 19 is connected to the monitor transistor 13 may be employed.

For example, in the above-described embodiments, the monitor transistor 13 may include at least one system monitor transistor 14 electrically independent of the n system transistors 12. For example, in the above-described embodiments, a plurality of system monitor transistors 14 may be connected to one system transistor 12. For example, in the above-described embodiments, at least one second monitor source SMS may be electrically disconnected from the first monitor source FMS to form an independent current path.

For example, in the above-described embodiments, a structure in which a first gate drive circuit 18 is connected to the main transistor 11 and a second gate drive circuit 18 is connected the monitor transistor 13 may be employed. In this case, the monitor transistor 13 may be controlled to be interlocked with the main transistor 11 or may be controlled not to be interlocked with the main transistor 11.

In the above-described embodiments, the example in which the second electrode 40 is fixed to the same potential as the first electrode 39 has been shown. However, a different potential than that of the first electrode 39 may be applied to the second electrode 40. In this case, a source potential may be applied to the second electrode 40. This structure may reduce the parasitic capacitance between the substrate 2 and the second electrode 40 and improve the switching speed.

In the above-described embodiments, the third insulating film 41 may be removed and the first electrode 39 and the second electrode 40 may be integrally formed. Further, the second insulating film 38 may have a thickness approximately equal to that of the first insulating film 37. That is, the trench structure 35 may have a single electrode structure including a single electrode buried in the trench 36 with an insulating film interposed therebetween.

In the above-described embodiments, the example in which the trench gate type main transistor 11 is formed in the output region 6 has been shown. However, a planar gate type main transistor 11 may be formed in the output region 6. In this case, a planar gate type monitor transistor 13 may be formed in the current detection region 7.

In the above-described embodiments, the example in which the first conductivity type is n-type and the second conductivity type is p-type has been shown. However, the first conductivity type may be p-type and the second conductivity type may be n-type. A specific configuration in this case is obtained by replacing the n-type region with a p-type region and replacing the p-type region with an n-type region in the aforementioned description and accompanying drawings.

Below are examples of features extracted from the present disclosure and the accompanying drawings. In the following description, alphanumeric characters in parentheses represent corresponding components in the above-described embodiments, but the scope of each clause is not limited to the embodiments.
[A1] A semiconductor device (61) including: a substrate (2), a device region (6) provided in the substrate (2), a terminal (26) covering the device region (6) in a plan view, a plurality of pseudo-bumps (75, 75a, 75b) densely arranged on the terminal (26) in a state of being opened from a wire, and at least one genuine bump (90) arranged more sparsely than the plurality of the pseudo-bumps (75, 75a, 75b) on the terminal (26) in a state of being connected to the wire.
[A2] The semiconductor device (61) of A1, wherein the plurality of pseudo-bumps (75, 75a, 75b) are arranged on the terminal (26) with a first occupation area per unit plane area, and the at least one genuine bump (90) is arranged on the terminal (26) with the second occupation area less than the first occupation area per unit area.
[A3] The semiconductor device (61) of A1 or A2, wherein the at least one genuine bump (90) includes a plurality of genuine bumps (90), and the plurality of genuine bumps (90) are sparsely arranged on the terminal (26).
[A4] The semiconductor device (61) of A3, wherein the plurality of pseudo-bumps (75, 75a, 75b) are arranged on the terminal (26) at a first pitch (P1), and the plurality of genuine bumps (90) are arranged on the terminal (26) at a second pitch (P2) lager than the first pitch (P1).
[A5] The semiconductor device (61) of any one of A1 to A4, wherein at least three pseudo-bumps (75, 75a, 75b) of the plurality of pseudo-bumps are densely arranged on the terminal (26).
[A6] The semiconductor device (61) of A5, wherein the at least three pseudo-bumps (75, 75a, 75b) are arranged in a layout in which the at least three pseudo-bumps (75, 75a, 75b) are located at vertices of an isosceles triangle in the plan view.
[A7] The semiconductor device (61) of any one of A1 to A6, wherein at least seven pseudo-bumps (75, 75a, 75b) of the plurality of pseudo-bumps are densely arranged on the terminal (26).
[A8] The semiconductor device (61) of A7, wherein six pseudo-bumps (75, 75a, 75b) of the at least seven pseudo-bumps are arranged around one pseudo-bump (75, 75a, 75b) of the at least seven pseudo-bumps.
[A9] The semiconductor device (61) of A8, wherein the six pseudo-bumps (75, 75a, 75b) are arranged in a layout in which the six pseudo-bumps (75, 75a, 75b) are located at vertices of a hexagon in the plan view, and the one pseudo-bump (75, 75a, 75b) is arranged in a layout in which the one pseudo-bump (75, 75a, 75b) is located at a center of the hexagon in the plan view.
[A10] The semiconductor device (61) of any one of A1 to A9, further including: a thin film portion (111, 121, 122) formed at the bonding portion of each of the pseudo-bumps (75, 75a, 75b) in the terminal (26), and a thick film portion (113, 124) formed in a region outside the bonding portion of each of the pseudo-bumps (75,75a, 75b) in the terminal (26).
[A11] The semiconductor device (61) of A10, further including a raised portion (114, 125, 126) in which a portion of the terminal (26) is thicker than the thick film portion (113, 124) at a bonding edge of each of the pseudo-bumps (75, 75a, 75b) in the terminal (26).
[A12] The semiconductor device (61) of any one of A1 to A11, wherein each of the pseudo-bumps (75, 75a, 75b) includes: a wide body portion (79) connected to the terminal (26), and a neck portion (80) which is narrower than the body portion (79) and protrudes from the body portion (79) toward an opposite side of the terminal (26).
[A13] The semiconductor device (61) of A12, wherein each of the pseudo-bumps (75, 75a, 75b) includes at least one gouged portion (120) recessed toward a central portion of the neck portion (80) in the neck portion (80).
[A14] The semiconductor device (61) of any one of A1 to A13, wherein each of the pseudo-bumps (75, 75a, 75b) includes a bump body (77) containing first metal, and a metal film (78) containing second metal different from the first metal and covering at least a portion of an outer surface of the bump body (77).
[A15] The semiconductor device (61) of any one of A1 to A14, further including a plurality of trench structures (35) formed in the device region (6) in the substrate (2), wherein each of the pseudo-bumps (75, 75a, 75b) overlaps the plurality of trench structures (35) in the plan view.
[A16] The semiconductor device (61) of A15, wherein each of the pseudo-bumps (75, 75a, 75b) has a thickness larger than a depth of each of the trench structures (35).
[A17] The semiconductor device (61) of A15 or A16, further including a transistor (11, 13) including the plurality of trench structures (35).
[A18] The semiconductor device (61) of A17, wherein the transistor (11, 13) is a gate split transistor (11, 13) including a plurality of system transistors (12, 14), which are controlled individually, and configured to generate a single output signal (IO, IM) by selective control of the plurality of system transistors (12, 14).
[A19] The semiconductor device (61) of A18, wherein the transistor (11, 13) is configured such that the on-resistance is changed by individual control of the plurality of system transistors (12, 14).
[A20] The semiconductor device (61) of any one of A1 to A19, further including: a control region (8) provided in the substrate (2), wherein the terminal (26) covers the device region (6) to expose the control region (8) in the plan view.
[A21] The semiconductor device (61) of A20, further including: a first temperature detection region (9) provided in the substrate (2) to be adjacent to the output region (6); a second temperature detection region (10) provided in the substrate (2) to be adjacent to the control region (8); a first temperature sensor (15) formed in the first temperature detection region (9); and a second temperature sensor (16) formed in the second temperature detection region (10).
[B1] A semiconductor device (61) including: a substrate (2), a device region (6) provided in the substrate (2), a terminal (26) covering the device region (6) in a plan view, a pseudo-bump (75a) arranged on the terminal (26) in a state of being opened from a wire, and a genuine bump (90) that is arranged on the terminal (26) in a state of being connected to the wire and has a size (S13) smaller than a size (S11) of the pseudo-bump (75a).
[B2] The semiconductor device (61) of B1, wherein the pseudo-bump (75a) is thicker than the terminal (26).
[B3] The semiconductor device (61) of B1 or B2, further including at least one small pseudo-bump (75b) that is arranged around the pseudo-bump (75a) on the terminal (26) in a state of being opened from the wire and has a size (S12) smaller than the size (S11) of the pseudo-bump (75a).
[B4] The semiconductor device (61) of B3, wherein the small pseudo-bump (75b) is thicker than the terminal (26).
[B5] The semiconductor device (61) of B3 or B4, wherein the at least one small pseudo-bump (75b) includes x (x>2) small pseudo-bumps (75b), and the x small pseudo-bumps (75b) are arranged around the pseudo-bump (75a).
[B6] The semiconductor device (61) of B5, wherein the value of x is 3 or more (x>3).
[B7] The semiconductor device (61) of B5 or B6, wherein the value of x is 4 or more (x>4).
[B8] The semiconductor device (61) of any one of B5 to B7, wherein the value of x is 20 or less (x<20).
[B9] The semiconductor device (61) of any one of B5 to B8, wherein the value of x is 6 or more and 12 or less (6<x<12).
[B10] The semiconductor device (61) of any one of B5 to B9, wherein the x small pseudo-bumps (75b) are arranged at equal intervals along a circumferential direction of the pseudo-bumps (75a) in a plan view.
[B11] The semiconductor device (61) of any one of B5 to B10, wherein the x small pseudo-bumps (75b) are arranged on a concentric circle centered on the central portion of the pseudo-bump (75a) in a plan view.
[B12] The semiconductor device (61) of any one of B5 to B11, wherein the x (x>3) small pseudo-bumps (75b) are arranged at vertices of a regular x-polygon in a plan view, respectively.
[B13] The semiconductor device (61) of B12, wherein the pseudo-bump (75a) is arranged at the center of the regular x-polygon in a plan view.
[B14] The semiconductor device (61) of any one of B1 to B13, wherein a plurality of genuine bumps (90) are arranged on the terminal (26).
[B15] The semiconductor device (61) of any one of B1 to B14, wherein the pseudo-bump (75a) includes a wide body portion (79) connected to the terminal (26), and a neck portion (80) which is narrower than the body portion (79) and protrudes from the body portion (79) toward an opposite side of the terminal (26).
[B16] The semiconductor device (61) of any one of B1 to B15, wherein the pseudo-bump (75a) includes a bump body (77) containing first metal, and a metal film (78) containing second metal different from the first metal and covering at least a portion of the outer surface of the bump body (77).
[B17] The semiconductor device (61) of any one of B1 to B16, further including: a thin film portion (121) formed at the bonding portion of the pseudo-bump (75a) in the terminal (26); and a thick film portion (124) formed in a region outside the bonding portion of the pseudo-bump (75a) in the terminal (26).
[B18] The semiconductor device (61) of B17, further including a raised portion (125) in which a portion of the terminal (26) is thicker than the thick film portion (124) at the bonding edge of the pseudo-bump (75a) in the terminal (26).
[B19] The semiconductor device (61) of any one of B1 to B18, further including a plurality of trench structures (35) formed in the device region (6) in the substrate (2), wherein the pseudo-bump (75a) overlaps the plurality of trench structures (35) in a plan view.
[B20] The semiconductor device (61) of B19, wherein the pseudo-bump (75a) has a thickness larger than a depth of each of the trench structures (35).
[B21] The semiconductor device (61) of any one of B1 to B20, further including a control region (8) provided in the substrate (2), wherein the terminal (26) covers the device region (6) to expose the control region (8) in a plan view.
[B22] The semiconductor device (61) of B21, further including: a first temperature detection region (9) provided in the substrate (2) to be adjacent to the output region (6); a second temperature detection region (10) provided in the substrate (2) to be adjacent to the control region (8); a first temperature sensor (15) formed in the first temperature detection region (9); and a second temperature sensor (16) formed in the second temperature detection region (10).

Although the embodiments have been described in detail, these embodiments are merely specific examples used to clarify technical contents, and the present disclosure should not be construed as being limited to these specific examples, and the scope thereof is limited by the appended claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a substrate;
a device region provided in the substrate;
a terminal covering the device region in a plan view;
a plurality of pseudo-bumps densely arranged on the terminal in a state of being opened from a wire; and
at least one genuine bump arranged more sparsely than the plurality of pseudo-bumps on the terminal in a state of being connected to the wire.

2. The semiconductor device of claim 1, wherein the plurality of pseudo-bumps are arranged on the terminal with a first occupation area per unit plane area, and
wherein the at least one genuine bump is arranged on the terminal with a second occupation area less than the first occupation area per unit area.

3. The semiconductor device of claim 1, wherein the at least one genuine bump includes a plurality of genuine bumps, and
wherein the plurality of genuine bumps are sparsely arranged on the terminal.

4. The semiconductor device of claim 3, wherein the plurality of pseudo-bumps are arranged on the terminal at a first pitch, and
wherein the plurality of genuine bumps are arranged on the terminal at a second pitch lager than the first pitch.

5. The semiconductor device of claim 1, wherein at least three pseudo-bumps of the plurality of pseudo-bumps are densely arranged on the terminal.

6. The semiconductor device of claim 5, wherein the at least three pseudo-bumps are arranged in a layout in which the at least three pseudo-bumps are located at vertices of an isosceles triangle in the plan view.

7. The semiconductor device of claim 1, wherein at least seven pseudo-bumps of the plurality of pseudo-bumps are densely arranged on the terminal.

8. The semiconductor device of claim 7, wherein six pseudo-bumps of the at least seven pseudo-bumps are arranged around one pseudo-bump of the at least seven pseudo-bumps.

9. The semiconductor device of claim 8, wherein the six pseudo-bumps are arranged in a layout in which the six pseudo-bumps are located at vertices of a hexagon in the plan view, and
wherein the one pseudo-bump is arranged in a layout in which the one pseudo-bump is located at a center of the hexagon in the plan view.

10. The semiconductor device of claim 1, further comprising:
a thin film portion formed at a bonding portion of each of the plurality of pseudo-bumps in the terminal; and
a thick film portion formed in a region outside the bonding portion of each of the plurality of pseudo-bumps in the terminal.

11. The semiconductor device of claim 10, further comprising a raised portion in which a portion of the terminal is thicker than the thick film portion at a bonding edge of each of the plurality of pseudo-bumps in the terminal.

12. The semiconductor device of claim 1, wherein each of the plurality of pseudo-bumps includes:
a wide body portion connected to the terminal; and
a neck portion which is narrower than the body portion and protrudes from the body portion toward an opposite side of the terminal.

13. The semiconductor device of claim 12, wherein each of the plurality of pseudo-bumps includes at least one gouged portion recessed toward a central portion of the neck portion in the neck portion.

14. The semiconductor device of claim 1, wherein each of the plurality of pseudo-bumps includes:
a bump body containing first metal; and
a metal film containing second metal different from the first metal and covering at least a portion of an outer surface of the bump body.

15. The semiconductor device of claim 1, further comprising a plurality of trench structures formed in the device region in the substrate,
wherein each of the plurality of pseudo-bumps overlaps the plurality of trench structures in the plan view.

16. The semiconductor device of claim 15, wherein each of the plurality of pseudo-bumps has a thickness larger than a depth of each of the plurality of trench structures.

17. The semiconductor device of claim 1, further comprising a control region provided in the substrate,
wherein the terminal covers the device region to expose the control region in the plan view.

18. A semiconductor device comprising:
a substrate;
a device region provided in the substrate;
a terminal covering the device region in a plan view;
a pseudo-bump arranged on the terminal in a state of being opened from a wire; and
a genuine bump that is arranged on the terminal in a state of being connected to the wire and has a size smaller than a size of the pseudo-bump.

19. The semiconductor device of claim 18, further comprising at least one small pseudo-bump that is arranged around the pseudo-bump on the terminal in a state of being opened from the wire and has a size smaller than the size of the pseudo-bump.

20. The semiconductor device of claim 19, wherein the at least one small pseudo-bump includes a plurality of small pseudo-bumps, and
wherein the plurality of small pseudo-bumps are arranged around the pseudo-bump.
